(19) United States
(12) Patent Application Publication
(10) Pub. No.: US 2021/0383220 A1
(43) Pub. Date: Dec. 9, 2021

(54) DEEP NEURAL NETWORK ENSEMBLES FOR DECODING ERROR CORRECTION CODES

(71) Applicant: Ramot at Tel-Aviv University Ltd., Tel-Aviv (IL)

(72) Inventors: Yair BEERY, Tel-Aviv (IL); Tomer RAVIV, Tel-Aviv (IL)

(73) Assignee: Ramot at Tel-Aviv University Ltd., Tel-Aviv (IL)

(21) Appl. No.: 17/337,519

(22) Filed: Jun. 3, 2021

Related U.S. Application Data
(63) Continuation-in-part of application No. 16/892,343, filed on Jun. 4, 2020.

(51) Int. Cl. G06N 3/08; G06N 3/04; H03M 13/41; G06F 11/10

(52) U.S. Cl. CPC G06N 3/08; G06N 3/0454; G06F 11/1044; H03M 13/41; G06N 3/0472

(57) ABSTRACT

Provided herein are methods and systems for applying an ensemble comprising a plurality of neural network based decoders trained using actively selected training samples for decoding error correction encoded codewords which are also encoded for error detection before transmitted over transmission channels subject to interference. In particular, each of the neural network based decoders is associated with only a limited size region of the distribution space of the error correction code where the distribution space is partitioned based on error detection values computed for the encoded codewords. As such each of the decoders is specialized for decoding encoded codewords mapped to its limited size associated region. During run-time a received encoded codeword may be mapped to one of the regions and may be fed accordingly to one of the neural network based decoders of the ensemble which is associated with the mapped region.

### RELATED APPLICATION

This application is a Continuation-In-Part (C.I.P.) of U.S. patent application Ser. No. 16/892,343 filed on Jun. 4, 2020, the contents of which are all incorporated by reference as if fully set forth herein in its entirety.

This application is also related to U.S. patent application Ser. No. 15/996,542 titled “Deep Learning Decoding of Error Correcting Codes” filed on Jun. 4, 2018, the contents of which are incorporated herein by reference in their entirety.

### FIELD AND BACKGROUND OF THE INVENTION

The present invention, in some embodiments thereof, relates to applying an ensemble of trained neural network based decoders for decoding encoded error correction codes transmitted over a transmission channel, and, more specifically, but not exclusively, applying an ensemble of neural network based decoders trained with actively selected training datasets for decoding encoded error correction codes transmitted over a transmission channel.

Transmission of data over transmission channels, either wired and/or wireless is an essential building block for most modern era data technology applications, for example, communication channels, network links, memory interfaces, components interconnections (e.g. bus, switched fabric, etc.) and/or the like. However, such transmission channels are typically subject to interferences such as, noise, crosstalk, attenuation, etc. which may degrade the transmission channel performance for carrying the communication data and may lead to loss of data at the receiving side. One of the most commonly used methods to overcome this is to encode the data with error correction data which may allow the receiving side to detect and/or correct errors in the received encoded data. Such methods may utilize one or more error correction models as known in the art, for example, linear block codes such as, for example, algebraic linear code, polar code, Low Density Parity Check (LDPC) and High Density Parity Check (HDPC) codes as well as non-block codes such as, for example, convolutional codes and/or non-linear codes, such as, for example, Hadamard code.

Machine learning and deep learning methods which are the subject of major research and development in recent years have demonstrated significant improvements in various applications and tasks.

Further research and exploration in the field of error correction codes revealed, demonstrated and established that such machine learning models, specifically neural network and more specifically deep neural networks for may be trained to decode such error correction codes with significantly improved performance and efficiency.

### SUMMARY OF THE INVENTION

According to a first aspect of the present invention there is provided a computer implemented method of training neural network based decoders to decode error correction codes transmitted over transmission channels subject to interference, comprising using one or more processors for:
Obtaining a plurality of samples each mapping one or more training codewords encoded according to one or more error detection codes and further encoded according to one or more error correction codes. Each sample is subjected to a different interference pattern injected to the transmission channel.
Computing an error detection value for each of the plurality of samples according to the one or more error detection codes.
Mapping each of the plurality of samples, based on its respective error detection value, to one of a plurality of regions of the distribution space of the error correction code.
Selecting a plurality of sample subsets each comprising one or more of the plurality of samples which is mapped to a respective one of the plurality of regions.
Training each of a plurality of neural network based decoders using a respective one of the plurality of sample subsets.

According to a second aspect of the present invention there is provided a system for training neural network based decoders to decode error correction codes transmitted over transmission channels subject to interference, comprising one or more processors adapted to execute code, the code comprising:
Code instructions to obtain a plurality of samples each mapping one or more training codewords encoded according to one or more error detection codes and further encoded according to one or more error correction codes. Each sample is subjected to a different interference pattern injected to the transmission channel.
Code instructions to compute an error detection value for each of the plurality of samples according to the one or more error detection codes.
Code instructions to map each of the plurality of samples, based on its respective error detection value, to one of a plurality of regions of the distribution space of the error correction code.
Code instructions to select a plurality of sample subsets each comprising one or more of the plurality of samples which is mapped to a respective one of the plurality of regions.
Code instructions to train each of a plurality of neural network based decoders using a respective one of the plurality of sample subsets.

According to a third aspect of the present invention there is provided a computer implemented method of decoding a code transmitted over a transmission channel subject to interference using an ensemble of neural network based decoders, comprising using one or more processors for:
Receiving an encoded codeword transmitted over a transmission channel, the received codeword is encoded according to one or more error detection codes and further encoded according to one or more error correction codes.
Applying one or more mapping functions to map the received encoded codeword to one of a plurality of regions of a distribution space of the error correction code based on an error detection value computed for the received encoded codeword according to the one or more error detection codes.
Selecting one or more of a plurality of neural network based decoders based on a region of the plurality of regions into which the received encoded codeword is mapped. Each of the plurality of neural network based decoders is trained to decode codes mapped into a respective one of the plurality of regions constituting the distribution space.
Feeding the code to the one or more selected neural network based decoders to decode the code.

According to a fourth aspect of the present invention there is provided a system for decoding a code transmitted over a transmission channel subject to interference using an ensemble of neural network based decoders, comprising one or more processor adapted to execute code, the code comprising:
Code instructions to receive an encoded codeword transmitted over a transmission channel, the received codeword is encoded according to one or more error detection code and further encoded according to a linear error correction code.
Code instructions to apply one or more mapping function to map the received encoded codeword to one of a plurality of regions of a distribution space of the error correction code based on an error detection value computed for the received encoded codeword according to the one or more error detection code.
Code instructions to select one or more of a plurality of neural network based decoders based on a region of the plurality of regions into which the received encoded codeword is mapped. Each of the plurality of neural network based decoders is trained to decode codes mapped into a respective one of the plurality of regions constituting the distribution space.
Code instructions to feed the code to the one or more selected neural network based decoder to decode the code.

In a further implementation form of the first, second, third and/or fourth aspects, the one or more error detection codes comprising Cyclic Redundancy Check (CRC) code.

In a further implementation form of the first, second, third and/or fourth aspects, the one or more error detection codes and the one or more error correction codes are selected according to one or more 5G cellular communication protocols.

In a further implementation form of the first, second, third and/or fourth aspects, the plurality of neural network based decoders are implemented based on Viterbi algorithm.

In a further implementation form of the first, second, third and/or fourth aspects, each of the plurality of neural network based decoder comprises an input layer, an output layer and a plurality of hidden layers comprising a plurality of nodes corresponding to transmitted messages over a plurality of edges of a graph representation of the encoded code and a plurality of edges connecting the plurality of nodes, each of the plurality of edges having a source node and a destination node is assigned with a respective weight adjusted during the training.

In a further implementation form of the first, second, third and/or fourth aspects, the graph is a member of a group consisting of: a bipartite graph, a Tanner graph and a factor graph.

In a further implementation form of the first, second, third and/or fourth aspects, the one or more error detection codes comprising Cyclic Redundancy Check (CRC) code.

In a further implementation form of the first and/or second aspects, the one or more training encoded codewords encode the zero codeword.

In a further implementation form of the first, second, third and/or fourth aspects, the training is done using one or more of: stochastic gradient descent, batch gradient descent and mini-batch gradient descent.

In a further implementation form of the first, second, third and/or fourth aspects, one or more of the plurality of neural network based decoders is further trained online when applied to decode one or more new and previously unseen encoded codewords of the code transmitted over a certain transmission channel.

In a further implementation form of the third and/or fourth aspects, the one or more mapping functions is based on decoding the received encoded codeword using one or more low complexity decoders.

In a further implementation form of the third and/or fourth aspects, the one or more mapping functions employ one or more gating neural network based decoders trained to decode the received encoded codeword.

In a further implementation form of the third and/or fourth aspects, the one or more gating neural network based decoder is implemented based on Viterbi algorithm.

In a further implementation form of the third and/or fourth aspects, during training, the plurality of neural network based decoders are trained using a plurality of samples each mapping one or more training encoded codewords of the one or more error correction codes. Each of the plurality of neural network based decoders is trained with a respective one of a plurality of sample subsets. Each of the plurality of sample subsets comprising one or more of the plurality of samples which are mapped to a respective one of the plurality of regions.

Other systems, methods, features, and advantages of the present disclosure will be or become apparent to one with skill in the art upon examination of the following drawings and detailed description. It is intended that all such additional systems, methods, features, and advantages be included within this description, be within the scope of the present disclosure, and be protected by the accompanying claims.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

Implementation of the method and/or system of embodiments of the invention can involve performing or completing selected tasks automatically. Moreover, according to actual instrumentation and equipment of embodiments of the method and/or system of the invention, several selected tasks could be implemented by hardware, by software or by firmware or by a combination thereof using an operating system.

For example, hardware for performing selected tasks according to embodiments of the invention could be implemented as a chip or a circuit. As software, selected tasks according to embodiments of the invention could be implemented as a plurality of software instructions being executed by a computer using any suitable operating system. In an exemplary embodiment of the invention, one or more tasks according to exemplary embodiments of methods and/or systems as described herein are performed by a data processor, such as a computing platform for executing a plurality of instructions. Optionally, the data processor includes a volatile memory for storing instructions and/or data and/or a non-volatile storage, for example, a magnetic hard-disk and/or removable media, for storing instructions and/or data. Optionally, a network connection is provided as well. A display and/or a user input device such as a keyboard or mouse are optionally provided as well.

### BRIEF DESCRIPTION OF THE SEVERAL VIEWS OF THE DRAWINGS

Some embodiments of the invention are herein described, by way of example only, with reference to the accompanying drawings. With specific reference now to the drawings in detail, it is stressed that the particulars are shown by way of example and for purposes of illustrative discussion of embodiments of the invention. In this regard, the description taken with the drawings makes apparent to those skilled in the art how embodiments of the invention may be practiced.

In the drawings:

FIG. 1 is a schematic illustration of an exemplary transmission system comprising a neural network based decoder for decoding an encoded error correction code transmitted over a transmission channel;

FIG. 2 is a flowchart of an exemplary process of training a neural network based decoder to decode an encoded error correction code using actively selected training samples, according to some embodiments of the present invention;

FIG. 3 is a schematic illustration of an exemplary system for training a neural network based decoder to decode an encoded error correction code using actively selected training samples, according to some embodiments of the present invention;

FIG. 4 is a graph chart of a Hamming distance distribution of training samples for various SNR values, according to some embodiments of the present invention;

FIG. 5 is a graph chart of a reliability parameter distribution of training samples for various SNR values, according to some embodiments of the present invention;

FIG. 6A, FIG. 6B, FIG. 6C, FIG. 6D, FIG. 6E and FIG. 6F are graph charts of BER and FER results of a neural network based decoder trained with actively selected training samples applied to decode BCH(63,36), BCH(63,45) and BCH(127,64) encoded linear block codes, according to some embodiments of the present invention;

FIG. 7 is a flowchart of an exemplary process of using an ensemble comprising a plurality of neural network based decoders to decode an encoded error correction code transmitted over a transmission channel, according to some embodiments of the present invention;

FIG. 8 is a schematic illustration of an exemplary ensemble comprising a plurality of neural network based decoders for decoding an encoded error correction code transmitted over a transmission channel, according to some embodiments of the present invention;

FIG. 9A, FIG. 9B, FIG. 9C and FIG. 9D are graph charts of FER results of an ensemble of neural network based decoder applied to decode CR-BCH(63,36) and CR-BCH(63,45) encoded linear block codes, according to some embodiments of the present invention;

FIG. 10 is a schematic illustration of an exemplary transmission system comprising a neural network based decoder for decoding encoded error correction codewords further encoded for error detection which are transmitted over a transmission channel, according to some embodiments of the present invention;

FIG. 11 is a flowchart of an exemplary process of using actively selected training samples to train neural network based decoders to decode encoded error correction codewords which are further encoded for error detection, according to some embodiments of the present invention; and

FIG. 12 is a flowchart of an exemplary process of using an ensemble comprising a plurality of neural network based decoders to decode encoded error correction codewords further encoded for error detection which are transmitted over a transmission channel, according to some embodiments of the present invention;

FIG. 13A, FIG. 13B, FIG. 13C and FIG. 13D are graph charts of Frame Error Rate (FER) and Viterbi Algorithm (VA) run results of an ensemble of neural network based weighted circular Viterbi decoders applied to decode Tail-Biting (87,29,13) and (93, 31, 15) convolutional codes, according to some embodiments of the present invention;

FIG. 14A and FIG. 14B are graph charts of FER results of an ensemble of neural network based weighted circular Viterbi decoders applied to decode Tail-Biting (138,46,30) and (198, 66, 50) convolutional codes, according to some embodiments of the present invention;

FIG. 15 is a graph chart of FER results of a trained neural network based circular Viterbi decoder vs, a trained neural network based weighted circular Viterbi decoder as function of the number of termination states of a convolutional codes, according to some embodiments of the present invention; and

FIG. 16 is a graph chart presenting performance of an ensemble of neural network based weighted circular Viterbi decoders as function of their size, according to some embodiments of the present invention.

### DESCRIPTION OF SPECIFIC EMBODIMENTS OF THE INVENTION

The present invention, in some embodiments thereof, relates to applying an ensemble of trained neural network based decoders for decoding encoded error correction codes transmitted over a transmission channel, and, more specifically, but not exclusively, applying an ensemble of neural network based decoders trained with actively selected training datasets for decoding encoded error correction codes transmitted over a transmission channel.

Wired and/or wireless transmission channels are the most basic element for a plurality of data transmission applications, for example, communication channels, network links, memory interfaces, components interconnections (e.g. bus, switched fabric, etc.) and/or the like. However, data transmitted via such transmission channels which are subject to one or more interferences such as, for example, noise, crosstalk, attenuation, and/or the like may often suffer errors induced by the interference. Error correction codes may be therefore applied to enable efficient error correction codes and effective decoders to accurately detect and/or correct such errors to correctly recover the transmitted encoded codes while maintaining high transmission rates.

The error correction codes may include a wide range of error correction models and/or protocols as known in the art, for example, linear block codes such as, for example, algebraic linear code, polar code, Low Density Parity Check (LDPC) code, High Density Parity Check (HDPC) code and/or the like. However, the error correction codes may further include non-block codes such as, for example, convolutional codes and/or non-linear codes as well as non-linear codes such as, for example, Hadamard code and/or the like.

Error correction decoders constructed using machine learning models, specifically, neural networks and more specifically, deep neural networks have proved to be highly efficient decoders capable of effectively decoding error correction codes to accurately recover the encoded codes. The neural network based decoders have therefore gained wide spread and adoption since the need for low complexity, low latency and/or low power decoders is rapidly increasing with the emergence of plurality of low end applications, for example, the Internet of Things.

Some of the current state of the art neural network based decoding models and/or algorithms employ the Weighted Belief Propagation (WBP) algorithm which may achieve high transmission rates close to the Shannon channel capacity when decoding the encoded error correction codes.

The neural network based decoders may be constructed based on a bipartite graph (or bigraph) representation of the encoded error correction code, for example, a Tanner graph, a factor graph and/or the like. The neural network may comprise an input layer, an output layer and a plurality of hidden layers which are constructed from a plurality of nodes corresponding to transmitted messages over a plurality of edges of the graph where the edges are assigned with learnable weights facilitating the WBP algorithm in a neural network form.

While in other fields data may be sparse and costly to collect, in data transmission and error decoding the data may be free to query and label since transmitted codewords may be easily collected, captured, simulated and/or otherwise obtained for practically any transmission channel subject to a wide range of interference effects. This may allow for vast potential data exploitation making availability of samples for training the neural network based decoders practically infinite. The neural network based decoders may be therefore typically trained using randomly selected training datasets.

According to some embodiments of the present invention, there are provided methods and systems for actively selecting training datasets used to train neural network based decoders for decoding one or more of the error correction codes, specifically, neural network constructed to facilitate the WBP algorithm.

The neural network based decoders may employ one or more neural network architectures, specifically deep neural networks, for example, a Fully Connected (CF) neural network, a Convolutional Neural Network (CNN), a Feed-Forward (FF) neural network, a Recurrent Neural Network (RNN) and/or the like.

A well-known property of the WBP algorithm is the independence of the performance from the transmitted codeword, meaning the performance of the WBP based decoder is independent (indifferent) to the transmitted codeword such that the performance may remain similar for any transmitted codeword. This property of the WBP algorithm is preserved by the neural network based decoders. It is therefore sufficient to use a single codeword for training the weights (parameters) of the neural network based decoder, specifically the zero codeword (all zero) since the architecture guarantees the same error rate for any chosen transmitted codeword.

The active selection of the training dataset(s) is directed to select samples of transmitted encoded codewords, which provide increased benefit for training the neural network based decoders compared to randomly selected samples. As such a plurality of samples may be explored to select a subset of samples that are estimated to provide the most benefit for training the neural network based decoders in order to improve performance of the neural network based decoders, for example, code recovery accuracy, code recovery reliability, immunity to false errors (e.g., false positive, false negative) and/or the like.

For example, the active selection may be defined to exclude samples which are transmitted over transmission channels subject to insignificant interference and may be thus characterized by high Signal to Noise Ratio (SNR). Such high SNR samples are not likely to include errors and are therefore expected to be easily decoded by the neural network based decoder. The high SNR samples may therefore present little and potentially no challenge for the neural network based decoder which may therefore gain no benefit from training with these samples, i.e. not adjust and/or evolve. In another example, the active selection may be defined to exclude samples which are transmitted over transmission channels subject to excessive interference and may be thus characterized by very low SNR. Such low SNR samples are therefore likely to include significant errors making them potentially un-decodable the neural network based decoder. The low SNR samples may therefore also present little and potentially no benefit to training the neural network based decoder since the neural network based decoder may be unable to correctly decode these samples.

The actively selected samples may be therefore in a range defined to exclude samples characterized by too little and/or too high SNR. Moreover, the actively selected samples may be near a decision boundary and/or the decision regions of the neural network based decoder. The SNR alone, however, may be limited as it may not convey the full scope of the samples which may best serve for training the neural network based decoders to achieve improved performance.

To overcome this limitation, one or more metrics may be defined to estimate the benefit of transmitted samples to the training the neural network based decoder and select samples of high benefit accordingly based on mapping a distribution of the samples and selecting such samples according to their mapping. As such, the applied metrics may be indicative of SNR to allow computing estimated SNR indicative values for the samples and selecting a subset of the samples based on the estimated SNR indicative values computed for the samples. In particular, the subset of samples may be selected based on their estimated SNR indicative values with respect to one or more selection thresholds defined to exclude (filter out) high SNR indicative value samples that may be subject to insignificant interference and are hence expected to be correctly decoded and also to exclude low SNR indicative value samples which may be subject to excessive interference and are hence potentially un-decodable.

Several SNR indicative metrics may be applied for computing the estimated SNR indicative values of the samples. For example, the SNR indicative metrics may be based on a Hamming distance computed between each of the explored samples and a respective word (message) encoded by an encoder to produce the training encoded codeword transmitted over the transmission channel subject to interference. In another example, the SNR indicative metrics may be based on one or more reliability parameters computed for each of the explored samples which is indicative of an estimated error of the respective sample. The reliability parameters may include, for example, an Average Bit Probability (ABP), a Mean Bit Cross Entropy (MBCE) and/or the like. In another example, the SNR indicative metrics may be based on a syndrome-guided Expectation-Maximization (EM) parameter computed for each of the explored samples.

After computing the estimated SNR indicative values for at least some of the samples explored for training the neural network based decoder, the subset of samples estimated to provide highest benefit may be selected based on the computed estimated SNR indicative values compared to one or more of the selection thresholds. The subset of samples may be then used for training the neural network based decoder.

The training of the neural network based decoder may be based on one or more methods, techniques and/or models as known in the art, for example, stochastic gradient descent, batch gradient descent, mini-batch gradient descent and/or the like.

The training session may further include a plurality of training iterations where in each iteration one or more of the selection thresholds may be adjusted to further refine the subset of samples selected for training the neural network based decoder.

Moreover, the neural network based decoder may be further trained online when applied to decode one or more new and previously unseen encoded codeword of the error correction code transmitted over a certain transmission channel. As such the neural network based decoder may adapt and adjust to one or more interference patterns typical and/or specific to the certain transmission channel.

Training the neural network based decoders with the actively selected samples may present major advantages and benefits compared to neural network based decoders trained using existing methods.

First, as presented herein after and demonstrated by experiments conducted to evaluate and validate the performance, the performance of the neural network based decoders trained with the actively selected samples may be significantly increased compared to corresponding or similar neural network based decoders trained with randomly selected samples. For example, an inference (recovery) performance improvement of 0.4 dB at the waterfall region, and of up to 1.5 dB at the error-floor region in Frame Error Rate (FER) was achieved by the neural network based decoders trained with the actively selected samples compared to the neural network based decoders trained with randomly selected samples for BCH(63,36) code. This improvement is achieved without increasing inference (decoding) complexity of the neural network based decoders.

Moreover, while the performance of the neural network based decoders trained with the actively selected samples is increased in terms of accuracy, reliability, error immunity and/or the like, the training resources required for training the neural network based decoder may be significantly reduced, for example, training time, computing resources (e.g. processing resources, storage resources, network resources, etc.) may be significantly reduced. This is because redundant and/or useless samples may be excluded from the training dataset while focusing on samples which are estimated to provide the highest benefit for training the neural network based decoder.

According to some embodiments of the present invention, there are provided methods and systems for decoding an encoded error correction code transmitted over a transmission channel subject to interference using an ensemble comprising a plurality of neural networks based decoders. Each of the neural networks based decoders is adapted and trained to decode encoded codewords mapped to a respective one of a plurality of regions constituting a distribution space of the code. This may be accomplished by taking advantage of the active learning concept and training each neural network based decoder of the ensemble with a respective subset of actively selected samples which are mapped to the respective region associated with the respective neural network based decoder.

During training of the ensemble of neural networks based decoders, the distribution space of the training samples of the error correction code is partitioned to the plurality of regions. Each of the neural networks based decoders is associated with a respective regions and is therefore trained with a respective subset of actively selected samples which are mapped to the respective region. Each neural networks based decoder is thus trained to efficiently decode encoded codewords which are mapped into its respective region. In particular, each of the plurality of regions may reflect an SNR range of the samples mapped into the respective region.

The distribution space of the training samples of the error correction code may be partitioned to the plurality of regions based on one or more partitioning metrics applied to compute values for the plurality of samples and map them accordingly to the regions. Since the partitioning may be based on the SNR of the samples, the partitioning metrics may apply one or more of the SNR indicative metrics. For example, the partitioning metrics may be based on the Hamming distance computed for each of the training samples. In another example, the partitioning metrics may be based on one or more of the reliability parameters computed for each of the training samples. In another example, the partitioning metrics may be based on the syndrome-guided EM parameter computed for each of the training samples.

Optionally, one or more of the neural networks based decoders of the ensemble are trained in a plurality of training iterations where in each iteration the neural networks based decoder(s) may be trained with another subset of samples. Moreover, one or more of the weights of the neural network based decoder(s) are updated in case the decoding accuracy of the respective re-trained and updated neural network based decoder is increased compared to a previous iteration.

In run-time, the ensemble may receive an encoded error correction code (codeword) transmitted over a transmission channel subject to one or more of the interferences. One or more mapping functions may be applied to map the received codeword code to one of the plurality of regions. Based on the mapped region, the mapping function(s) may select one of the neural networks based decoders of the ensemble which is associated with the mapped region for decoding the received code.

The mapping function(s) may be implemented using one or more architectures, techniques, methods and/or algorithms. For example, the mapping function(s) may map the received code based on an error estimation of an error pattern of the received code. In another example, the mapping function(s) may apply one or more low complexity decoders, for example, a hard-decision decoder to encode the received code and map it accordingly to one of the regions. In another example, the mapping function(s) may apply one or more neural networks, specifically, a simple and low-complexity neural network trained to encode the received code and map it accordingly to one of the regions.

The received code may be then fed to the selected neural networks based decoder which may decode the code to recover the transmitted message word.

Optionally, the mapping function(s) may feed the received code to multiple and optionally all of the neural networks based decoders of the ensemble which may simultaneously decode the code. Each of the neural networks based decoders may further compute a score reflecting (ranking) an accuracy and/or reliability of the decoded (message) word. The word decoded with the highest score may be than selected as the recovered message word.

As described for the actively selected trained neural network based decoders, one or more of the neural network based decoders of the ensemble may be further trained online when applied to decode one or more received encoded codeword of the error correction code transmitted over a certain transmission channel. As such the ensemble of neural network based decoders may adapt and adjust to one or more interference patterns typical and/or specific to the certain transmission channel.

Applying the ensemble of neural network based decoders, specifically deep neural network based decoders may present major advantages and benefits compared to other implementations of neural network based decoders.

First, each of the neural network based decoders is configured and trained to decode codewords mapped to a specific region of the distribution space of the code. Since each region is significantly limited and small compared to the entire distribution space, each neural network based decoders may adjust to become highly optimized for decoding codewords mapped to the significantly smaller region compared to a single neural network based decoder that need to be capable of decoding codewords spread over the entire distribution space as may be done by the existing methods.

Moreover, since each of the neural network based decoders is configured and trained to decode codewords mapped to the limited region, each of the neural network based decoders of the ensemble may be significantly less complex compared to the single neural network based decoder configured to decode codewords spread over the entire distribution space. The reduced complexity may significantly reduce the latency for decoding the received codeword and/or reduce the computing resources required for decoding the received codeword. In case multiple neural network based decoders of the ensemble are selected to decode the recovered code, the most suitable neural network based decoder optimized for the region of the received code may essentially be also applied to decode the received code. Since the most suitable neural network based decoder may present the best decoding performance, the score computed for its decoded code may be the highest score and the recovered code decoded by the most suitable neural network based decoder may be therefore selected as the final recovered code outputted from the ensemble.

Furthermore, since typically only one of the neural network based decoders of the ensemble may be selected by the mapping function and operated for each received codeword, the computing resources and typically the cost may be further reduced.

In addition, training the reduced complexity neural network based decoders each with a significantly reduced subset of the training dataset may require significantly reduced computing resources. Moreover, the plurality of neural network based decoders of the ensemble may be trained simultaneously in parallel thus reducing training time and possibly training cost.

According to some embodiments of the present invention, partitioning the distribution space of the error correction code for training and using a plurality of neural network based decoders each specialized for a respective region of the distribution space of the error correction code may be done based on an error detection metric applied to the encoded codewords.

To this end, each codeword may be encoded twice (doubly encoded) at the transmitter, first according to one or more error detection codes followed by encoding according to one or more of the error correction codes. As described herein before, the error correction codes used to encode the codewords may include, for example, linear error correction codes such as, for example, block codes, convolutional codes and/or the like as well as non-linear error correction codes. The error correction block codes may include, for example, algebraic linear code, polar code, LDPC code, HDPC code, Hadamard code and/or the like. The error correction convolutional codes may include for example, Tail-Biting code and/or the like.

The error detection codes used for encoding the codewords may include, for example, Cyclic Redundancy Check (CRC) code and/or the like. For example, the error detection code and the error correction code may be chosen according to one or more 5G cellular communication protocols where the error correction code is polar code and the error detection code is CRC.

During training, the distribution space of the error correction code may be divided (partitioned) to a plurality of regions each comprising a limited size portion, segment, section and/or sector of the overall error correction's distribution space. The distribution of codewords of the error correction code may relate to one or more operational parameters, attributes and/or characteristics of the error correction code and may be therefore partitioned based on one or more partitioning metrics, in particular metrics relating to the error detection value of encoded codewords. To this end the encoded codewords may be further encoded for error detection according to the error detection code(s).

Each of the plurality of neural networks based decoders may be then trained, learned, evolve and specialize for decoding encoded codewords mapped to a respective one of the plurality of regions jointly encompassing the entire distribution space.

A plurality of training (data) samples each mapping one or more encoded coders of the error correction code after encoded for error detection may be used for training the plurality of neural network based decoders. Each of the training samples may be mapped to one of the plurality of regions to create and select a plurality of sample subsets each comprising training samples mapped to the same region such that each of the plurality of sample subsets corresponds to a respective one of the plurality of regions.

Each of the neural networks based decoders may be then associated with a respective region and may be trained accordingly using a respective sample subset corresponding to the respective region, i.e., a respective sample subset comprising training samples mapped to the receptive region. As such, after trained, each of the neural networks based decoders may be specialized for decoding encoded codewords mapped to a respective portion (region) of the error correction code distribution space.

Moreover, an ensemble may be constructed to include the plurality of trained neural network based decoders for decoding doubly encoded codewords which may be mapped to one of the plurality of trained neural network decoders based on their error detection value.

In run-time, the ensemble may receive, a transmission channel subject to one or more of the interferences, one or more doubly encoded codewords which are encoded according to an error detection code and further encoded according to an error correction code before transmitted.

One or more mapping functions (also designated gating function, module, etc.) may be applied to map the received (doubly) encoded codeword to one of the plurality of regions of the error correction code's distribution space based on the error detection value computed for the received encoded codeword.

The received encoded codeword may be then fed to the selected neural network based decoder for decoding the received encoded codeword.

As described for the neural network based decoders trained using actively selected training samples, one or more of the neural networks based decoders of the ensemble may be further trained online when applied to decode one or more received encoded codewords transmitted over a certain transmission channel. As such the ensemble of neural networks based decoders may adapt and adjust to one or more interference patterns typical and/or specific to the certain transmission channel.

Applying the ensemble of neural networks based decoders to decode encoded codewords of an error correction code where each decoder is trained for a respective region of the error correction code distribution space partitioned based on error detection values of codewords may present major advantages and benefits compared to other implementations of neural network based decoders.

First, each of the neural networks based decoders may be configured, trained and thus specialized to decode codewords mapped to a specific region of the overall distribution space of the error correction code. This means that each of the neural networks based decoders may be associated (correspond) with a respective region comprising only a limited and typically small portion (segment, section, sector, etc.) of the entire distribution space of the error correction code. Each neural networks based decoder may therefore adjust to become highly optimized (specialized) for decoding codewords mapped to the significantly smaller region associated with the respective decoder compared to a single decoder trained for decoding codewords spread over the entire distribution space as may be done by the existing methods making the single decoder highly inefficient.

Moreover, since each of the neural networks based decoders is configured and trained to decode codewords mapped to the limited region of the error correction code's distribution space, each of the neural networks based decoders of the ensemble may be significantly less complex compared to the single neural network based decoder configured to decode codewords spread over the entire code space. The reduced complexity may significantly reduce the latency for decoding the received codeword and/or reduce the computing resources required for decoding the received codeword which may also reduce deployment cost of the ensemble.

Furthermore, since typically only one of the neural networks based decoders of the ensemble may be selected by the mapping function(s) and operated for decoding each received encoded codeword, the computing resources utilized by the ensemble at any given time may be significantly reduced thus further reducing the cost of the ensemble deployment.

In addition, the computing resources may be significantly reduced since training the reduced complexity neural network based decoders based decoders each with a significantly reduced subset of the training samples datasets. Moreover, the plurality of neural networks based decoders of the ensemble may be trained simultaneously in parallel thus reducing training time and possibly training cost.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

As will be appreciated by one skilled in the art, aspects of the present invention may be embodied as a system, method or computer program product. Accordingly, aspects of the present invention may take the form of an entirely hardware embodiment, an entirely software embodiment (including firmware, resident software, micro-code, etc.) or an embodiment combining software and hardware aspects that may all generally be referred to herein as a “circuit,” “module” or “system.” Furthermore, aspects of the present invention may take the form of a computer program product embodied in one or more computer readable medium(s) having computer readable program code embodied thereon.

Any combination of one or more computer readable medium(s) may be utilized. The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer program code comprising computer readable program instructions embodied on a computer readable medium may be transmitted using any appropriate medium, including but not limited to wireless, wire line, optical fiber cable, RF, etc., or any suitable combination of the foregoing.

The computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

The computer readable program instructions for carrying out operations of the present invention may be written in any combination of one or more programming languages, such as, for example, assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages.

The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

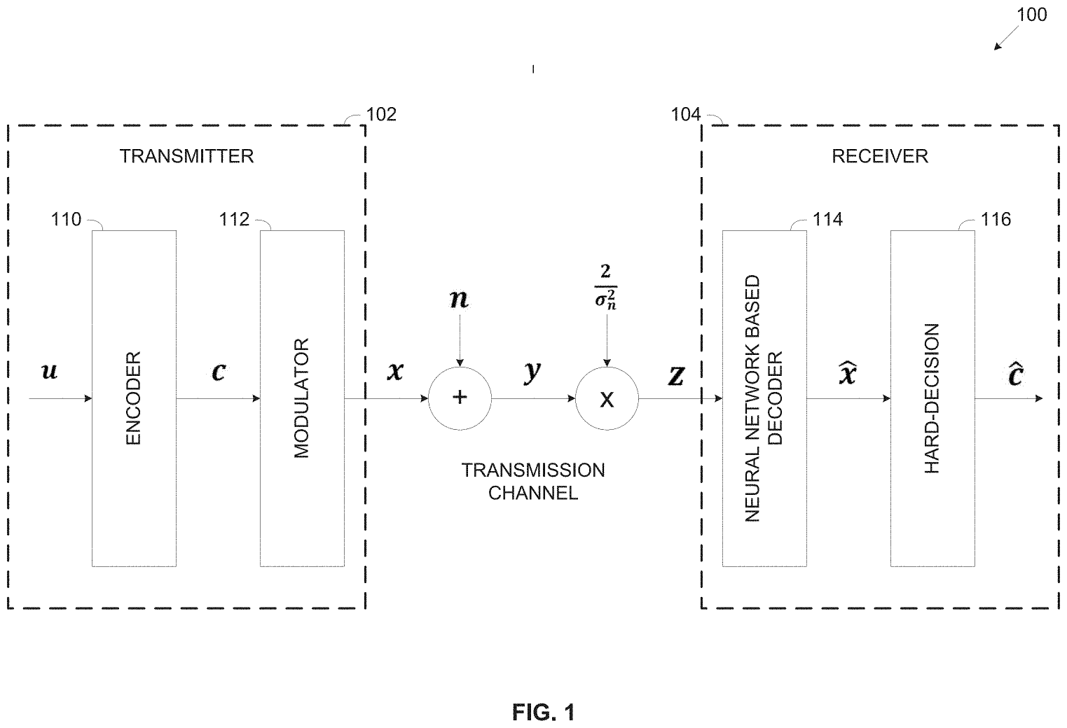

Referring now to the drawings, FIG. 1 illustrates a schematic illustration of an exemplary transmission system comprising a neural network based decoder for decoding an encoded error correction code transmitted over a transmission channel.

An exemplary transmission system 100 as known in the art may include a transmitter 102 configured to transmit data to a receiver 104 via a transmission channel which may comprise one or more wired and/or wireless transmission channels deployed for one or more of a plurality of applications, for example, communication channels, network links, memory interfaces, components interconnections (e.g. bus, switched fabric, etc.) and/or the like. In particular, the transmission channel may be subject to one or more interferences, for example, noise, crosstalk, attenuation, and/or the like which may induce one or more errors into the transmitted data.

The transmitter 102 may include an encoder 110 configured to encode data (message) words according to one or more encoding algorithms and/or protocols. Specifically, in order to support error detection and/or correction, the encoder 110 may encode the message words according to one or more error correction code models and/or protocols as known in the art. The error correction codes, may include, for example, linear block codes such as, for example, algebraic linear code, polar code, LDPC code, HDPC code and/or the like. However, the error correction codes may further include non-block codes, for example, convolutional codes such as, for example, Tail-Biting Convolutional Code (TBCC) and/or the like. While described and demonstrated for linear codes, some embodiments of the present invention may be applied for non-linear codes such as, for example, Hadamard code and/or the like.

The transmitter 102 may further include a modulator 112 which may receive the encoded code from the encoder 110 and modulate the encoded code according to one or more modulation schemes as known in the art, for example, Phase-shift keying (PSK), Binary phase-shift keying (BPSK), Quadrature phase-shift keying (QPSK) and/or the like.

The transmitter 102 may then transmit the modulated code to the receiver 104 via the transmission channel which may be subject to noise.

The receiver 104 may include a decoder 114 configured to decode the modulated encoded code received from the transmitter 102. In particular, the decoder 114 may be a neural network based decoder employing one or more trained neural networks as known in the art, in particular deep neural networks, for example, a CF neural network, a CNN, an FF neural network, an RNN and/or the like. The receiver 104 may further include a hard-decision decoder to demodulate the decoded code and recover the message word originally encoded at the transmitter 102 by the encoder 110.

Each of the elements of the transmission system 100, for example, the neural network based decoder 114, may be implemented using one or more processors executing one or more software modules, using one or more hardware modules (elements), for example, a circuit, a component, an Integrated Circuit (IC), an Application Specific Integrated Circuit (ASIC), a Field Programmable Gate Array (FPGA), an Artificial Intelligence (AI) accelerator and/or the like and/or applying a combination of software module(s) and hardware module(s).

As evident, while the transmission system 100 is presented in very high level and simplistic schematic manner to describe modules, elements, features and functions relevant for the present invention, it is appreciated that full system layout and architecture are apparent to a person skilled in the art will. Moreover, it should be noted that for brevity, some embodiments of the present invention relate to linear codes. This however, should not be construed as limiting since the same methods, systems, algorithms, processes and architecture may be applied to other non-linear and/or non-block error correction codes, such as, for example, convolutional codes, Hadamard code and/or the like. Furthermore, for brevity and clarity, some embodiments of the present invention relate to a transmission channel subject to interference characterized by Additive white Gaussian Noise (AWGN). However, this should not be construed as limiting since the same methods, systems, algorithms, processes and architecture may be applied for transmission channels subject to other interference types, for example, the Rayleigh Fading Channel and the Colored Gaussian Noise Channel.

Before describing at least one embodiment of the present invention, some background is provided for the WBP algorithm which may be used for decoding error correction linear block codes as known in the art.

linear codes, the same methods, systems, algorithms, processes and architecture may be applied to other non-linear and/or non-block error correction codes, such as, for example, convolutional codes, Hadamard code and/or the like

The following text may include mathematical equations and representations which may follow some conventions. Scalars are denoted in italics letters while vectors in bold. Capital and lowercase letters stand for a random vector and its realization, respectively. For example, C and c stand for the codeword random vector and its realization vector. X and Y are the transmitted and received channel words. \hat{X} denotes the decoded modulated-word, while Ĉ denotes the decoded codeword. The i^{th} element of a vector v will be denoted with a subscript vᵢ. As stated herein before, the transmission channel is an AWGN channel characterized by an SNR denoted by ρ for convenience.

An error correction code, for example, a linear block code having a minimum Hamming distance dₘᵢₙ and a code length N may be denoted by [symbol] . Let u denote the message word driven into the encoder 110, x denote the transmitted word after encoded by the encoder 110 and modulated by the modulator 114 in BPSK modulation, and y denote the received word induced with Gaussian noise n˜ [symbol] (0, σₙ²I). It should be noted that rather than decoding the received codeword y, the neural network based decoder 114 may typically decode a received Log Likelihood Ratio (LLR) word z to recover the decoded word denoted ĉ.

Let d(c₁, c₂) (dist(c₁, c₂)) denote the Hamming distance between two codewords c₁ and c₂. Specifically, d_{H} denotes the Hamming distance between the encoded codeword c and the decoded word e. The received word will always be decoded correctly by a hard-decision decoder if the Hamming distance between c and y demodulated by the hard-decision decoder less or equal to

$${t}_{H} = \frac{{d}_{min} - 1}{2} .$$

Let T be a latent binary variable as known in the art, which denotes successful decoding of the neural network based decoder 114, with a value of 1 if c=ĉ which reflects d_{H}=0. Finally, I(X; Y) denotes the mutual information between two random variables, X and Y.

The neural network based decoder 114 may be trained using different parameters as known in the art. Let Γ_{θ}(S) be a distribution over received words Y, parameterized by hyperparameters θ∈Θ set with values S. For example, for brevity let θ be ρ and S=1 dB. Then, a training sample is drawn, specifically for a transmitted all-zero codeword, according to P_{γ}(y;ρ=1). For a batch of independent and identically distributed (i.i.d.) training samples, the entire sampling procedure may be repeated n times, where n is the required batch size and both θ and S may vary in the same batch. A batch sampled according to F may be denoted by y_{γ}.

The Belief Propagation (BP) is an inference algorithm used to efficiently calculate the marginal probabilities of nodes in a graph. The BP algorithm may be further extended for graphs with loops however, in such graphs the calculated probabilities may be approximation only. Such version of the BP is known in the art as the loopy belief propagation.

The neural network utilized by the neural network based decoder 114 may be derived from the BP algorithm, specifically from the WBP algorithm which is a messages passing algorithm which may be constructed from a graphical representation of a parity check matrix describing the encoded code, specifically a bipartite graph, for example, a Tanner graph, a factor graph and/or the like. For brevity the description is directed herein after to the Tanner graph, this, however, should not be construed as limiting since the same may apply for other graph types, specifically other bipartite graph types.

The neural network based decoders 114 constructed based on the graphical representation of the parity check matrix network may comprise an input layer, an output layer and a plurality of hidden layers which are constructed from a plurality of nodes corresponding to transmitted messages over a plurality of edges of the graph where the edges are assigned with learnable weights facilitating the WBP algorithm.

The Tanner graph is an undirected graphical model, constructed of nodes and edges connecting between the nodes. There are two types of nodes, variables nodes each corresponding to a single bit of the received code (codeword) and checks nodes each corresponding to a row in the code's parity check matrix. In message passing based decoders such as the BP algorithm based decoders 114, the messages are transmitted over the edges. An edge exists between a variable v and a check node h if and only if (iff) variable node v participates (has coefficient 1) in the condition defined by the h^{th} row in the parity check matrix. The variable nodes may be initialized according to equation 1 below.

$${z}_{v} = log \frac{P ( {c}_{v} = 0 \vert {y}_{v} )}{P ( {c}_{v} = 1 \vert {y}_{v} )} = \frac{2 {y}_{v}}{{σ}_{n}^{2}} \qquad \underline{Equation 1}$$

Where the subscript v indicates a variable node and z stands for a received LLR value. The last equality is true for AWGN channels with common BPSK mapping to {±1}.

The WBP message passing algorithm proceeds by iteratively passing messages over edges from variable nodes to check nodes and vice versa. The WBP message from node a to node b at iteration i will be denoted by m_{i,(a,b)} with the convention that m_{0,(a,b)}=0 for all a,b combinations.

Variable-to-check (nodes) messages are updated in odd iterations according to the rule expressed in equation 2 below:

$${m}_{i , ( v , h )} = {z}_{v} + {\sum }_{( {h}^{′} , v ) , {h}^{′} \neq h} {m}_{i - 1 , ( {h}^{′} , v )} \qquad \underline{Equation 2}$$

While the check-to-variable (nodes) messages are updated in even iterations according to the rule expressed in equation 3 below:

$${m}_{i , ( h , v )} = 2 arctanh ( {\prod }_{( {v}^{′} , h ) , {v}^{′} \neq v} tanh ( \frac{{m}_{i - 1 , ( {v}^{′} , h )}}{2} ) ) \qquad \underline{Equation 3}$$

Finally, the value of the output variable node may be calculated according to equation 4 below.

$${\hat{x}}_{v} = {z}_{v} + {\sum }_{( {h}^{′} , v ) , {h}^{′} \neq h} {m}_{2 τ , ( h ′ , v )} \qquad \underline{Equation 4}$$

Where τ is the number of BP iterations and all values considered are LLR values.

As known in the art, learnable weights may be assigned to the variable-check message passing rule according to equation 5 below.

$${m}_{i , ( v , h )} = tanh ( \frac{1}{2} ( {w}_{i , v} {z}_{v} + {{\sum }_{( {h}^{′} , v )}}_{{h}^{′} \neq h} {w}_{i , ( {h}^{′} , v , h )} {m}_{i - 1 , ( {h}^{′} , v )} ) ) \qquad \underline{Equation 5}$$

Similarly, weights may be assigned to the output marginalization according to equation 6 below.

$${\hat{x}}_{v} = σ ( - [ {w}_{2 τ + 1 , v} {z}_{v} + {{\sum }_{( {h}^{′} , v )}}_{{h}^{′} \neq h} {w}_{2 τ + 1 , ( {h}^{′} , v )} {m}_{2 τ , ( {h}^{′} , v )} ] ) \qquad \underline{Equation 6}$$

where σ is the sigmoid function.

The set of weights may be denoted by w={w_{i,v},w_{i,(h′,v,h)},w_{i,(v,h′)}}.

It should be noted that no weights are assigned to the check-variable rule, which may be formed according to equation 7 below.

$${m}_{i , ( h , v )} = 2 arctanh ( {\prod }_{( {v}^{′} , h ) , {v}^{′} \neq v} {m}_{i - 1 , ( {v}^{′} , h )} ) \qquad \underline{Equation 7}$$

This form of the check-variable rule is explained by expected numerical instabilities which may be due to the arctan h domain.

The above formulation unfolds the loopy algorithm into a neural network. It may be seen that the hyperbolic tangent function was moved from the check-variable rule to scale the message to a reasonable output range. A sigmoid function may be used to scale the LLR values into a range of [0,1]. An output value in the range [0.5,1] is considered a ‘1’ bit while an output value in the range [0,0.5] is considered a ‘0’ (an output value which equals 0.5 is randomly attributed to the ‘0’ bit).

Training the neural network may be done, as known in the art, using Binary Cross Entropy (BCE) multi-loss as expressed in equation 8 below.

$$L ( c , \hat{c} ) = - \frac{1}{V} {{\sum }_{t = 1}}^{τ} {{\sum }_{v = 1}}^{V} [ {c}_{v} log {\hat{c}}_{v , t} + ( 1 - {c}_{v} ) log ( 1 - {\hat{c}}_{v , t} ) ] \qquad \underline{Equation 8}$$

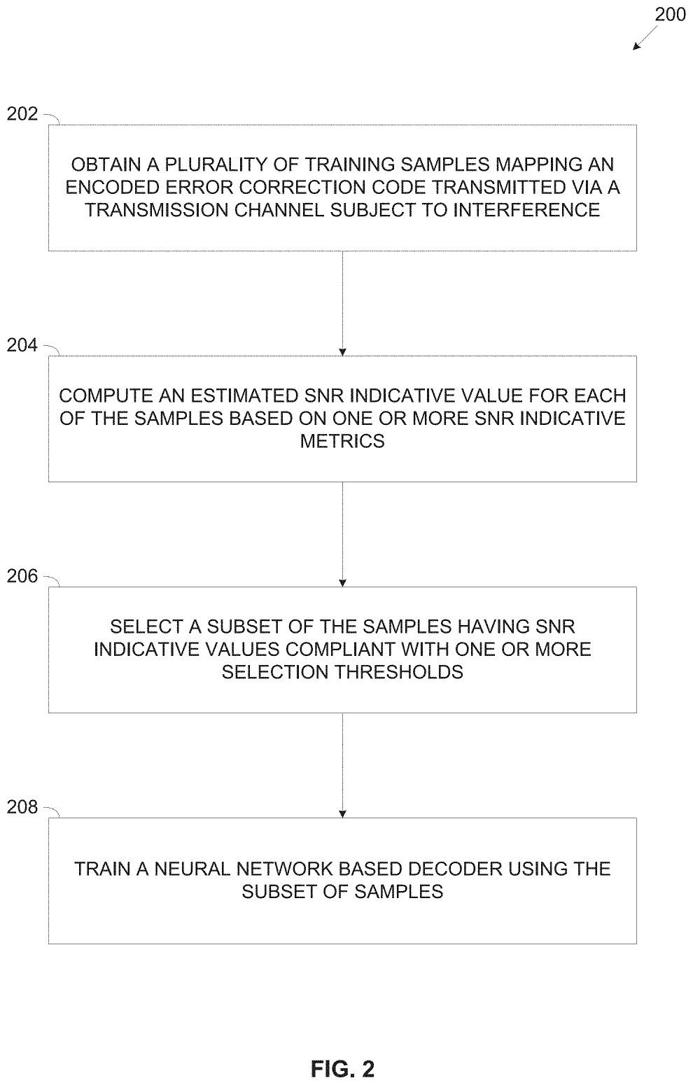

Reference is now made to FIG. 2, which is a flowchart of an exemplary process of training a neural network based decoder 114 to decode an encoded error correction code using actively selected training samples, according to some embodiments of the present invention.

An exemplary process 200 may be executed to train one or more neural network based decoders such as the neural network based decoder 114 to decode one or more error correction codes, for example, linear block codes such as, for example, algebraic linear code, polar code, LDPC and HDPC codes, non-block codes such as, for example, convolutional codes and/or non-linear codes, such as, for example, Hadamard code.

Training the neural network based decoder 114 may be done by applying active learning in which the training dataset(s) may comprise actively selected training samples estimated to provide significantly increased benefit and contribution to the training of the neural network based decoder 114. As such the neural network based decoder 114 may present significantly improved decoding performance, for example, increased accuracy, increased reliability, reduced error rate, and/or the like.

In particular, the contribution and benefit of the sample words to the training of the neural network based decoder 114 may be evaluated based on the SNR of the samples which may be quantized using one or more SNR parameters, in particular, SNR indicative metrics. The SNR indicative metrics introduced herein after may be indicative (informative) of the SNR of each evaluated sample and may be therefore used to evaluate the SNR of each sample and hence the potential contribution and benefit of each sample to the training of the neural network based decoder 114.

Moreover, the training process 200 may be a stream based iterative process in which in each training iteration another batch or subset of samples is selected and used to further train the neural network based decoder 114.

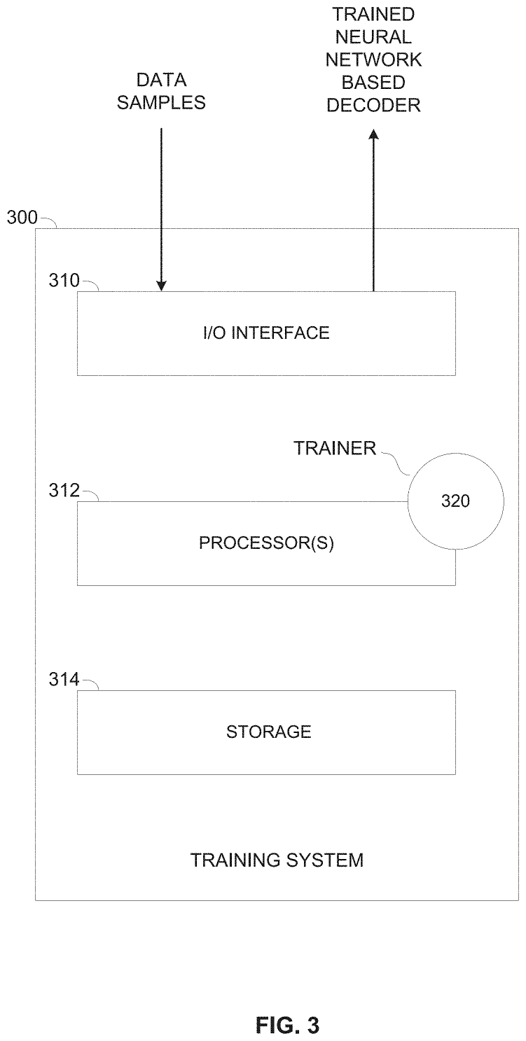

Reference is also made to FIG. 3, which is a schematic illustration of an exemplary system for training a neural network based decoder such as the neural network based decoder 114 to decode an encoded error correction code using actively selected training samples, according to some embodiments of the present invention.

An exemplary training system 300 may comprise an Input/Output (I/O) interface 310, a processor(s) 312 for executing a process such as the process 200 and a storage 314 for storing code (program store) and/or data.

The I/O interface 310 may comprise one or more wired and/or wireless interfaces, for example, a Universal Serial Bus (USB) interface, a serial interface, a Radio Frequency (RF) interface, a Bluetooth interface and/or the like. The I/O interface 210 may further include one or more network and/or communication interfaces for connecting to one or more wired and/or wireless networks, for example, a Local Area Network (LAN), a Wireless Local Area Network (WLAN), a Wide Area Network (WAN), a Municipal Area Network (MAN), a cellular network, the internet and/or the like.

The processor(s) 312, homogenous or heterogeneous, may include one or more processing nodes arranged for parallel processing, as clusters and/or as one or more multi core processor(s). The storage 314 may include one or more non-transitory memory devices, either persistent non-volatile devices, for example, a hard drive, a solid state drive (SSD), a magnetic disk, a Flash array and/or the like and/or volatile devices, for example, a Random Access Memory (RAM) device, a cache memory and/or the like. The storage 314 may further include one or more network storage resources, for example, a storage server, a network accessible storage (NAS), a network drive, a cloud storage and/or the like accessible via the network interface 310.

The processor(s) 312 may execute one or more software modules, for example, a process, a script, an application, an agent, a utility, a tool and/or the like each comprising a plurality of program instructions stored in a non-transitory medium such as the storage 314 and executed by one or more processors such as the processor(s) 312. The processor(s) 312 may further include, integrate and/or utilize one or more hardware modules (elements integrated and/or utilized in the task management system 200, for example, a circuit, a component, an IC, an ASIC, an FPGA, an AI accelerator and/or the like).

[1] As such, the processor(s) 312 may execute one or more functional modules utilized by one or more software modules, one or more of the hardware modules and/or a combination thereof. For example, the processor(s) 312 may execute a trainer 320 functional module for executing the process 200.

As shown at 202, the process 200 starts with the trainer 320 receiving a plurality of data samples each mapping an encoded codeword of an error correction code transmitted over a transmission channel subject to interference, for example, noise, crosstalk, attenuation and/or the like. In particular, each of the encoded codeword (data) samples which may be subject to a different interference pattern.

The encoded codeword samples may be used as training samples for training one or more neural network based decoders such as the neural network based decoder 114.

Optionally, each of the plurality of training samples maps the zero codeword (all zero) may not degrade the performance of the trained neural networks based decoder 114 since the WBP architecture of the neural network based decoder 114 may guarantee the same error rate for any chosen transmitted codeword.

The trainer 320 may receive the data samples via the I/O interface 310 from one or more sources. For example, the trainer 320 may receive the data samples and/or part thereof from one or more remote networked resources connected to one or more of the networks to which the I/O interface 310 is connected, for example, a remote server, a cloud service, a cloud platform and/or the like. In another example, the trainer 320 may retrieve the data samples and/or part thereof from one or more attachable storage mediums attached to the I/O interface 310, for example, an attachable storage device, an attachable processing device and/or the like.

As known in the art, since data is highly available in the data transmission and error decoding field, various approaches, methodologies and methods may be applied to select the training samples used to train the neural network based decoders 114.

For example, multiple neural network based decoders 114 may be trained each with data drawn from Γ_{ρ}(i) where −4≤i≤8, i∈ [symbol] , The NVE(ρₜ, ρᵥ) (Normalized [symbol] Validation Error) measure as known in the art may be then used to compare between the trained neural network based decoder models. As may be noticed, the neural network based decoder models may diverge when trained using only correct or noisy words, drawn from high or low SNR, respectively. Some existing methods known in the art suggest guidelines for choosing pt such that the training set used to train the neural network based decoder 114 set comprised samples from y which are near the decision boundary.

Some guidelines may be also set for selecting the neural network based decoder models. For example, a hidden assumption as known in the art is that y_{γ} which are drawn from Γ_{ρ}(S₁) and Γ_{ρ}(S₂) (S₁≠S₂) may require different decoder weights, w₁, w₂. It may be observed that knowledge possession of ρᵥ may also be mandatory for LLR-based decoders since an estimate is required to compute LLRs. As such, a mutual information inequality expressed in equation 9 below may apply for the neural network based decoder models.

$$I ( Y , {ρ}_{v} \text{;} T ) {=}^{( a )} I ( Y ; T ) + I ( {ρ}_{v} \text{;} T \vert Y ) {\geq }^{( b )} I ( Y \text{;} T ) \qquad \underline{Equation 9}$$

where (a) follows from the mutual information chain rule, and (b) follows from the non-negativity of mutual information.

As such, the additional information of ρᵥ may only aid and improve the decoding performance of the neural network based decoder 114 and may not degrade it. This information of the transmission channel and the neural network based decoder 114 distributions, conditioned on the received word, may be non-zero for sub-optimal decoders. As known in the art, inference (decoding) of the received word may not only require knowledge of ρᵥ but may further depend on ρᵥ. In other words, the neural network based decoder model is data dependent.

As shown at 204, the trainer 320 may compute an estimated SNR indicative value for each of the data samples based on one or more SNR indicative metrics.

Since the performance of the neural network based decoder 114 may significantly depend on the training samples, one or more metrics may be defined to explore the data space and identify and select training samples which may provide highest benefit to the trained neural network based decoder 114 thus significantly increasing its performance.

In particular, since the contribution of the samples may significantly depend of their SNR, the metrics may be SNR indicative metrics which may be used to compute an SNR indicative value for the samples and select the most beneficial training samples. For example, training samples having high SNR indicative values may be subject to insignificant interference and are thus expected to be easily and correctly decoded by the neural network based decoder 114. Such high SNR samples may be therefore excluded from the training dataset. In another example, training samples having low SNR indicative values may be subject to excessive interference and may be therefore potentially un-decodable by the neural network based decoder 114. Such low SNR samples may be also excluded from the training dataset.

A new distribution Γ_{new} may be defined as a distribution of words (codewords) which may be used as training samples for training the neural network based decoder 114 to achieve as high decoding performance as possible. Let κ denote the contribution of a word, in the training phase, to the validation decoding performance such that higher contribution words may be associated with higher κ value. The goal is therefore to identify and define parameters θ∈Θ and corresponding values S defining words distribution Γ₀(S) such that the κ value integrated over the distribution is maximized, for example, as expressed in equation 10 below.

arg max_{θ,S}∫_{y∈Γ}_{_{θ}}_{(S)}κ(y) Equation 10:

The solution to equation 10 may be intractable due to the infinite number of such parameters and values. As such, a heuristic-based solution may be required. Specifically, the parameters may be selected based on availability of vast decoding knowledge while using the above insights, i.e., the SNR of the words. In particular, y_{γ} should be neither too noisy nor absolutely correct and should lie close to the decision boundary.

As stated herein before, the embodiments are presented for an AWGN transmission channel. Therefore, parameters θ′ may be searched which limit the feasible y_{γ} of the channel distribution Γ_{ρ}(S), associated with K_{ρ}(S) to Γ_{ρ,θ},(S, A) and associated with higher K_{ρ,θ},(S, A), where K_{θ}(S) is denoted K_{θ}(S)=∫_{y∈Γ}_{_{θ}}_{(S)}κ(y).

Some received words may be un-decodable due to locality of the WBP decoding algorithm, the Tanner graph structure induced by the parity-check matrix and/or a high Hamming distance. By sampling from specific Γ_{ρ,d}_{_{H}}(S, A) the number of erroneous bits in y may be easily controlled.

A first SNR indicative metric may be therefore the Hamming distance since identifying and selecting encoded codewords samples having a reasonable predefined Hamming distance between them and the transmitted words may decrease the amount of un-decodable words in F.

Based on the Hamming distance metric, the trainer 320 may compute the estimated SNR indicative value for each of the received codeword samples z by computing the Hamming distance between the respective sample and a respective word u encoded by an encoder such as the encoder 110 to produce the received encoded codeword z.

A second SNR indicative metric may include one or more reliability parameters computed and/or identified for each of the received encoded codeword samples.

Soft in soft out (SISO) decoding compose the received signal to n LLR values, {z₁, . . . , zₙ}. In general zᵥ∈(−∞, ∞) but in practice the value zᵥ may be limited by selecting (choosing) appropriate threshold. The closer the zᵥ to 0, the less reliable it may be. Mapping the LLR values to bits may be considered in two steps. First, the LLR values may be mapped to probabilities according to equation 11 below.

Π_{LLR→Pr}(zᵢ)=σ(−zᵢ) Equation 11:

The probabilities may be then mapped into corresponding bits according to a rule expressed in equation 12 below.

$${Π}_{P r \to b i t} ( {\tilde{z}}_{i} ) = \{ \begin{matrix}1 , if {\tilde{z}}_{i} > 0.5 \\ 0 , otherwise\end{matrix} \qquad \underline{Equation 12}$$

The process of direct quantization from LLR values to corresponding bits may be referred as hard decision (HD) decoding according to equation 13 below.

Π_{HD}(zᵢ)=Π_{Pr→bit}(Π_{LLR→Pr}(zᵢ)) Equation 13:

Obviously there is information loss in the process as evident from equation 14 below.

Π_{HD}(z₁)=Π_{HD}(z₂) [symbol] z₁=z₂ Equation 14:

One reliability parameter which may be used to quantify reliability of a given z sample may be an Average Bit Probability (ABP) which may represent a deviation of probabilities of each bit of the respective sample z from a respective bit of a word u encoded by the encoder 110 to produce the at least one training encoded codeword z.

The trainer 320 may compute the SNR indicative value for each sample based on the ABP parameter according to equation 15 below.

$${η}_{A B P} ( {c}_{i} , {z}_{i} ) = \frac{1}{N} {\sum }_{i = 1}^{N} \vert {c}_{i} - {Π}_{L L R \to P r} ( {z}_{i} ) \vert \qquad \underline{Equation 15}$$

Another reliability parameter which may be used to quantify the reliability of a given z sample may be a Mean Bit Cross Entropy (MBCE) which may represent a distance between a probabilities distribution at the encoder 110 (of a transmitter such as the transmitter 102) and the probabilities distribution at the neural network based decoder 114 (of a receiver such as the receiver 104).

The trainer 320 may compute the SNR indicative value for each sample based on the MBCE parameter according to equation 16 below.

$${ℓ}_{MBCE} ( {c}_{i} , {z}_{i} ) = \frac{1}{N} {\sum }_{i = 1}^{N} \vert {c}_{i} \cdot log {Π}_{L L R \to P r} ( {z}_{i} ) + ( 1 - {c}_{i} ) \cdot log ( 1 - {Π}_{L L R \to P r} ( {z}_{i} ) ) \vert \qquad \underline{Equation 16}$$

By limiting the distribution to [symbol] (S, A₁, A₂), the trainer 320 may have better control of the distribution of y, and consequently of z, such that y_{γ} has higher κ on average. The guiding intuition, again, is that higher K words may lie close to the decision boundaries. As known in the art, A₁,A₂ may be chosen such that [symbol] (S, A₁, A₂) is maximized.

A third SNR indicative metric may include a syndrome-guided Expectation-Maximization (EM) parameter computed and/or identified for each of the received encoded codeword samples. The syndrome-guided EM parameter computed for an estimated error pattern of each sample may map the respective sample with respect to an EM cluster center computed for at least some of the plurality of samples. This means that as the trainer 320 processes the samples, the computed syndrome-guided EM values of the samples may be aggregated to form the EM cluster center.

The trainer 320 may thus compute the SNR indicative value based on the syndrome-guided EM metric by computing the syndrome-guided EM metric value for each newly processed sample thus mapping it with respect to the EM cluster center.

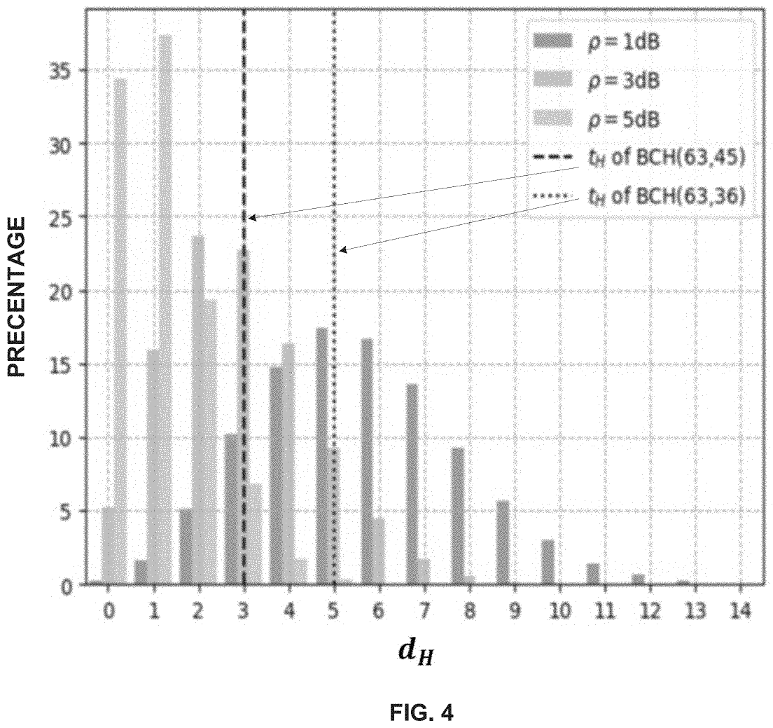

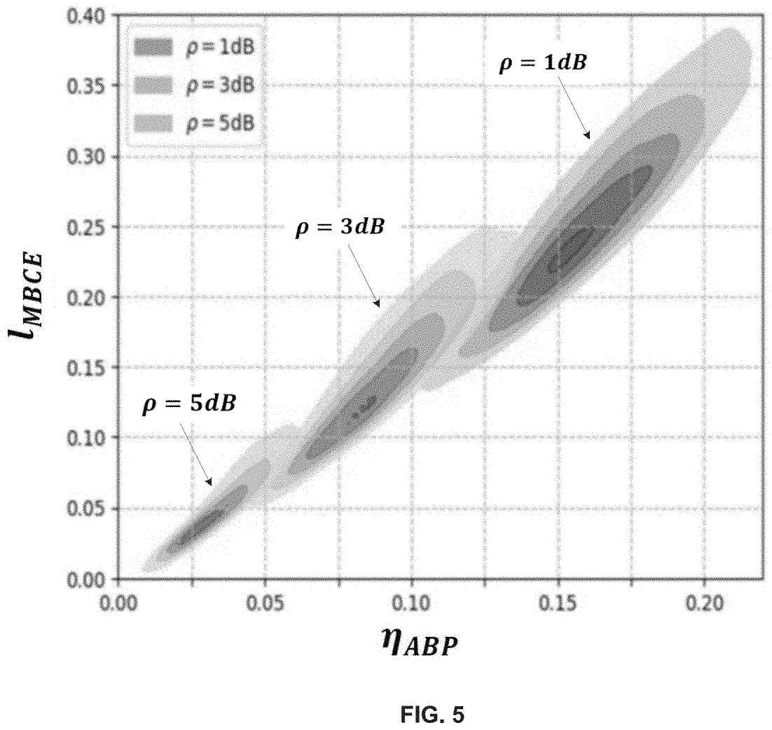

Reference is now made to FIG. 4, which is a graph chart of a Hamming distance distribution of training samples for various SNR values, according to some embodiments of the present invention. Reference is also made to FIG. 5, which is a graph chart of a reliability parameter distribution of training samples for various SNR values, according to some embodiments of the present invention.

FIG. 4 and FIG. 5 present a correlation of the Hamming distance and the reliability parameters to p and T for an exemplary linear block code, for example, BCH963,36), BCH(63,45) and/or the like. In both figures, 100,000 codewords were simulated per ρ on a code (codeword) with length of 63 bits.

As seen in FIG. 4, each ρ defines a different probability distribution of d_{H} values. This distribution may be unique for each code length and each simulated ρ. The higher the SNR, the lower the d_{H} center of this probability distribution. High ρ may include a high amount (number) of no errors frames, while low p value may induce many high noise received words with d_{H} higher than t_{H}. Both t_{H} values for the two codes BCH(63,36) and BCH(63,45) are also plotted with respective dashed lines.

As seen in FIG. 5, each ρ defines a probability distribution over the two reliability parameters, ABP and MBCE such that the higher the p, the closer the distribution is to the origin. Here, no threshold is defined for correct and highly incorrect words, y, as in FIG. 4, thus samples from this probability distribution must be selected much more carefully.

Reference is made once again to FIG. 2.

As shown at 206, the trainer 320 may select a subset of the samples based on the SNR indicative value computed for each of the codeword samples based on one or more of the SNR indicative metrics, specifically, the Hamming distance, the reliability parameters and/or the syndrome-guided EM parameter. In particular, the trainer 320 may select the subset of samples based on compliance of the SNR indicative value computed for each of the samples with one or more thresholds (levels) defined for selecting the most beneficial samples.

With respect to the Hamming distance metric, experiments were conducted to demonstrate and justify the Hamming based SNR indicative metric. A (WBP) neural network based decoder 114 was trained without any correct received words, for which d_{H}=0, and without high noise words, i.e., words having a d_{H}>t_{H} where t_{H} is the error correction capability of the given code. Therefore, t_{H} expresses the maximal number of erroneous bits that can be corrected by a hard-decision decoder. The results show an improvement of up to 0.5 dB when training the neural network based decoder 114 using the actively selected training samples compared to randomly selecting training samples. Moreover, by selecting (drawing) samples according to a distribution based on the Hamming distance as opposed to according to the SNR, the trainer 320 may have further control on training words' properties.

Pseudo-code excerpt 1 below presents an exemplary algorithm which may be applied by the trainer 320 to compute the SNR indicative values for the plurality of received samples based on the Hamming distance metric and actively select a subset of samples which are estimated to provide highest benefit for training the trained neural network based decoder 114 thus significantly increasing its performance.

Pseudo-Code Excerpt 1:

| Initialization: | decoder DEC as known in the art |
|---|---|
| Input: | current decoder DEC S = {s₁, ... ., sₙ} |
| | set of SNR values |
| | A = {1, ... ., dₘₐₓ} set of d_{H} values |
| | c encoded word |
| Output: | improved model DEC |
| 1 | SampleByDistance (DEC, S, A, c) |
| 2 | while error decreases do |
| 3 | sample batch Q from Γ_{p, d}_{_{H}} (S, A); |
| 4 | for y in Q do |
| 5 | dᵢₙ ← dist(Π_{HD} (y), c); |
| 6 | dₒᵤₜ ← dist(ĉ, c); |
| 7 | if dₒᵤₜ = 0 or dₒᵤₜ ≥ dᵢₙ then |
| 8 | Q ← Q\y; |
| 9 | end |
| 10 | DEC ← update model based on Q; |
| 11 | end |
| 12 | return DEC; |

The algorithm described in pseudo-code excerpt 1 is an iterative process, where at each iteration (time step), the current neural network based decoder model (line 6) determines the next queried batch, i.e., selects the subset of samples to be used for the next training iteration (line 8) for the model update (line 10). This algorithm is based on the notion presented herein before to exclude (remove) successfully decoded y samples in addition to excluding highly noisy y samples from the subset used for training (lines 7-8). The excluded sample words may be far from the decision boundary and may thus degrade the training and hence may reduce performance of the trained neural network based decoder. On one hand, the real signal (codeword) may be nearly impossible to be recovered from a very noisy y samples, thus the learning signal towards a minima may be very low. On the other hand, for very reliable y samples, the learning signal may be also low since for every direction of decision the neural network based decoder 114 may take, these reliable samples may be decoded successfully and are thus not informative for the learning process.

Pseudo-code excerpt 2 below presents an exemplary algorithm which may be applied by the trainer 320 to compute the SNR indicative values for the plurality of received samples based on the reliability parameters and actively select a subset of samples which are estimated to provide highest benefit for training the trained neural network based decoder 114 thus significantly increasing its performance.

Pseudo-Code Excerpt 2:

| Initialization: | decoder DEC as known in the art |
|---|---|
| Input: | current decoder DEC S = {s₁, ... ., sₙ} |
| | set of SNR values |
| | A = {1, ... ., dₘₐₓ} set of d_{H} values |
| | c encoded word |
| Output: | improved model DEC |
| 1 | SampleByDistance (DEC, S, A, c) |
| 2 | μ, Σ ← Choose Prior (S, c) |
| 3 | while error decreases do |
| 4 | sample batch Q from Γ_{p, d}_{_{H}} (S, A); |
| 5 | η_{ABP} ← calculate according to |
| | equation 15 per sample; |
| 6 | [symbol] _{MBCE} ← calculate according to |
| | equation 16 per sample; |
| 7 | θ ← [η_{ABP}, [symbol] _{MBCE}]; |
| 8 | w ← ƒ (θ\|μ, Σ); |
| 9 | \tilde{w} ← w/\|\|w\|\|₁; |
| 10 | \tilde{Q} ← random sampling b |
| | words from Q w.p \tilde{w}; |
| 11 | DEC ← update model based on Q; |
| 12 | end |
| 13 | return DEC; |

The algorithm described in pseudo-code excerpt 2 is also an iterative process where in each iteration another subset of samples is selected. As seen, a distribution [symbol] (S, A₁, A₂) is first computed for several untrained BP neural network based decoders 114 with different number of iterations τₛₑₜ={τ₁, . . . , τᵣ} empirically. The trainer 320 may select (query) each subset (batch) by setting a prior on η_{ABP}, [symbol] _{MBCE}. Firstly, the prior may be chosen as a Normal distribution with expectation, μ, and covariance matrix, Σ, over y samples that are decodable by adding iterations to the standard BP neural network based decoders 114. The trainer 320 may select the prior using an algorithm described in pseudo-code excerpt 3 below. These y samples are assumed to be close to the decision boundaries, since BP neural network based decoders 114 with additional iterations are able to decode these samples. The WBP neural network based decoders 114 may compensate for these additional iterations by training using the actively selected samples subset. Secondly, in the algorithm described in pseudo-code excerpt 2, the trainer 320 may select (query) the subset (batch) by performing several trivial steps (lines 4-9). The last step (line 10) includes random sampling of a given size batch by the normalized weights as the probabilities, without replacement.

One important distinction is that the uncertainty sampling method is typically performed over the output signal of the neural model, while the method presented in pseudo-code excerpt 2 applies the sampling over the input signal. That is because for the uncertainty sampling, the multiple BP neural network based decoders are the baseline for improvement, not the WBP (weighted) based decoder.

As shown at 208, the trainer may train one or more neural network based decoders such as the neural network based decoder 114 using the subset of samples selected according to their SNR indicative values computed based on one or more of the SNR indicative metrics.

The trainer may apply one or more training algorithms, methods and/or paradigms as known in the art for training the neural network based decoder 114, for example, stochastic gradient descent, batch gradient descent, mini-batch gradient descent and/or the like.

As stated herein before, the process 200 may be an iterative process comprising a plurality of training iterations. However, since the neural network based decoder 114 may evolve during the training, its decision regions may be altered accordingly, specifically, the optimal θ,S used to select the samples subset may change between iterations.

Therefore, in order to train the neural network based decoder 114 with samples y which are close to the decision boundaries in each iteration, the distribution Γ₀(S) must be adjusted and selected accordingly in each iteration. This is an essential feature of the active learning. As such, in each training iteration, the trainer 320 may adjust one or more of the selection thresholds to select, in each iteration, an effective subset of samples over the distribution Γ_{θ}(S). In each iteration, the trainer 320 may use the respective subset of samples selected in the respective training iteration to further train the neural network based decoder 114.

Moreover, the neural network based decoder(s) 114 may be further trained online when applied to decode one or more new and previously unseen encoded codewords of the error correction code transmitted over a certain transmission channel. This may allow for adaptation of the neural network based decoder 114 to one or more interference pattern specific to the transmission channel applicable to the specific trained neural network based decoder 114.

Performance of a neural network based decoder 114 trained according to the active learning approach was evaluated through a set of experiments. Following are test results for the neural network based decoder 114 trained using the actively selected training samples for several short linear block codes, specifically BCH(63,45), BCH(63,36) and BCH(127,64) with t_{H}=3, t_{H}=5 and t_{H}=10, respectively.

In particular, the evaluated neural network based decoder 114 employs A Cycle-Reduced (CR) parity-check matrices as known in the art, thus evaluating the active learning training in difficult and extreme scenarios in which the number of short cycles is already small and improvement by altering weights is harder to achieve. Since major improvement is demonstrated for such difficult scenarios, applying the active learning training for lower complexity scenarios may yield even better performance increase compared to the traditional training methods.

The number of iterations is chosen as 5 which follows a benchmark in the field as known in the art. The zero codeword is used for training which imposes no limitation due to symmetry and independence of performance of the WBP based decoder from the data. The zero codeword also serves as the codeword in the algorithms presented in pseudo-code excerpts 1 and 2. All hyperparameters relevant to the training are summarized in Table 1 below.

TABLE 1

| Hyperparameters | Values |
|---|---|
| Architecture | Feed Forward |
| Initialization | As known in the art (*) |
| Loss Function | BCE with Multi-loss |
| Optimizer | RMSPROP |
| Pt range | 4dB to 7dB |
| Learning Rate | 0.01 |
| Batch (Subset) Size | 1250 / 300 words per SNR (**) |
| Messages Range | (−10,10) |

(*) Wix in equations 5 and 6 are set to constant 1 since no additional improvement was observed.
(**) for 63 / 127 code length, respectively.

All WBP neural network based decoders 114 are trained until convergence. Two of the SNR indicative metrics were applied to select the subsets of samples used for the training, specifically, the Hamming distance and the reliability parameters. Regarding the active learning hyperparameters, for the Hamming distance approach, and in order to maintain consistency, the same dₘₐₓ was chosen for the two short codes. All hyperparameters are summarized in Table 2 below. In addition, a combined selection approach is introduced, a reliability & d_{H} filtering, in which the distance d_{H} filtering is applied to the reliability parameters based approach.

TABLE 2

| | | CR-BCH | CR-BCH |
|---|---|---|---|
| Method | Hyperparameters | N = 63 | N = 127 |
| Hamming Distance | dₘₐₓ | 2 | 4 |
| *Reliability | τₛₑₜ | {5, 7, 10, 15} | |
| | μ | (0.025, 0.1) | (0.03, 0.1) |
| | Σ | $[ \begin{matrix}6 .25 \cdot {10}^{- 4} & 0 \\ 0 & 5.625 \cdot {10}^{- 3}\end{matrix} ]$ | |
| *Reliability & d_{H} | dₘₐₓ | 3 | 5 |
| filtering | τₛₑₜ | {5, 7, 10, 15} | |
| | μ | (0.025, 0.1) | (0.03, 0.1) |

| | |
|---|---|
| Σ | $[ \begin{matrix}6 .25 \cdot {10}^{- 4} & 0 \\ 0 & 5.625 \cdot {10}^{- 3}\end{matrix} ]$ |

The WBP neural network based decoders 114 were simulated over a validation set of 1 dB to 10 dB until at least 1000 errors are accumulated at each given point. In addition, the syndrome based early termination is adopted, since it was observed that some correctly decoded codewords were misclassified again by the following layers. This may also benefit complexity since the average number of iterations is less than or equal to 5 when using this rule.

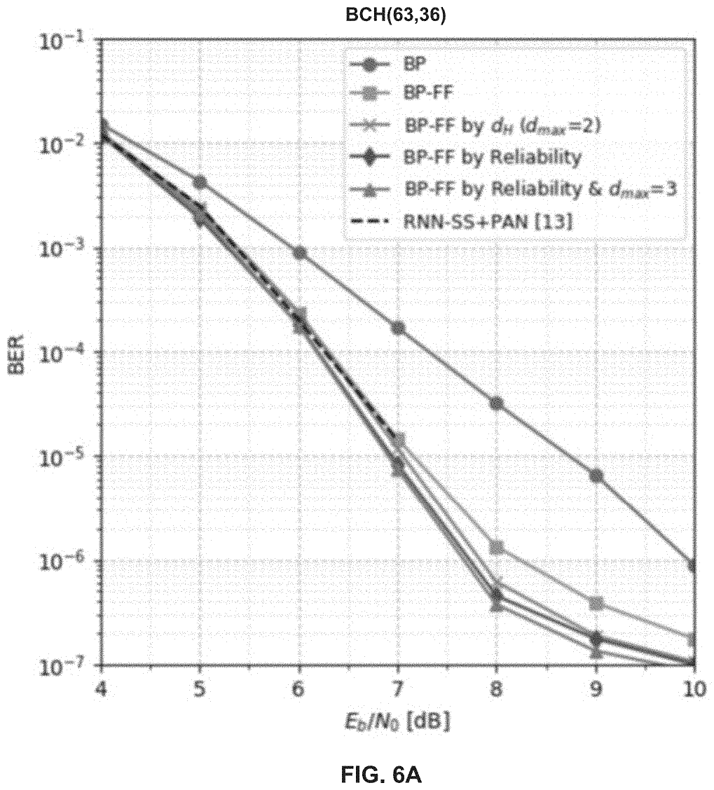

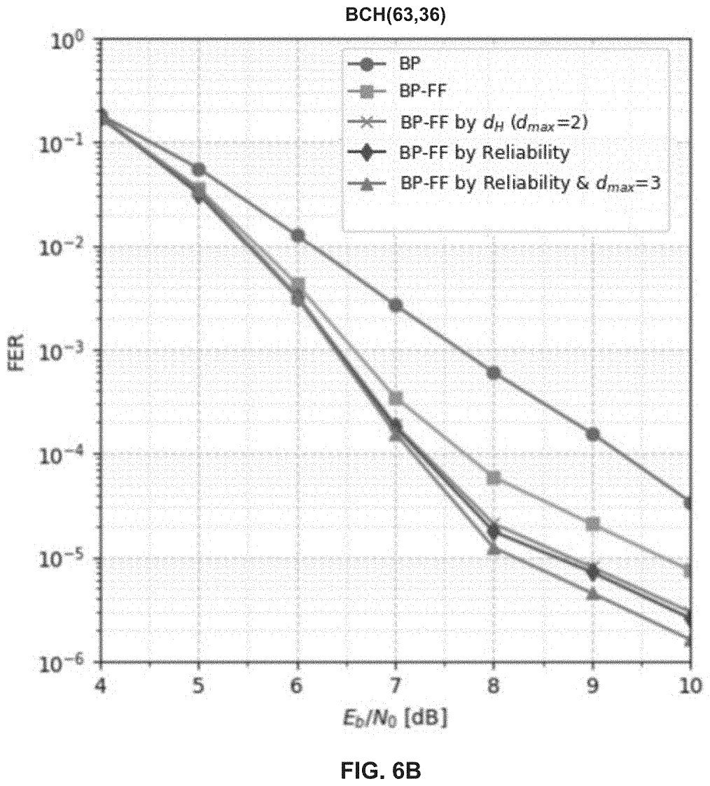

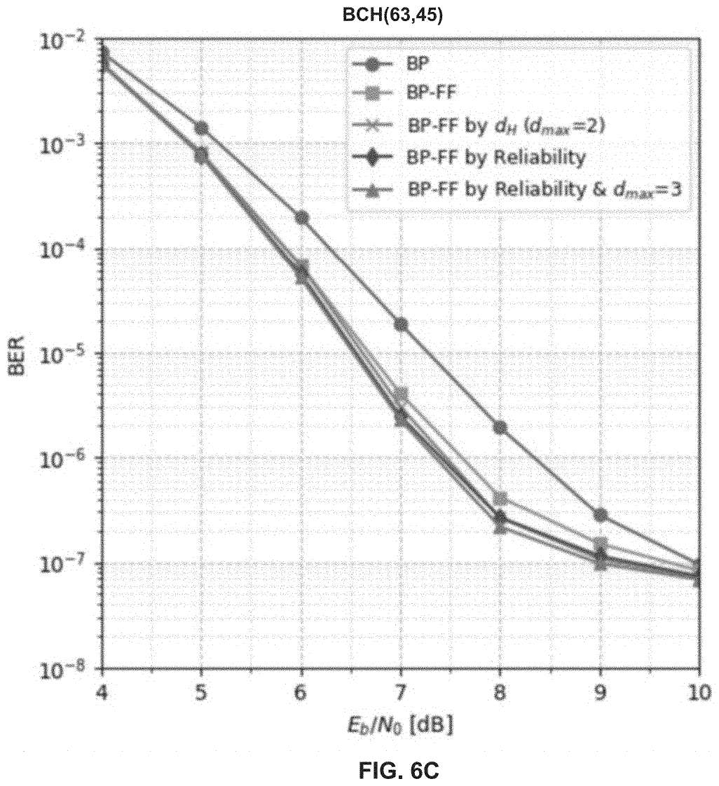

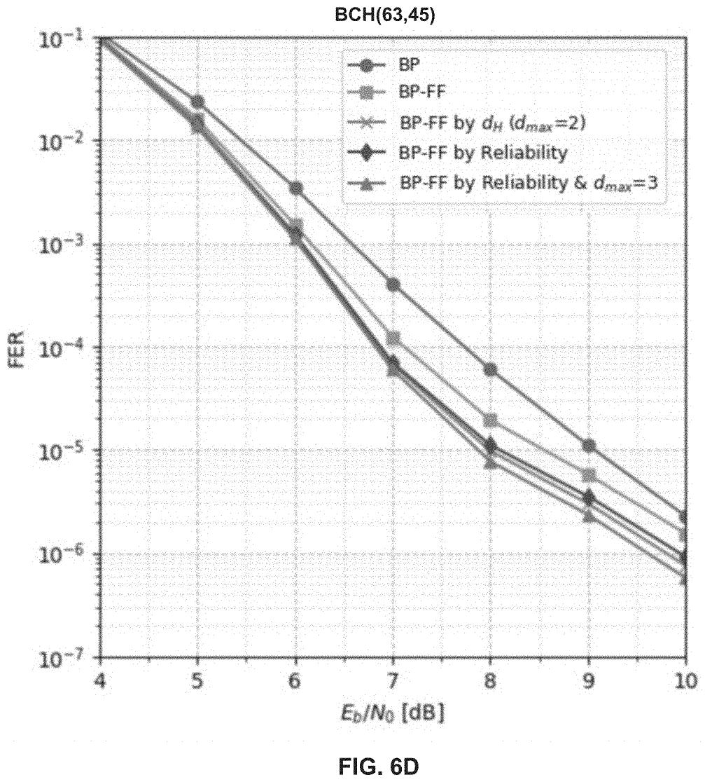

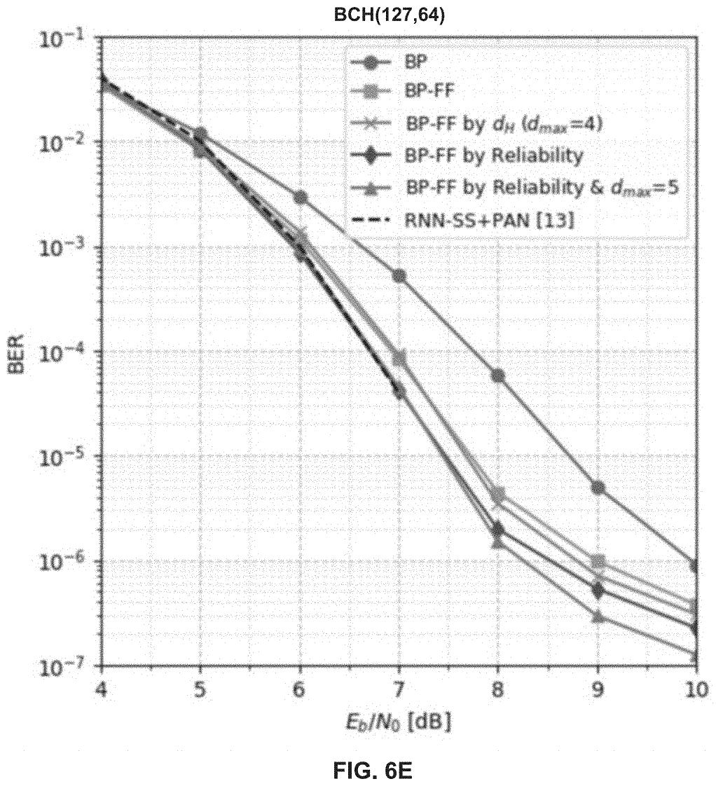

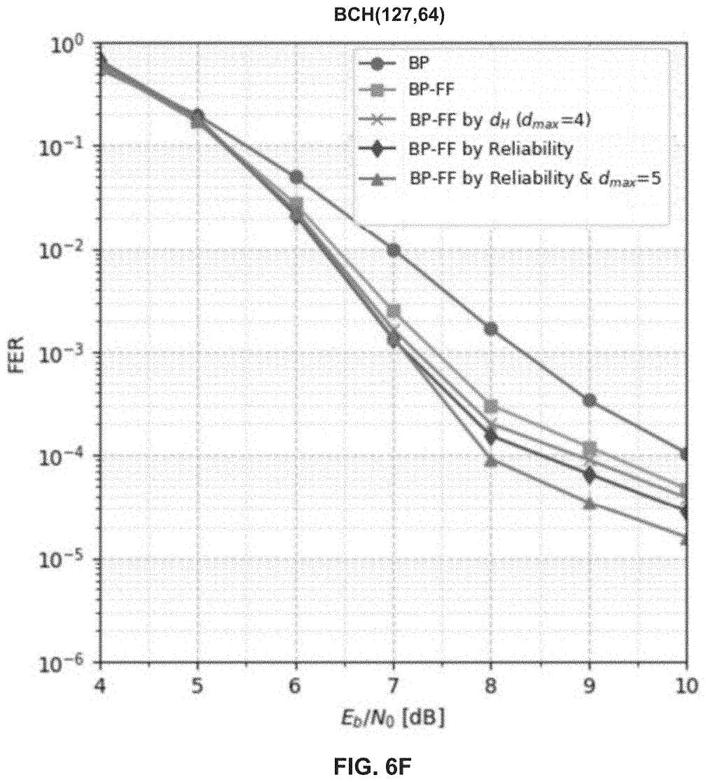

Results for the simulations are presented in FIG. 6A, FIG. 6B, FIG. 6C, FIG. 6D, FIG. 6E and FIG. 6F, which are graph charts of BER and FER results of a neural network based decoder trained with actively selected training samples applied to decode BCH(63,36), BCH(63,45) and BCH(127,64) encoded linear block codes, according to some embodiments of the present invention.

The graph charts in FIG. 6A, FIG. 6B, FIG. 6C, FIG. 6D, FIG. 6E and FIG. 6F present a comparison of performance results, in terms of number of BER and FER for a neural network based decoder such as the neural network based decoder 114 trained according to different training approaches compared to other decoding models, specifically:
BP—the original BP algorithm.
BP-FF—An original BP decoder utilizing a Feed-Forward (FF) neural network constructed according to the BP algorithm with hyperparameters as detailed in tables 1 and 2 trained using randomly selected training samples (passive learning).
BP-FF by d_{H} (dₘₐₓ=2)—the BP-FF trained using training samples selected based on the Hamming distance SNR indicative metric (distance-based approach).
BP-FF by Reliability—the BP-FF trained using training samples selected based on the reliability parameters SNR indicative metric (reliability-based approach).
BP-FF by Reliability & d_{H} (dₘₐₓ=3)—the BP-FF trained using training samples selected based on the reliability parameters SNR indicative metric applied with the Hamming distance filtering (combined selection approach).

As seen in FIG. 6A, FIG. 6B, FIG. 6C, FIG. 6D, FIG. 6E and FIG. 6F, both the distance-based and reliability-based approaches outperform the original BP-FF model with hyperparameters as in tables 1 and 2. In particular, the observed contribution of the actively selected samples may be separated to two different regions. At the waterfall region, the improvement varies from 0.25 dB to 0.4 dB in FER and 0.2 dB to 0.3 dB in BER for the different codes, BCH(63,36), BCH(63,45) and BCH(127,64). At the error-floor region, the gain is increased by 0.75 dB to 1.5 dB in FER and by 0.75 to 1 dB in BER for all the simulated codes, BCH(63,36), BCH(63,45) and BCH(127,64). Furthermore, it should be noted that an aggregated increase in gain of about 2 dB is achieved in high SNR, compared to the BP.

The best decoding gains per code are summarized in Table 3 below.

TABLE 3

| | Region | | | |
|---|---|---|---|---|
| | Waterfall | | Error-floor | |
| Code | BER[dB] | FER[dB] | BER[dB] | FER[dB] |
| CR-BCH(63,36) | 0.2 (10⁻⁵) | 0.25 (10⁻³) | 1 (4 ? 10⁻⁷) | 1.5 (10⁻⁵) |
| CR-BCH(63,45) | 0.2 (10⁻⁵) | 0.25 (10⁻⁴) | 0.75 (2 · 10⁻⁷) | 0.75 (3 · 10⁻⁶) |
| CR-BCH(127,64) | 0.3 (10⁻⁴) | 0.4 (10⁻³) | 0.75 (10⁻⁶) | 1.25 (10⁻⁴) |

The measured error value, where the gain is observed, is specified in parentheses. Comparing to state of the art methods in the BER graphs, a gain of 0.25 dB is achieved in the CR-BCH(63,36) code, while in CR-BCH(127,64) one can observe similar performance. Furthermore, the difference in gains between the curve of the BP-FF by Reliability and the curve of the BP-FF by Reliability & d_{H} indicates that the two methods indeed train on different distributions of words.

The FER metric is observed to gain the most from all approaches, with the BP-FF by reliability & d_{H} filtering approach having the best performance. One conjecture is that all these methods are optimized to improve FER directly. For the Hamming distance approach (BP-FF by d_{H}), lowering the number of errors in a single codeword reflects the FER directly. The reliability parameters are taken as a mean over the received words, thus adding more information on each y sample rather than on each single bit, yᵢ. As evident, all methods achieve better performance while keeping the same decoding complexity as known in the art. This emphasizes the fact that the performance improvement is achieved solely by the smart sampling of the data to train the neural network based decoder 114, i.e., by actively selecting the training samples which are estimated to provide highest contribution for better training the neural network based decoder 114 to achieve better improved performance.

According to some embodiments of the present invention, there are provided methods and systems for using an ensemble comprising a plurality of neural networks based decoders such as the neural network based decoder 114 to decode codewords of one or more of the encoded error correction codes transmitted over transmission channels subject to one or more of the interferences. Each of the neural networks based decoders 114 is adapted and trained to decode encoded codewords mapped to a respective one of a plurality of regions constituting a distribution space of the code.

The ensemble therefore builds on the active learning concept by training each neural network based decoder 114 of the ensemble with a respective subset of actively selected samples which are mapped to the respective region associated with the respective neural network based decoder 114.

The ensemble comprising multiple neural networks based decoders 114 each trained with samples mapped to a respective region of the code distribution space may significantly outperform existing methods even such state of the art decoders which employ an array of multiple decoders, for example, the example, the list decoding. In particular, the Belief Propagation List (BPL) decoder for polar codes as known in the art may comprise a plurality of decoders which may run in parallel since—“there exists no clear evidence on which graph permutation performs best for a given input” to quote the prior art. this approach may thus utilize excessive computing resources since if the decoders were input-specialized, each received encoded codeword may be mapped to a single decoder, thus preserving computation resources. Recently, some state of the art methods suggested learning a gating function which may be applied to map the incoming encoded codeword to one of the decoders of the BPL but failed to build on the domain knowledge to achieve such an effective gating function.

Furthermore, other state of the art methods may suggest adding stochastic perturbations with varying magnitudes to the received encoded codeword to create artificial interference patters, followed by applying the same BP algorithm on each of the multiple copies. As such, each BP decoder is in fact introduced with a modified input distribution. Ambiguity may arise with respect to the optimal choices for the magnitudes of the artificial noises. In practice, it may be desired that each decoder to correctly decode a different part of the original input codeword distribution, such that the list-decoder covers the entire input codeword distribution in an efficient manner.

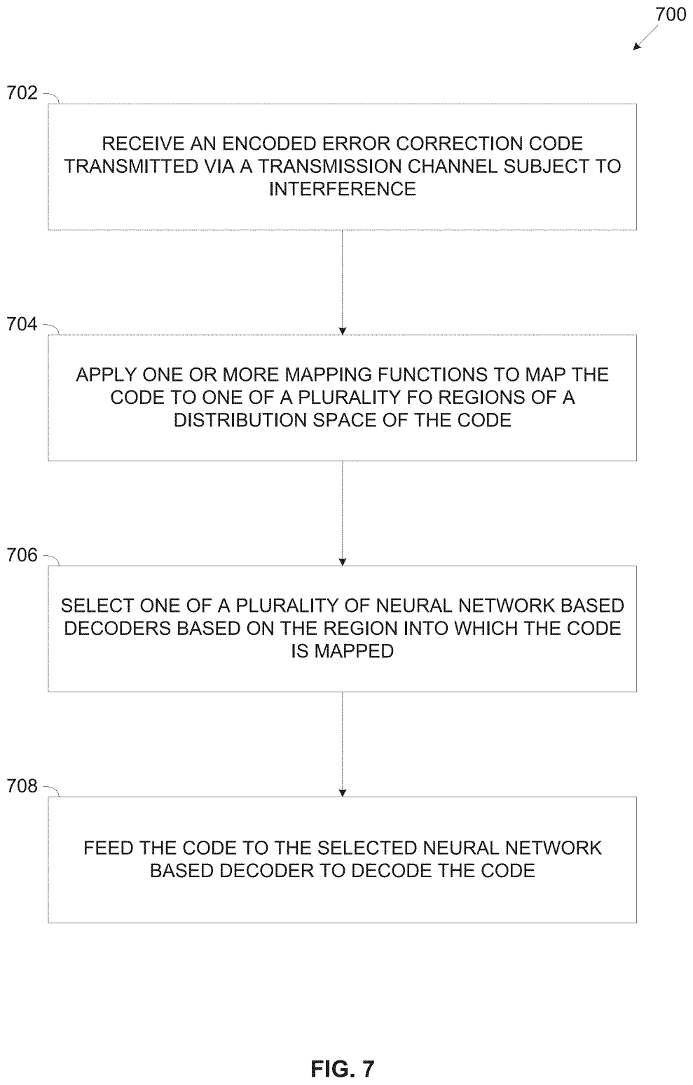

Reference is now made to FIG. 7, which is a flowchart of an exemplary process of using an ensemble comprising a plurality of neural network based decoders to decode an encoded error correction code transmitted over a transmission channel, according to some embodiments of the present invention.

An exemplary process 700 may be executed to decode an encoded codeword of an error correction code error, for example, for example, linear block codes such as, for example, algebraic linear code, polar code, LDPC and HDPC codes, non-block codes such as, for example, convolutional codes and/or non-linear codes, such as, for example, Hadamard code using an ensemble of neural networks based decoders such as the decoder 114.

In particular, the distribution space of the encoded codewords may be partitioned to a plurality of regions. Each of the neural networks based decoders of the ensemble may be adapted and trained to decode encoded codewords mapped to a respective one of the plurality of regions.

In real-time (online) one or more mapping (gating) functions may be applied to map each received encoded code to one of the plurality of regions and direct the received code to one or more of the neural network based decoders of the ensemble accordingly.

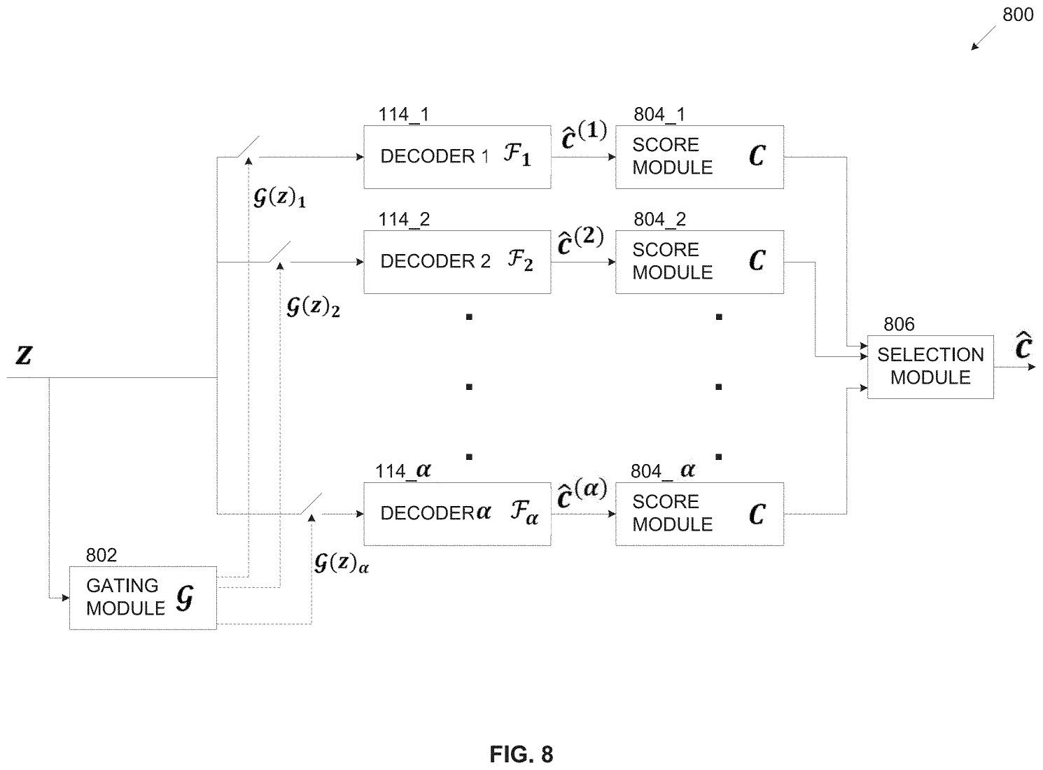

Reference is also made to FIG. 8, which is a schematic illustration of an exemplary ensemble comprising a plurality of neural network based decoders such as the decoder 114 for decoding an encoded error correction code transmitted over a transmission channel, according to some embodiments of the present invention.

An exemplary ensemble 800 may comprise a plurality of WBP neural network based decoders such as the neural network based decoder 114, for example, a decoder_1 114_1, a decoder_2 114_2 through a decoder_α 114_α. Each of the neural networks based decoders 114 may include one or more neural networks, specifically, one or more deep neural networks, for example, a CF neural network, a CNN, an FF neural network, an RNN and/or the like.

As described herein before, the BP algorithm is an inference algorithm used to decode corrupted codewords in an iterative manner. The BP algorithm passes messages over the nodes of the bipartite graph, for example, the Tanner graph, the factor graph and/or the like until convergence or a maximum number of iterations is reached. The nodes in the Tanner graph are of two types: variable and check nodes. An edge exists between a variable node v and a check node h iff variable v participates in the condition defined by the h^{th} row in the parity check matrix H. The weights in the BP algorithm based Tanner graph representation may be assigned with learnable weights thus unfolding the BP algorithm into a neural network referred to as WBP.

The ensemble 800 may further include a plurality of scoring modules 804 which may each apply one or more scoring functions to compute a score reflecting and/or ranking an accuracy of the recovered code (codeword) decoded by a respective one of the neural network based decoders 114. As such, each scoring module 804, for example, scoring module 1 804_1, a scoring module 2 804_2 through a scoring module a 804_α may be associated with a respective one of the neural network based decoders 114, specifically a decoder_1 114_1, a decoder_2 114_2 through a decoder_α 114_α respectively.

Moreover, in case a received codeword is decoded by multiple decoders 114, a selection module 806 may apply one or more selection functions to select one of the recovered codewords typically based on the ranking score computed for each recovered codeword decoded by a respective one of the neural network based decoders 114.

The ensemble 800 may include a gating (mapping) module 802 which may apply one or more mapping functions to map each received encoded code to one or more of neural network based decoders 114, specifically according to the region into which the received encoded code is expected to map.

Each of the elements of the transmission system 100, specifically the gating module 802, the decoders 114, the scoring modules 804 and the selection module 806, may be implemented using one or more processors executing one or more software modules, using one or more hardware modules (elements), for example, a circuit, a component, an Integrated Circuit (IC), an Application Specific Integrated Circuit (ASIC), a Field Programmable Gate Array (FPGA), an Artificial Intelligence (AI) accelerator and/or the like and/or applying a combination of software module(s) and hardware module(s).

During training of the ensemble of neural networks based decoders 114, the distribution space of a plurality of training samples mapping one or more encoded codewords of the error correction code is partitioned to the plurality of regions. In particular, the training samples map the encoded codeword(s) transmitted over a transmission channel subject to different interference patterns comprising, for example, noise, crosstalk, attenuation and/or the like. As such each of the training samples may be induced with a different interference pattern.

Optionally, the training samples map the encoded zero codeword (all zero) of the error correction code which may not degrade the performance of the trained neural networks based decoders 114 since the WBP architecture of the neural network based decoder2 114 may guarantee the same error rate for any chosen transmitted codeword.

Each of the neural networks based decoders 114 may be associated with a respective one of the plurality of regions constituting the distribution space of the code and is therefore trained with a respective subset of samples mapped to the respective region. Each neural networks based decoder is thus trained to efficiently decode encoded codewords which are mapped into its respective region. In particular, each of the plurality of regions may reflect an SNR range of the samples mapped into the respective region.

As discussed herein before, an i^{th} element of a vector v may be denoted with a subscript vᵢ. Further, v_{i,j} corresponds to an element of a matrix. However, denoted with a superscript, v⁽ⁱ⁾ presents the i^{th} member of a set.

Let u∈{0,1}^{k} be a message word encoded with function [symbol] :{0,1}^{k}→{0,1}^{V} to form a codeword c, with k and V being the information word's length and the codeword's length, respectively. A BPSK-modulated (0→1,1→−1) transmitted word (codeword) is denoted by x. After transmission through the transmission channel, specifically an AWGN channel, the received word is denoted y, where y=x+n, where n˜N(0, σₙ ²I) is the white noise. Next, LLR values are considered for decoding by

$$z = \frac{2}{{σ}_{n}^{2}} .$$

y At last, a decoding function F: [symbol] ^{V}→{0,1}^{V} is applied to the LLR values to form the decoded codeword ĉ= [symbol] (z). In addition, one or more stopping criteria may be applied after each decoding iteration.

The neural network based decoders 114 generally denoted [symbol] may be parameterized by weights w, obtained by training [symbol] over a training dataset [symbol] until convergence. The neural network based decoders 114 may be therefore denoted by [symbol] .

Since each of the neural network based decoders 114 of the ensemble 800 is directed to efficiently decode codewords mapped to different regions, one or more of the neural network based decoders 114 may be structured differently compared to each other, for example, have different number of hidden layers. Moreover, since each of the neural network based decoders 114 is trained using a different subset of training samples, the neural network based decoders 114 may be weighted differently, i.e., have different weights assigned to one or more of their edges.

Consider a distribution P(e) of binary errors e=y_{HD} xor c at the output of the transmission channel, where y_{HD} is the received encoded word after processed according to a hard-decision rule ( [symbol] ⁺→0, [symbol] ⁻→1). A set of K observable binary error patterns may be denote by ε={e⁽¹⁾, . . . , e^{(K)}}, where these error patterns are observed for the training samples used for the training. The error distribution ε may be partitioned into the plurality of different error-regions according to equation 17 below. Specifically, the error distribution ε may be partitioned into a different error-regions which may be associated with the α different neural network based decoders 114.

$$ɛ = {{⋃}^{α}}_{i = 1} {𝒳}^{( i )} \text{:} {𝒳}^{( i )} ⋂ {𝒳}^{( i )} = ∅ , ∀ i \neq j \qquad \underline{Equation 17}$$

A plurality of training dataset subsets, specifically α subsets {( [symbol] ⁽¹⁾, . . . , [symbol] ^{(α)})} may be derived from the α different error-regions according to the relation expressed in equation 18 below.

[symbol]

⁽ⁱ⁾={z^{(κ)}:e^{(κ)}∈X⁽ⁱ⁾} Equation 18:

As such, each of the α neural network based decoders 114 of the ensemble 800, { [symbol] , . . . , [symbol] } may be trained with a respective one of the subsets { [symbol] ⁽¹⁾, . . . , [symbol] ^{(α)}}. The a neural network based decoders 114 may be therefore notated by { [symbol] , . . . , [symbol] } with each neural network based decoder 114 denoted by [symbol] or [symbol] for brevity.

Effective partitioning the distribution space of the code training samples as expressed by the error distribution may be crucial not only to improve performance of each single neural network based decoder 114, but to the generative capabilities of the overall ensemble 800.

Several methods may be therefore applied to effectively partition the code distribution space to the plurality of regions, specifically using one or more partitioning metrics. These partitioning metrics may be very similar in their concept to the SNR indicative metrics discussed herein before for the active learning since they are also directed to actively selecting the samples subsets according to their mapping in the distribution space, and moreover according to their error distribution which may be highly correlated with the SNR experienced by the training samples which may induce the errors exhibited by the training samples.

A first partitioning metric may be the Hamming distance indicating the number of bit positions differed between the hard-decision of the recovered received encoded codeword and the correct word originally encoded by the encoder 110. The errors may be partitioned according to the Hamming distance according to one or more approaches, for example, from the zero-errors vector as expressed in equation 19 below.

X⁽ⁱ⁾={e^{(κ)}:e^{(κ)} has i non—zero bits} Equation 19:

The plurality of subsets of samples of the training dataset may be thus generated according to equation 2 by mapping each of the training samples in the distribution space to one of the plurality of regions and grouping together to a respective subset all the samples mapped into each region. Furthermore, all error patterns e^{(κ)} with more than a non-zero bits may be assigned to X^{(α)}.

A second partitioning metric may include one or more of the reliability parameters computed and/or identified for each of the training samples. The reliability parameters, specifically, the ABP and/or the MBCE which map the probabilities distribution of the training samples LLR values may be highly correlated with the error patterns exhibited by the training samples. The plurality of training samples may be therefore mapped in the distribution space to the plurality of regions and all samples mapped to a respective one of the plurality of regions may be grouped into a respective one of the plurality of subsets of samples.

A third partitioning metric may include the syndrome-guided Expectation-Maximization (EM) parameter which may map each of the training samples with respect to the center of one or more EM clusters computed for at least some error patterns identified in one or more previously processed training samples.

In particular, similar error patterns may be clustered using the EM algorithm as known in the art. Each cluster may define a respective error-region X⁽ⁱ⁾.

Let μ⁽ⁱ⁾∈[0,1]^{V} be a multivariate Bernoulli distribution corresponding to region X⁽ⁱ⁾. Let [symbol] ={(μ⁽¹⁾, π₁), . . . , (μ^{(α)}, π_{α})} be a Bernoulli mixture with πᵢ∈[0,1] being each mixture's coefficient such that Σᵢ₌₁^{α}πᵢ=1. It is assumed that each error e is distributed by mixture [symbol] according to equation 20 below.

$$P ( e \vert ℛ ) = {\sum }_{i = 1}^{α} {π}_{i} P ( e \vert {μ}^{( i )} ) \qquad \underline{Equation 20}$$

where the Bernoulli prior may be defined according to equation 21 below.

P(e|μ⁽ⁱ⁾)=Πᵥ₌₁^{V}(μᵥ⁽ⁱ⁾)^{e}^{ᵥ}(1−μᵥ⁽ⁱ⁾)^{1-e}^{ᵥ}. Equation 21:

At first, all μ⁽ⁱ⁾ and π may be randomly initialized. Then, the EM algorithm may be is applied to infer parameters that maximize the log-likelihood function over K samples as expressed in equation 22 below.

$$log ( ɛ \vert ℛ ) = {\sum }_{κ = 1}^{K} log ( P ( {e}^{( κ )} \vert ℛ ) ) . \qquad \underline{Equation 22}$$

The clustering may be performed once as a preprocess phase of the training session. During the training, upon convergence to one or more final parameters, each region X⁽ⁱ⁾ may be assigned with error patterns which are more probable to originate from cluster i than from any other cluster j as expressed in equation 23 below.

X⁽ⁱ⁾={e^{(κ)}:πᵢP(e^{(κ)}|μ⁽ⁱ⁾)>πⱼP(e^{(κ)}|μ^{(j)}),∀j≠i}. Equation 23:

This may be followed by computing and forming the plurality of subsets D⁽ⁱ⁾ according to equation following equation 18.

Proposition 1:

Let ε be formed of error patterns drawn from α different AWGN channels σ⁽¹⁾, . . . , σ^{(α)}. Let K be the number of total patterns, where an equal number is drawn from each channel. Then, for α desired mixture centers and as K tends to infinity, the global maximum of the likelihood may be attained at parameters

$${μ}^{( i )} = ( Q ( \frac{1}{{σ}^{( t )}} ) , … , Q ( \frac{1}{{σ}^{( t )}} ) ) , \qquad$$

where Q(⋅) being the Q-function.

Proof:

First, the true centers of the mixture were derived, recalling that the AWGN channel may be viewed as a binary symmetric channel with a crossover probability of

$$Q ( \frac{1}{{σ}^{( i )}} ) .$$

Second, the parameterized centers were shown to attain the global maximum of the likelihood function when identical to the true centers as known in the art.

Proposition 1 indicates that though the distribution of binary errors at the channel's output may be modeled with a mixture of multivariate Bernoulli distribution, a naive application of the EM algorithm may tend to converge to a trivial solution which may fail to adequately cluster complex classes. To overcome this limitation, the code structure, as available in the domain knowledge, may be used to identify non-trivial latent classes. For each error, the syndrome, s=He may be first calculated. Thereafter, each index v may be assigned a label in {0,1} based on the majority of either unsatisfied or satisfied conditions it is connected to according to equation 24 below.

Equation 24:

qᵥ=arg max_{b∈{0,1}} [symbol] 1ₛ_{ᵢ}_{=b} (3)
with [symbol] (v) being the indices of check nodes connected to v in the Tanner graph and 1 denotes an indicator function which has a value 1 if sᵢ=b and 0 otherwise.

Assuming each latent class i, which corresponds to a single error-region, is modeled with two different multivariate Bernoulli distributions μ^{(i,0)}, μ^{(i,1)}. Label qᵥ determines for each index v it's Bernoulli parameter μᵥ^{(i,q}^{ᵥ}⁾. Under this new model, the Bernoulli mixture [symbol] ^{syn} may be expressed by equation 25 below.

Equation 25:

[symbol]

^{syn}={(μ^{(1,0)},μ^{(1,1)},π₁), . . . ,(μ^{(α,0)},μ^{(α,1)},π_{α}} (1)

having α latent classes:

$$\begin{matrix}P ( e \vert {ℛ}^{s y n} ) = {\sum }_{i = 1}^{α} {π}_{i} p ( e \vert {ϕ}^{( i )} ) \\ Where \text{:} & ( 2 ) \\ P ( e \vert {ϕ}^{( i )} ) = {\prod }_{v = 1}^{V} {( {μ}_{v}^{( i , {q}_{v} )} )}^{{e}_{v}} {( 1 - {μ}_{v}^{( i , {q}_{v} )} )}^{1 - {e}_{v}} & ( 3 )\end{matrix}$$

New E and M steps may be derived as known in the art. An α-dimensional latent variable z′=(z′₁, . . . , z′_{α}) with binary elements and Σᵢ₌₁^{α}z′ᵢ=1 is first introduced. Then the log-likelihood function of the complete data given the mixtures' parameters may be expressed by equation 26 below.

$$𝔼 [ log P ( {e}^{( 1 )} , {q}^{( 1 )} , {{z}^{′}}^{( 1 )} , … , {e}^{( K )} , {q}^{( K )} , {{z}^{′}}^{( K )} \vert {ℛ}^{s y n} ) ] == {\sum }_{κ = 1}^{K} {\sum }_{i = 1}^{α} {Res}_{κ , i} [ log {π}_{i} + {\sum }_{v = 1}^{V} ( {e}_{v}^{( κ )} log {μ}_{v}^{( i , {q}_{ν}^{( κ )} )} + ( 1 - {e}_{v}^{( κ )} ) log ( 1 - {μ}_{v}^{( i , {q}_{ν}^{( κ )} )} ) ) ] \qquad \underline{Equation 26}$$

The new E-step may be then expressed by equation 27 below.

$${Res}_{κ , i} = \frac{{π}_{i} P ( {e}^{( κ )} \vert {ϕ}^{( i )} )}{P ( {e}^{( κ )} \vert {ℛ}^{s y n} )} \qquad \underline{Equation 27}$$

where Res_{κ,i}≡ [symbol] z′ᵢ^{(κ)}] is the responsibility of distribution i given sample κ.

The new M-step may be then expressed by equation 28 below.

$${μ}_{v}^{( i , b )} = \frac{{\sum }_{κ = 1}^{K} {1}_{{q}_{v}^{( κ )} = b} {Res}_{κ , i} {e}_{v}^{( κ )}}{{\sum }_{κ = 1}^{K} {1}_{{q}_{v}^{( κ )} = b} {Res}_{κ , i}} , {π}_{i} = \frac{{\sum }_{κ = 1}^{K} {Res}_{κ , i}}{K} \\ with b ∈ \{ 0 , 1 \} . \qquad \underline{Equation 28}$$

In equation 28, only the indices with active qᵥ in μ^{(i,q}^{ᵥ}⁾ may be updated with the new responsibilities. The data partitioning that follows this clustering is referred to as the syndrome-guided EM approach.

After partitioning the distribution space to the plurality of regions based on one or more of the partitioning metrics and creating the plurality of subsets of training samples according to their mapping to the regions, each subset may be used to train a respective one of the α neural network based decoders 114.

The training session may further comprise a plurality of training iterations where in each of the plurality of iterations each of the α neural network based decoders 114 may be trained with another subset of training samples grouped according to their mapping to the regions based on one or more of the partitioning metrics. One or more weights of one or more of the α neural network based decoders 114 may be updated in case a decoding accuracy score of the updated neural network based decoder(s) 114 is increased compared to a previous training iteration.

After the neural network based decoders 114 of the ensemble 800 are trained, the ensemble may be applied to decode one or more new and previously unseen encoded codewords of the error correction code.

As shown at 702, the process 700 starts with the ensemble 800 receiving an encoded error correction code z transmitted via a transmission channel subject to interference characterized by a certain interference pattern injected to the transmission channel.

As shown at 704, the gating module 802 may apply one or more mapping functions to map the received encoded word z to one or more of the plurality of regions constituting the code distribution space. In particular, the mapping function(s) used by the gating module 802 may map the received encoded word z based on error estimation of an error pattern of the received encoded word z.

However, since the gating module 802 may lack full knowledge of the error pattern e of the received encoded word z, the gating module 802 may employ one or more techniques for computing an estimated error \tilde{e} which may be used to map the received encoded word z to a respective one of the regions constituting the code distribution space, specifically the distribution based on the error patterns identified for the code during the training.

For example, the mapping function(s) used by the gating module 802 may employ a low complexity decoder, for example, a classical non-learnable Hard Decision Decoder (HDD) which may be implemented as known in the art, for example, by the Berlekamp-Massey algorithm and/or the like. The low complexity HDD may decode the received encoded word z to produce an estimated codeword \tilde{c}, from which the gating module 802 may calculate an estimated error \tilde{e}=y_{HD} xor \tilde{c}.

In another example, the mapping function(s) used by the gating module 802 may employ one or more neural network based decoders trained to decode the code, in particular, simple and low complexity neural network based decoder(s) which are not designed, constructed and trained to accurately decode the received encoded word z but rather roughly decode it to produce an approximated codeword \tilde{c}, from which the gating module 802 may calculate the estimated error \tilde{e}.

As shown at 706, the gating module 802 denoted by [symbol] ^{V}→{0,1}^{α} may select one or more of the neural network based decoders 114 [symbol] ᵢ for decoding the received [symbol] encoded codeword z. In particular, the gating module 802 may select the neural network based decoder(s) 114 [symbol] ᵢ according to the region into which the received encoded codeword z is mapped, for example, based on the estimated error \tilde{e} computed for the received encoded codeword z.

The gating module 802 select the neural network based decoder(s) 114 [symbol] ᵢ according to one or more selection approaches to select the neural network based decoder(s) 114 [symbol] ᵢ to decode the encoded codeword z, for example, a single-choice gating in which a single neural network based decoder 114 [symbol] ᵢ is selected, an all-decoders gating in which all the neural network based decoders 114 [symbol] ᵢ are selected and a random-choice gating in which a single neural network based decoder 114 [symbol] ᵢ is randomly selected. It should be noted, that while the single-choice gating and the all-decoders gating may be viable implementations, the random-choice gating may clearly not facilitate an effective mapping and may be thus provided only for performance referencing.

In case of the all-decoders gating, the gating module 802 may assign [symbol] (z)ⱼ=1 for all j thus selecting all a neural network based decoder(s) 114 [symbol] ᵢ to decode the received encoded codeword z In such case, the HDD or the low complexity neural network based decoder may be unused since all of the neural network based decoders 114 [symbol] ᵢ are selected regardless of the estimated error mapping.

In case of the random-choice gating, the gating module 802 may apply one or more random selection methods and/or algorithms as known in the art to randomly select j such that [symbol] (z)ⱼ=1 for i=the randomly selected j and [symbol] (z)ᵢ=0 for all other i, thus randomly selecting one of the neural network based decoders 114 [symbol] ᵢ to decode the received encoded codeword z. In this case, the HDD or the low complexity neural network based decoder are also not used.

However, when employing the single-choice gating, the gating module 802 may select a single one of the neural network based decoders 114 [symbol] ᵢ to decode the received encoded codeword z according to the estimated error \tilde{e} computed for the received encoded codeword z. As such, the gating module 802 may apply the gating function [symbol] to the encoded codeword z and set [symbol] (z)ⱼ=1 for index j realizing \tilde{e}∈X^{(j)}, i.e. the estimated error \tilde{e} of encoded codeword z is within the region associated with neural network based decoder 114 [symbol] ⱼ and [symbol] (z)ᵢ=0 for all the other neural network based decoders 114 [symbol] ᵢ.

The all-decoders gating may serve as a baseline, the FER in the single-gating case is lower-bounded by the FER achievable by employing all decoders in an efficient manner. The random-choice gating naturally may not present any benefit to efficient decoding the encoded codeword z and it may be applied only to prove the significance of the single-choice gating.

As shown at 708, the received encoded codeword z may be fed to the neural network based decoder(s) 114 [symbol] ᵢ selected by the gating module 802. For example, the gating module 802 may operate one or more switching circuits which may couple or de-couple each of the α neural network based decoder(s) 114 [symbol] ᵢ to the input circuit of the ensemble 800 thus feeding the received encoded codeword z only to the selected neural network based decoder(s) 114 [symbol] ᵢ.

In case of the single-choice gating and random-choice gating the selected neural network based decoder 114 [symbol] ᵢ may decode the received encoded codeword z and the ensemble 800 may output a recovered version of the encoded codeword z.

However, in case of the all-decoders gating, all α neural network based decoder(s) 114 [symbol] ᵢ decode the received encoded codeword z and output recovered respective versions. In such case the decoded word recovered by one of the α neural network based decoders 114 [symbol] ᵢ has to be selected and output from the ensemble 800.

To this end the accuracy of the recovered word decoded by each of the neural network based decoder(s) 114 [symbol] ᵢ may be evaluated and scored by a respective one of the score modules 804. The score modules 804 may apply one or more scoring function [symbol] :{0,1}^{V}→ [symbol] to compute a score reflecting and/or ranking an estimated accuracy of the recovered code. The mapping function is a function which may map a vector (sequence) of “0” and/or “1”, specifically the recovered code (codeword) to a real value. As such, each score module 804 may compute a respective score value ranking the respective recovered code (codeword) decoded by a respective neural network based decoder 114 [symbol] ᵢ. The scoring function may follow, for example, the formulation of equation 29 below to compute a score value [symbol] .

[symbol]

(ĉ⁽ⁱ⁾)=ĉ⁽ⁱ⁾z^{transpose} Equation 29:

As known in the art, this particular scoring function may produce greater values for codewords compared to pseudo-codewords. This scoring function may therefore mitigate the effects of the pseudo-codewords, which are most dominant at the error floor region as known in the art.

The selection module 806 may select one of the recovered codewords according to one or more selection rules, typically based on the ranking score computed for each recovered codeword decoded by a respective one of the neural network based decoders 114 [symbol] ᵢ. An exemplary selection rule may follow the formulation of equation 30 below.

ĉ=arg max [symbol] [symbol] (ĉ⁽ⁱ⁾) Equation 30:

The decoded word having highest score among all valid candidates, i.e., among all the recovered codewords decoded by all a neural network based decoders 114 [symbol] ᵢ may be selected as the final decoded word which is output from the ensemble 800. In case no valid candidates exist, all candidates may be considered.

Moreover, one or more neural network based decoders 114 of the ensemble 800 may be further trained online when applied to decode one or more new and previously unseen encoded codewords. This may allow for adaptation of the ensemble 800 to one or more interference pattern specific to the transmission channel applicable to the specific ensemble 800.

Performance of the neural network based decoder 114 trained according to the active learning approach was evaluated through a set of experiments. Following are test results for the neural network based decoder 114 trained using the actively selected training samples for several short linear block codes, specifically BCH(63,45), BCH(63,36) and BCH(127,64) with t_{H}=3, t_{H}=5 and t_{H}=10, respectively.

Performance of an ensemble such as the ensemble 800 was evaluated through a set of experiments. Following are test results for α simulated ensemble 800 constructed based on the Hamming distance and the syndrome-guided EM approaches for two different linear block codes, specifically BCH(63,45) and BCH(63,36). The ensemble 800 utilizes the CR parity-check matrices. Every neural network based decoder such as the neural network based decoder 114 member of the ensemble 800 is trained until convergence. Training is done using zero codewords only, which is not limiting due to the symmetry of the BP algorithm. A vectorized Berlekamp-Massey algorithm based HDD was used for mapping (gating) the received code to one or more of the neural network based decoders 114. The training comprises five iterations only for BP decoding as the common benchmark. Syndrome based stopping criterion is applied after each BP training iteration. The validation dataset is composed of SNR values of 1 dB to 10 dB, at each point at least 100 errors are accumulated.

The number of neural network based decoder 114 chosen for the simulation was α=3 for both methods, as adding neural network based decoder 114 did not significantly boost performance. For the Hamming distance approach, the three regions chosen were X⁽¹⁾, X⁽²⁾, X⁽³⁾. Training is done by finetuning, starting from weights of the BP-FF as known in the art, with a smaller learning rate as specified in table 1 below. For the syndrome-guided EM approach, all neural network based decoder 114 are trained from scratch, as finetuning yielded lesser gains. In the training phase, knowledge of the transmitted word is assumed. Thus, all training datasets contained the known errors (no HDD employed in training). A value of K=10⁶ was empirically chosen, equally drawn from SNR values of 4 dB to 7 dB. These SNR values neither have too noisy words nor too many correct words. Relevant training hyperparameters are detailed in table 4.

TABLE 4

| Hyperparameters | Values |
|---|---|
| Architecture | Feed Forward |
| Initialization | as in [5] |
| Loss Function | Binary Cross Entropy with Multi-loss |
| Optimizer | RMSPROP |
| Pt range | 4dB to 7dB |
| From-Scratch Learning Rate | 0.01 |
| Finetune Learning Rate | 0.001 |
| Batch Size | 1000 words per SNR |
| Messages Range | (-10,10) |

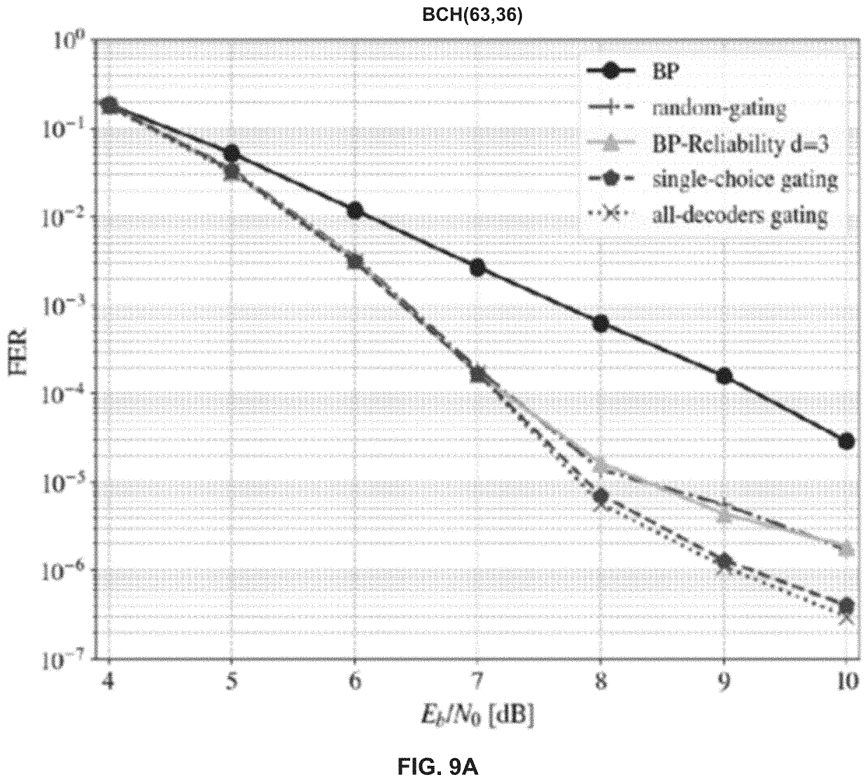

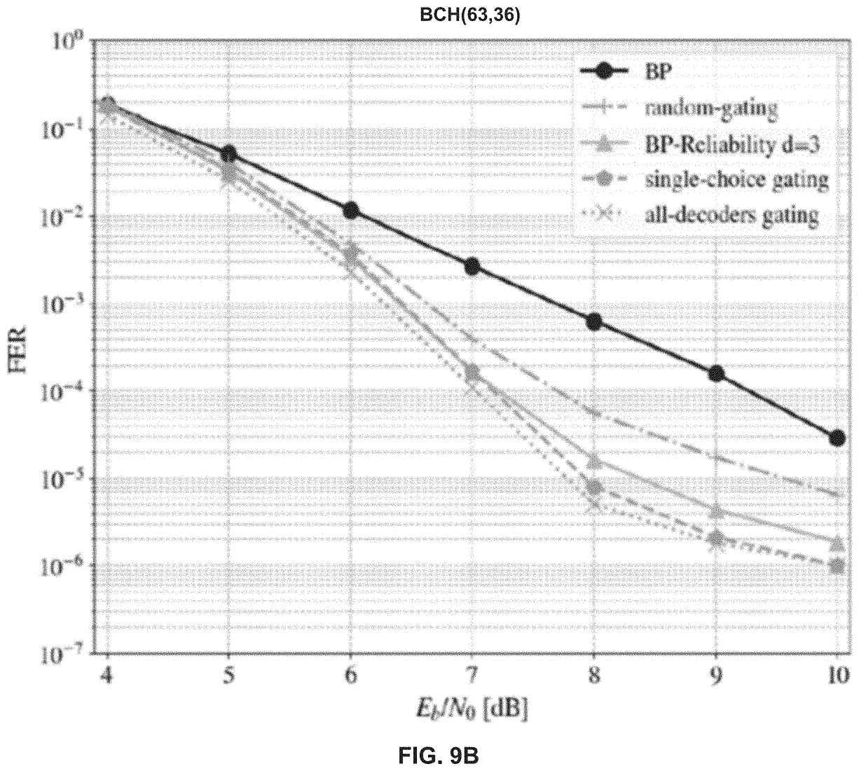

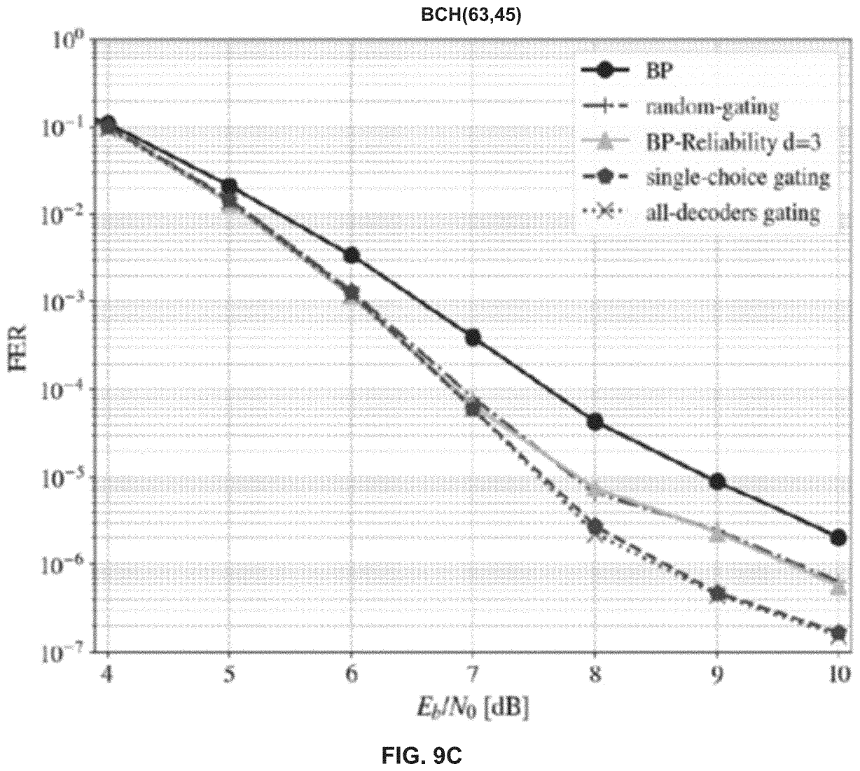

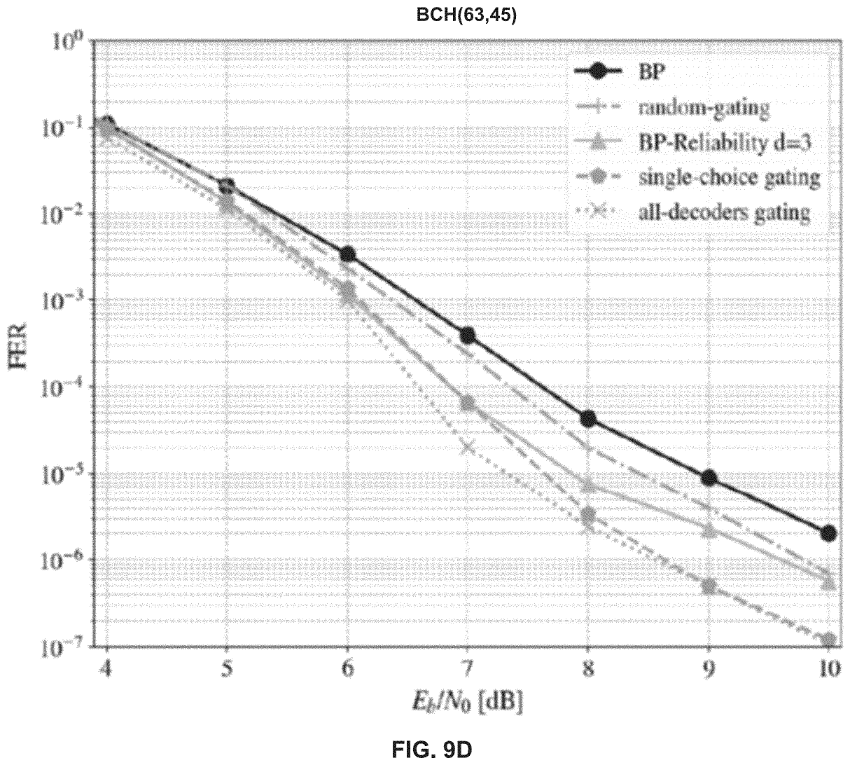

Reference is now made to FIG. 9A, FIG. 9B, FIG. 9C and FIG. 9D, which are graph charts FER results of an ensemble of neural network based decoder applied to decode CR-BCH(63,36) and CR-BCH(63,45) encoded linear block codes, according to some embodiments of the present invention.

The graph charts in FIG. 9A, FIG. 9B, FIG. 9C and FIG. 9D present a comparison of performance results, in terms of number of FER for an ensemble such as the ensemble 800 comprising a plurality of neural network based decoders such as the neural network based decoder 114 compared to other decoding models, specifically:
BP—the original BP algorithm.
Random choice gating—an ensemble 800 employing randomly selection of one of the neural network based decoder 114 to decode the received encoded word.
BP-Reliability d=3—the BP-FF trained using active learning in which training samples are selected based on the reliability parameters SNR indicative metric applied with the Hamming distance filtering of d=3 (combined selection approach).
Single-choice gating—an ensemble 800 employing randomly selection of a single one of the neural network based decoder 114 to decode the received encoded word.
All-decoders gating—an ensemble 800 employing randomly selection of all of the neural network based decoder 114 to decode the received encoded word.

As seen in FIG. 9A, FIG. 9B, FIG. 9C and FIG. 9D, the ensembles 800 based on the Hamming distance and the syndrome-guided EM approaches compare favorably to the best results of the neural network based decoder 114 trained using active learning, specifically the BP-Reliability approach by up to SNR of 7 dB, and surpasses it thereafter. FER gains of up to 0.4 dB at the waterfall region are observed for the ensembles 800 of both approaches in the two codes. At the error floor region, the improvement of the ensembles 800 varies from 0.5 dB to 1.25 dB in the CR-BCH(63,36), while a constant 1 dB is observed in the CR-BCH(63,45). No improvement is achieved in the low-SNR regime. This may be attributed to the limitation of the model-based approach which may be seen in other models known in the art.

Also evident in the graph charts is that the two ensembles 800 based on the Hamming distance and the syndrome-guided EM have non-negligible performance difference only at SNR of 9 dB and 10 dB. The ensemble 800 based on the Hamming distance approach surpasses the ensemble 800 based on the syndrome-guided EM one in the CR-BCH(63,36) with the reverse situation in the CR-BCH(63,45). The gating for the Hamming approach is optimal, as indicated by the ensemble employing the single-choice gating curve that adheres to the all-decoders lower-bound. The ensemble 800 based on the syndrome-guided gating is suboptimal over medium SNR values, as indicated by the gap between the ensemble 800 employing single-choice gating and the ensemble 800 employing all-decoders curves, having potential left for further investigation and exploitation.

Lastly, comparing the random-choice gating for the two ensembles 800 based on the Hamming distance and the syndrome-guided EM approaches, it may be seen that though the random-choice gating is worse for the syndrome-guided EM ensemble 800 than for the Hamming distance ensemble 800, the gains of the two ensembles 800 are quite similar. This hints that each neural network based decoder 114 in the EM based ensemble 800 specializes on a smaller region of the input distribution, yet as a whole these neural network based decoders 114 complement one another, such that the syndrome-guided EM ensemble 800 covers as much of the input distribution as the Hamming distance ensemble 800.

According to some embodiments of the present invention, neural network based decoders may be constructed and trained to decode one or more error correction codewords, specifically, codewords which are encoded twice, first according to one or more error detection codes and then according to one or more of the error correction codes. The encoded codewords which are encoded twice are designated doubly encoded codewords herein after.

The error correction codes used to encode the codewords may include, for example, linear error correction codes such as, for example, block codes, convolutional codes and/or the like as well as non-linear error correction codes. The error correction block codes may include, for example, algebraic linear code, polar code, LDPC code, HDPC code, Hadamard code and/or the like. The error correction convolutional codes may include for example, Tail-Biting code and/or the like.

The error detection code(s) used for encoding the codewords may include, for example, Cyclic Redundancy Check (CRC) code and/or the like. For example, the error detection code and the error correction code may be chosen according to one or more 5G cellular communication protocols where the error correction code is polar code and the error detection code is CRC.

The error detection code(s) according to which the used codewords are encoded may include, for example, CRC code. For example, the error detection code(s) and the error correction code(s) may be chosen (selected) according to 5G cellular communication standard and/or specification such that the selected error detection code(s) and the error correction code(s) may comply with one or more 5G cellular communication protocols where the error correction code is polar code and the error detection code is CRC.

Moreover, an ensemble comprising a plurality of trained neural network based decoders may be deployed to decode one or more of the doubly encoded codewords encoded according to an error detection code and also according to an error correction code the error correction codes where each of the neural network based decoders may be trained and specialized for decoding a respective subset of received codewords.

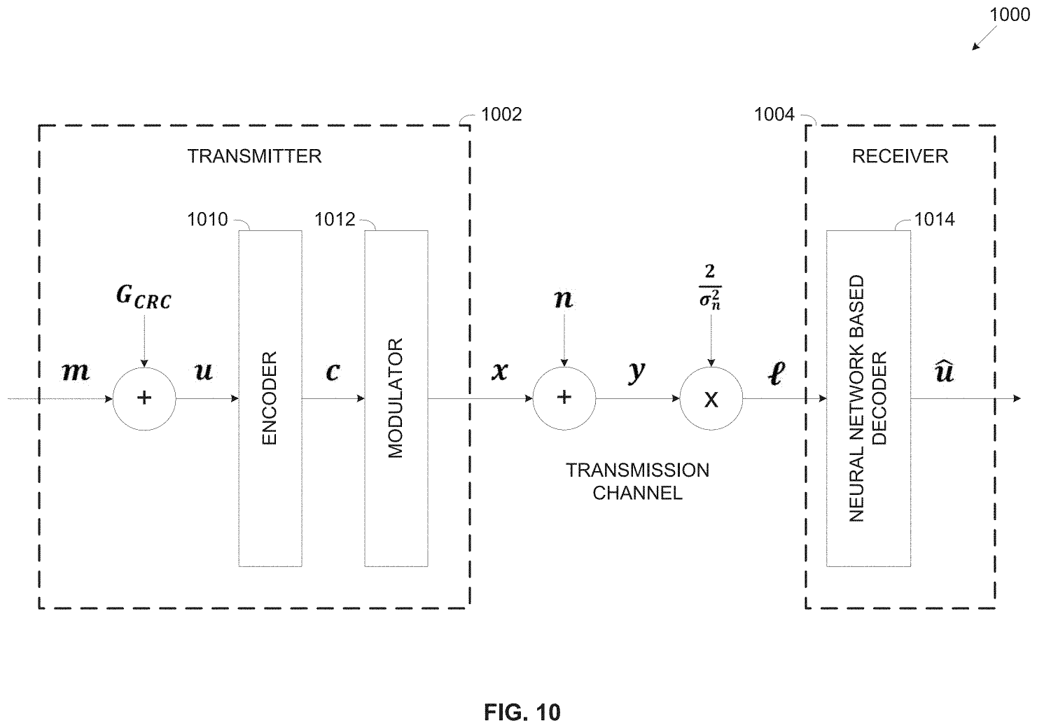

Reference is now made to FIG. 10, which is a schematic illustration of an exemplary transmission system comprising a neural network based decoder for decoding encoded error correction codewords further encoded for error detection which are transmitted over a transmission channel, according to some embodiments of the present invention.

An exemplary transmission system 1000 may include a transmitter 1002 configured to transmit data to a receiver 1004 via a transmission channel comprising one or more wired and/or wireless transmission channels deployed for one or more of a plurality of applications, for example, communication channels, network links, memory interfaces, components interconnections and/or the like. As described herein before, the transmission channel may be subject to one or more interferences, for example, noise, crosstalk, attenuation, and/or the like which may induce one or more errors into the transmitted data.

The data transmitted by the transmitter 1002 may be encoded twice to produce doubly encoded codewords. First the data (messages) may be encoded using one or more of the error detection codes, algorithms and/or protocols, for example, CRC and/or the like. The data encoded for error detection may be than further encoded by an encoder 1010 of the transmitter 1002 configured to encode the data message words according to one or more of the error correction codes algorithms and/or protocols, example, linear codes as well as non-linear codes.

The transmitter 1002 may further include a modulator 1012 such as the modulator 112 configured to modulate the encoded code according to one or more of the modulation schemes known in the art, for example, PSK, BPSK, QPSK and/or the like. The transmitter 1002 may then transmit the modulated code to the receiver 1004 via the transmission channel which may be subject to noise.

The receiver 1004 may include a decoder 1014 configured to decode the modulated doubly encoded code received from the transmitter 1002. In particular, the decoder 1014 may utilize one or more neural network based decoders employing one or more trained neural networks as known in the art, in particular deep neural networks, for example, a CF neural network, a CNN, an FF neural network, an RNN and/or the like to decode the data messages received from the transmitter 1002.

Each of the elements of the transmission system 1000, for example, the neural network based decoder 1014, may be implemented using one or more processors executing one or more software modules, using one or more hardware modules (elements), for example, a circuit, a component, an IC, an ASIC, an FPGA, an AI accelerator and/or the like and/or applying a combination of software module(s) and hardware module(s).

As described for the transmission system 100, for brevity the transmission system 1000 is presented in very high level and simplistic schematic manner to describe modules, elements, features and functions relevant for the present invention. It is appreciated that full system layout and architecture may become apparent to a person skilled in the art. Furthermore, for brevity and clarity, some embodiments of the present invention relate to a transmission channel subject to interference characterized by AWGN. This, however, should not be construed as limiting since the same methods, systems, algorithms, processes and architecture may be applied for transmission channels subject to other interference types, for example, Rayleigh Fading Channel, Colored Gaussian Noise Channel and/or the like.

Before describing at least one embodiment of the present invention, some background is provided for the neural network based decoders used for decoding error correction codes.

A message word m∈{0,1}^{N}^{ₘ} may be encoded by an error detection code algorithm, for example, CRC code according to a systematic generator matrix G_{CRC} with a parity check matrix H_{CRC} to produce a detection code word u∈{0,1}^{N}^{ᵤ} of a codebook [symbol] .

The encoder 1010 may further encode the encoded word u again using one or more of the error correction code algorithms according to a generator matrix G_{CC} with a parity check matrix H_{CC} to produce a codeword c=(c⁽¹⁾, . . . , c^{(N}^{ᵤ}⁾ with c⁽ⁱ⁾∈{0,1}^{1/R}^{_{CC}} where R_{CC} denotes the rate of the error correction code. For brevity, V is denoted by V=1/R_{CC} and the length of the error correction code may be calculate as N_{c}=Nᵤ·V.

The modulator 1012 may modulate each codeword c to produce a respective modulated word x which may be transmitted via the transmission channel. As stated herein before, the transmission channel may be subject to AWGN interference such that the transmitted word may be induced with Gaussian noise n˜ [symbol] (0, σₙ²I) resulting in a codeword y received by the receiver 1004.

However, as described herein before, rather than decoding the codeword the y, the receiver 1004 may decode an LLR word [symbol] which is a value approximated based on the bits i.i.d. and Gaussian prior

$$ℓ = \frac{2}{{σ}_{n}^{2}} \cdot y .$$

The receiver 1004 which may be represented by a function, [symbol] (⋅): [symbol] ^{N}^{_{c}}→{0,1}^{N}^{ᵤ} by may output an estimated detection codeword û maximizing the optimization problem expressed in equation 29 below.

$$\hat{u} = {arg max }_{u ∈ 𝒰} P ( u / ℓ ) \qquad \underline{Equation 29}$$

Equation 29 may be simplified, as known in the art, to be expressed in Bayes in equation 30 below.

$${arg max }_{u ∈ 𝒰} P ( u / ℓ ) = {arg max }_{u ∈ 𝒰} P ( u ) P ( ℓ / u ) \qquad \underline{Equation 30}$$

where P( [symbol] ) is omitted since the term is independent of u.

[symbol]

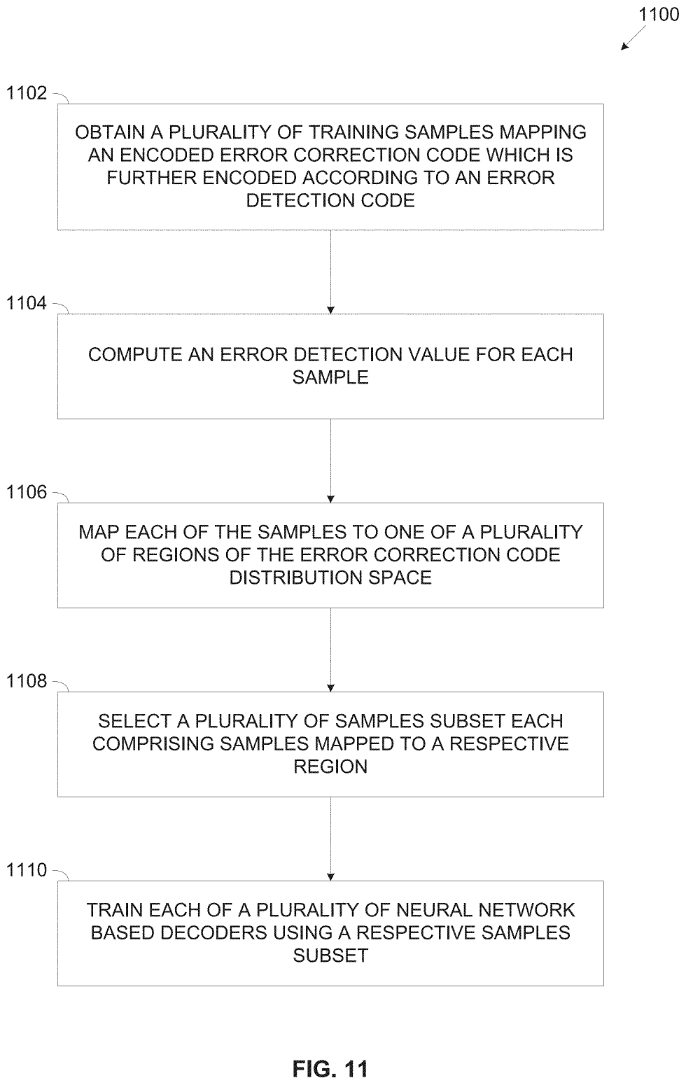

Reference is now made to FIG. 11, which is a flowchart of an exemplary process of using actively selected training samples to train neural network based decoders to decode encoded error correction codewords which are further encoded for error detection, according to some embodiments of the present invention.

An exemplary process 1100 may be executed by a trainer such as the trainer 320 executed by a training system such as the training system 300 to train a plurality of neural network based decoders to decode doubly encoded codewords transmitted over a transmission channel. As described herein before, each doubly encoded codeword is first encoded according to one or more of the error detection codes and is further encoded according to one or more of the error correction codes.

Each of the neural network based decoders may be implement based on the graph representation (trellis) of the encoded error correction code as described herein before, for example, a bipartite graph, a Tanner graph, a factor graph and/or the like. Each of the neural network based decoders may therefore comprise an input layer, an output layer and a plurality of middle (hidden) layers comprising a plurality of nodes corresponding to messages transmitted over a plurality of edges of the graph representation. Each of the edges connects a certain source node and a certain destination node and may be assigned a respective weight adjusted during the training.

As shown at 1102, the process 1100 starts with the trainer 320 receiving, fetching, retrieving and/or otherwise obtaining a plurality of data samples each mapping an encoded codeword of an error correction code transmitted over a transmission channel subject to interference, for example, noise, crosstalk, attenuation and/or the like. In particular, each of the plurality of encoded codeword (data) samples which may be used to train the network based decoders is doubly encoded, i.e. first encoded according to the error detection code followed by encoding according to the error correction code.

The trainer 320 may obtain the data samples from the storage 314 and/or via the I/O interface 310 from one or more sources as described herein before for the process 200.

Each of the samples may be further associated with a respective label indicative of its mapping to one of a plurality of regions constituting the distribution space of the error correction code. The distribution space of the error correction code may relate to one or more operational parameters, attributes and/or characteristics of the error correction code. The partitioning of the distribution space to the plurality of regions may be therefore based on one or more partitioning metrics, in particular metrics relating to the error detection value of doubly encoded codewords. For example, as described herein before, the distribution space may relate to an SNR value of the encoded codewords transmitted via the transmission channel subject to noise. In another example, assuming the error correction code used to encode the encoded codewords is a convolutional code, the distribution space may be partitioned according to one or more states of the encoded codewords, for example, a start state (initial state), a termination state (end state), a combination of states thereof and/or the like.

One or more of the doubly encoded training (data) samples may be created, for example, by simulating a plurality of message words randomly where each message word is doubly encoded and transmitted through the transmission channel. In another example, one or more of the training samples may be extracted and/or retrieved from one or more real-world transmission systems such as the transmission system 1000.

Optionally, each of the plurality of training samples maps the zero codeword (all zero). Using the zero codeword may not degrade the performance of the trained network based decoders since the same error rate may be maintained and guaranteed for any chosen transmitted codeword.

As sown at 1104, the trainer 320 may compute an error detection value, for example, a CRC value for each of the plurality of training samples. To compute the CRC, the trainer 320 may apply one or more methods, techniques and/or algorithms as known in the art depending on the error correction code applied to encode the plurality of training samples.

As shown at 1106, the trainer 320 may map each of the plurality of training samples to one of the plurality of regions of the distribution space of the error correction code. The trainer 320 may apply the CRC metrics to map each training sample to one of the regions based on the CRC value computed for the respective sample.

Optionally, the trainer 320 maps one or more of the training samples to one or more of the regions based on the label associated with the samples which may be indicative of the region they are mapped to.

The trainer 320 may partition the distribution space of the error correction code according to the number of neural network based decoders that are trained, which may be denoted by a such that each of the neural network based decoders may be mapped to a respective one of the regions constituting the error correction code's distribution space.

As shown at 1108, the trainer 320 may select a plurality of sample subsets of the plurality of training samples where each of the sample subsets comprises training samples mapped to a respective one of the plurality of regions of the distribution space of the error correction code. This means that all samples included in each of the sample subsets are mapped to a respective one of the plurality of regions.

As shown at 1110, the trainer 320 may train the plurality of neural network based decoders using the training samples. Specifically, the trainer 320 may train each neural network based decoder using a respective sample subset.

Since each sample subset is mapped to a respective region comprising a limited portion of the distribution space, during the training each of the neural network based decoders may be specialized, i.e., learn, evolve, adapt and/or adjust to efficiently decode a certain group of doubly encoded codewords which are mapped to only a limited portion, segment, section and/or sector of the error correction code's distribution space.

As described herein before, the trainer 320 may apply one or more of the training algorithms, methods and/or paradigms known in the art for training the network based decoders, for example, stochastic gradient descent, batch gradient descent, mini-batch gradient descent and/or the like.

According to some embodiments of the present invention, an ensemble comprising the plurality of trained network based decoders may be applied to decode error correction codewords which are encoded twice, first according to an error detection code followed by encoding according to the error correction code. Since each of the network based decoders is specialized for efficiently decoding encoded codewords mapped to a respective region of the distribution space of the error correction code which is limited and small compared to the entire distribution space, the ensemble of decoders may be capable of efficiently decoding any encoded codeword mapped to any of the limited size regions. The ensemble therefore builds on the active learning concept in which training samples are mapped to the limited size regions and used to selectively train each of the plurality of network based decoders to become expert in its associated region.

The ensemble may further comprise a mapping function and/or a gating module configured to analyze each received doubly encoded codeword, map it to one of the plurality of regions constituting the error correction code's distribution space and select one of the trained network based decoders of the ensemble which is estimated to most efficiently decode the received codeword. In particular, the mapping function may select the network based decoders most suitable to decode the received doubly encoded codeword based on the CRC value determined, estimated and/or computed for the received doubly encoded codeword.

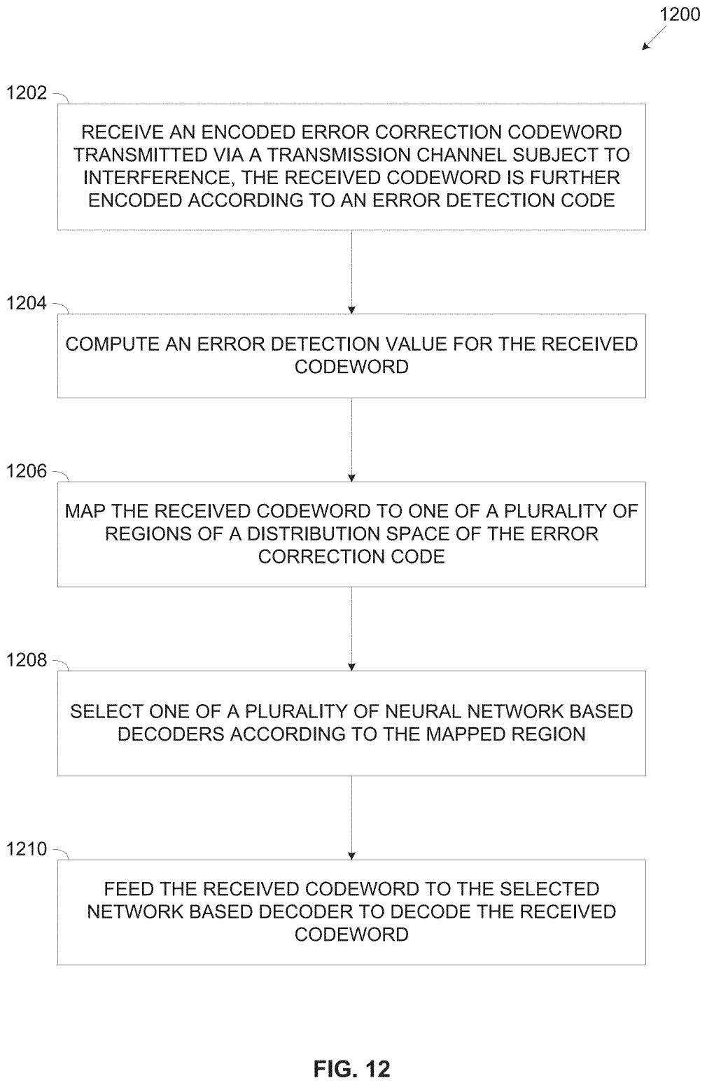

Reference is now made to FIG. 12, which is a flowchart of an exemplary process of using an ensemble comprising a plurality of neural network based decoders to decode encoded error correction codewords further encoded for error detection which are transmitted over a transmission channel, according to some embodiments of the present invention.

An exemplary process 1200 may be executed by an ensemble comprising a plurality of trained neural network based decoders to decode a received encoded codeword.

As shown at 1202, the process 1200 starts with an ensemble comprising α trained neural network based decoders receiving an encoded error correction code [symbol] transmitted via a transmission channel subject to interference characterized by a certain interference pattern injected to the transmission channel.

In particular, the received encoded error correction code [symbol] is derived from a message word encoded twice at a transmitter such as the transmitter 1002. First the message word is encoded according to one or more of the error detection codes, for example, CRC and/or the like. After encoded for error detection, the encoded word is further encoded according to the error correction code, for example, a linear code, such as, for example, a block code, a convolutional code and/or the like, a non-linear code and/or the like to produce a doubly encoded codeword.

As shown at 1204, the ensemble, for example, the mapping function(s) may compute an error detection value, for example, a CRC value and/or the like for the received doubly encoded codeword.

The mapping function(s) may apply one or more methods, techniques and/or algorithms to compute the CRC value. For example, the mapping function(s) may apply a gating decoder, for example, a neural network based decoder to decode the received doubly encoded codeword and compute its error detection value.

The gating decoder may be a simple and relatively low cost decoder which may consume little resources. However, while incapable of accurately, reliably and/or consistently decoding the received doubly encoded codeword, the gating decoder may produce a rough approximation of the received doubly encoded codeword which may be sufficient for the mapping function(s) to compute an estimated and/or approximated CRC value for the received doubly encoded codeword.

As shown at 1206, based on the computed CRC value, the mapping function(s) may map the received doubly encoded codeword to one of the plurality of regions constituting the distribution space of the error correction code.

As shown at 1208,

However, as shown 1208, the mapping function(s) may select one of the plurality of neural network based decoders of the ensemble which corresponds to the region into which the received doubly encoded codeword is mapped.

As described herein before, each of the neural network based decoders corresponds to a respective one of the plurality of regions which combined together constitute the entire distribution space. The selected neural network based decoder may be therefore the most suitable decoder of the ensemble for decoding the received doubly encoded codeword since it was trained and specialized for decoding error correction encoded codewords mapped to region into which the received doubly encoded codeword is mapped.

As shown at 1210, the received doubly encoded codeword, [symbol] may be fed to the selected neural network based decoder which may decode the received doubly encoded codeword [symbol] an output a respective decoded codeword decoded codeword ũ⁽ⁱ⁾.

As described for the trained neural network based decoders configured to decode the error correction codes (not doubly encoded codewords), one or more of the neural networks based decoders of the ensemble may be further trained online when applied to decode one or more received doubly encoded codewords transmitted over a certain transmission channel. As such the ensemble of neural networks based decoders may adapt and adjust to one or more interference patterns typical and/or specific to the certain transmission channel.

Following is a detailed exemplary implementation of the processes 1100 and 1200 for an exemplary linear code, specifically a Tail-Biting Convolutional Code (TBCC). This however should not be construed as limiting since similar and/or other implementations may become apparent to a person skilled in the art for training and using neural network based decoders to decode other linear error correction codes (e.g. block codes, convolutional codes) and/or non-linear error correction codes which are further encoded for error detection.

As known in the art, neural network based decoders employing one or more variations of Viterbi algorithm (VA) which may be highly efficient for decoding error correction convolutional codes. The solution to equation 30 may be therefore computed for convolutional error correction encoded codewords using the Viterbi algorithm.

The memory of the convolutional code may be denoted by v and the state space of the convolutional code may be denoted by S={0, . . . , 2^{v}−1}.

As known in the art, convolutional codes may be represented by multiple temporal transitions which may depend on the input bit and the current state. The temporal transitions and relations may be conveniently expressed by the graph (trellis) representation of the convolutional code, for example, bipartite graph, Tanner graph, factor graph and/or the like where the sequence of states may be denoted by s∈S^{N}^{ᵤ}⁺¹.

Based on the properties of the convolutional codes, there is a one-to-one correspondence between the codeword u and the state sequence s as expressed in equation 31 below.

$${arg max}_{u ∈ 𝒰} P ( u ) P ( ℓ / u ) = {arg max}_{s ∈ {S}^{{N}_{u} + 1}} P ( s ) P ( ℓ / s ) \qquad \underline{Equation 31}$$

Applying the Markov property to equation 31 as known in the art may produce equation 32 below:

$${arg max}_{s ∈ {S}^{{N}_{u} + 1}} P ( s ) P ( ℓ / s ) = {arg max}_{s ∈ {S}^{{N}_{u} + 1}} {\prod }_{i = 1}^{{N}_{u}} P ( {s}_{i + 1} \vert {s}_{i} ) P ( {ℓ}_{iV - V + 1 \text{;} iV} \vert {s}_{i + 1} , {s}_{i} ) = {arg max}_{s ∈ {S}^{{N}_{u} + 1}} { \prod }_{i = 1}^{{N}_{u}} log ( P ( {s}_{i + 1} \vert {s}_{i} ) ) + log ( P ( {ℓ}_{iV - V + 1 \text{;} iV} \vert {s}_{i + 1} , {s}_{i} ) ) \qquad \underline{Equation 32}$$

where the last transition is due to the monotonic nature of the log function.

A path metric λ and a branch metric β representing transitions over an edge of the graph (trellis) may be denoted λᵢ=−log(P(sᵢ₊₁|sᵢ)) and βᵢ=−log(P( [symbol] _{iV-V+1;iV}|sᵢ₊₁,sᵢ)). Applying the path metric λ and the branch metric β to equation 32 may produce equation 33 below.

$${arg max}_{s ∈ {S}^{{N}_{u} + 1}} P ( s ) P ( ℓ / s ) = {arg max}_{s ∈ {S}^{{N}_{u} + 1}} {\sum }_{i = 1}^{{N}_{u}} {λ}_{i} + {β}_{i} \qquad \underline{Equation 33}$$

The decoder 1014 may efficiently solve equation 33 by applying the Viterbi algorithm as known in the art to perform a forward pass over the graph (trellis) representation of the convolutional code according to equation 34 below.

$${λ}_{i} ( s ) = {min}_{{s}^{′} ∈ S} {λ}_{i} ( {s}^{′} ) + {β}_{i} s ∈ S \qquad \underline{Equation 34}$$

starting from i=2 up to i=Nᵤ+1 in an incremental fashion with initialization

$${λ}_{i} ( s ) = \{ \begin{matrix}- {λ}_{max} if s = {s}_{1} \\ 0 otherwise\end{matrix}$$

with s₁=0, where the constant λₘₐₓ is designated the LLR clipping parameter.

The decoder 1014 may then perform a trace-back operation Π: [symbol] ^{N}^{_{c}}×S→ [symbol] to compute the estimated detection codeword û based on the LLR word [symbol] and a termination state s, according to equation 35 below.

[symbol]

û=Π( [symbol] ,s′) Equation 35:

Specifically, the trace-back may compute the sequence of states s that follows the minimal λᵢ(s) values at each stage, starting from S_{N}_{ᵤ}₊₁ backwards. The decoder 1013 may map the sequence s to the corresponding estimated codeword û and under the classical zero-tail termination, the decoder 1014 may output û=Π( [symbol] , 0).

The Tail-Biting Convolution Code (TBCC) which is an exemplary convolutional code is based on the assumption of equal start (initial) and end (termination) states where the actual values of the states are determined by the last v bits of the codeword.

It may be theoretically possible to apply a Maximum-Likelihood Decoder (MLD) based on the Viterbi algorithm to decode TBCC codewords by executing multiple runs of the Viterbi algorithm to identify the codeword whose matching λ_{N}_{ᵤ}₊₁(s′) value is minimal. However, this approach may be highly limited since the decoding complexity grows exponentially with the increase in the number of bits of the encoded codeword.

However, while sub-optimal, neural network based decoders employing circular Viterbi algorithm (CVA), as known in the art, may be applied to more efficiently decode TBCC codewords. The CVA may exploit the circular nature of the TBCC graph (trellis) by executing the Viterbi algorithm for a specified number of repetitions, where each new repetition of the Viterbi algorithm may be initialized with the end metrics of the previous repetitions. The CVA starts and ends its run at the zero state, being error prone near the zero tails. Explicitly, the forward pass of the CVA follows may follow equation 34 for i∈{2, . . . , I·Nᵤ} where I denoting an odd number of replications with the same initialization expressed in equation 34. The bits of the middle replication may be the least errors-prone as they are farthest from the zero tails, thus returning the decoded codeword

$$\hat{u} = {( Π ( , 0 ) )}_{i + [ \frac{I}{2} ] \cdot {N}_{u}}$$

for i∈{1, . . . , Nᵤ}.

The neural network based decoders configured for decoding double encoded codewords encoded according to the convolutional codes may therefore apply a parameterized and weighted circular Viterbi algorithm (WCVA) to overcome the limitations described herein before which the decoding methods known in the art suffer, in particular the limitations of the neural network based CVA decoders.

The neural network based weighted circular Viterbi decoders apply may apply branch metrics corresponding to the edges of the graph (trellis) representation of the TBCC code. Moreover, weights are also applied to the path metrics thus incorporating another level of freedom for the neural network based weighted circular Viterbi decoders to train, learn, evolve and adapt to the TBCC code. Optionally, in order to reduce the computation complexity, only some of the repetition of the CVA may be parameterized and weighted, specifically the middle repetitions. The weighted paths and branches may be expressed based on equation 34 as expressed in equation 36 below.

$${λ}_{i} ( s ) = {min}_{{s}^{′} ∈ S} {ω}_{i , {s}^{′} , s} {λ}_{i - 1} ( {s}^{′} ) + {ω}_{i , β} {β}_{i} \\ for [ \frac{I}{2} ] \cdot {N}_{u} \leq i \leq [ \frac{I}{2} ] \cdot {N}_{u} . \qquad \underline{Equation 36}$$

The neural network based weighted circular Viterbi decoders may be therefore trained and learned to compute and identify weights (parameters) {ω_{i,s′,s},ω_{i,β}} producing termination states equal to ground truth start and end states of the TBCC codewords. Since the exact equality criterion is non-differentiable, a respective multi-class cross entropy loss may be applied, acting as a surrogate loss as expressed in equation 37 below.

[symbol]

(s,λ)=−log σ(λ^{l}(S_{N}_{ᵤ}₊₁) Equation 37:
where

$${λ}^{l} ( \cdot ) = {λ}_{[ \frac{I}{2} ] \cdot {N}_{u}} ( \cdot )$$

designates the last learnable layer of the neural network based weighted circular Viterbi decoder and σ is a softmax function expressed in equation 38 below.

$$σ ( {λ}^{l} ( s ) ) = \frac{{e}^{{λ}^{l} ( s )}}{{\sum }_{{s}^{′} ∈ S} {e}^{{λ}^{l} ( {s}^{′} )}} \qquad \underline{Equation 38}$$

It was experimented and proved that applying the softmax function of equation 37 leads to efficient convergence of the end (termination) states of the TBCC in the middle replications of the neural network based weighted circular Viterbi decoder to their ground-truth values. Further experimentation revealed that parameterizing, i.e., assigning weights to the edges of additional layers beyond the middle layer had no significant improvement on the decoding performance of the neural network based weighted circular Viterbi decoder and therefore only the middle layer(s) are weighted.

Moreover, it should be noted that the gradients back-propagate through the non-differentiable min criterion of equation 36 as in the maximum pooling operation, i.e., they may only affect the state that achieved the minimum metric as expressed by the weights.

However, since the initial state of the code is unknown, the probability of all termination states may be the same which may translate to all edges of the neural network based weighted circular Viterbi decoder having equal edges, contrary to the BP based neural networks in which not all edges are created equal, for example, edges participating in many short cycles may be assigned higher weights compared to less frequent edges. As result, it may be possible that during training of the neural network based weighted circular Viterbi decoder, the weights may not adjust and at worst may even lead to divergence.

In order to overcome this limitation and exploit the decoding performance increase gained by adjusting the weights, the symmetry of the problem, i.e., the similar probabilities of the termination states, the termination state distribution space may be divided to a plurality of subsets and a plurality of neural network based weighted circular Viterbi decoders may be each trained using a respective subset. As such, each of the plurality of neural network based weighted circular Viterbi decoder may be specialized for efficiently decoding codewords having termination states included in the respective subset with which the decoder was trained.

The exemplary process following the process 1100 may be therefore executed by a trainer such as the trainer 320 to train a plurality of neural network based weighted circular Viterbi decoders to decode codewords of one or more convolutional codes, for example, TBCC transmitted over a transmission channel which are further encoded for error detection using one or more of the error detection codes, for example CRC and/or the like.

Each of the neural network based weighted circular Viterbi decoders may be implement based on the graph representation (trellis) of the encoded convolutional code as described herein before, for example, bipartite graph, Tanner graph, factor graph and/or the like. Each of the neural network based weighted circular Viterbi decoders may therefore comprise an input layer, an output layer and a plurality of middle (hidden) layers comprising a plurality of nodes corresponding to messages transmitted over a plurality of edges of the graph representation. Each of the edges connecting a certain source node and a certain destination node may be assigned with a respective weight adjusted during the training.

The trainer 320 may receive and/or obtain a plurality of data samples each mapping an encoded codeword of an error correction convolutional code transmitted over a transmission channel subject to interference, for example, noise, crosstalk, attenuation and/or the like. In particular, the training samples may include message words which are encoded according to one or more detection codes, for example, CRC and further encoded according to the correction code, specifically the convolutional code, for example, TBCC before transmitted over the transmission channel.

The trainer 320 may divide (partition) the termination state distribution space of the convolutional code to create a plurality of termination state subsets each comprising one or more respective termination states of the plurality of termination states of the convolutional code. This means that each of the terminations states may be included in only one of the termination state subsets while, combined together, the termination state subsets cover the entire termination state distribution space of the convolutional code. The termination state subsets may therefore represent the regions of the distribution space of the error correction code as described in the process 100.

In particular, the trainer 320 may create the termination state subsets according to the number of neural network based weighted circular Viterbi decoders that are trained, which may be denoted by a such that each of the neural network based weighted circular Viterbi decoders may be mapped to a respective one of the termination state subsets created by the trainer 320.

Moreover, the trainer 320 may create the termination state subsets to include close-by termination states which are significantly similar to each other.

The trainer 320 may select a plurality of sample subsets of the plurality of samples where each of the sample subsets comprises training samples having a termination state which is included in a respective one of the plurality of termination state subsets. In other words, the trainer 320 may map each of the sample subsets to a respective one of the termination state subsets by selecting each sample subset to include training samples having termination states that are included in the respective mapped termination state subset.

The termination state of each transmitted training sample u which as described herein before may equal the initial state of the training sample may be denoted by si.

The trainer 320 may therefore include each training sample u in a respective sample subset mapped to a certain termination state subset which includes state si and may add a tuple ( [symbol] , u) accordingly as shown in equation 39 below.

$$D ( i ) = \{ ( ℓ , u ) \text{:} \frac{{2}^{v}}{ℓ} \cdot ( i - 1 ) \leq {s}_{1} \leq \frac{{2}^{v}}{α} \cdot i - 1 \} \\ with i ∈ \{ 1 , … , α \} . \qquad \underline{Equation 39}$$

The trainer 320 may apply the above mapping process for the plurality of training samples such that each of the sample subsets may eventually include a plurality of samples having termination state(s) included in a respective one of the termination state subsets.

The trainer 320 may train the plurality of neural network based weighted circular Viterbi decoders using the training samples. Specifically, the trainer 320 may train each neural network based weighted circular Viterbi decoder using a respective sample subset.

Since each sample subset is mapped to a respective termination state subset comprising a limited number of termination states, during the training each of the neural network based weighted circular Viterbi decoder may be specialized, i.e., learn, evolve, adapt and/or adjust to efficiently decode a certain group of encoded codewords which are characterized by having only a limited number of termination states.

The trainer 320 may train each of the network based weighted circular Viterbi decoders by applying the forward pass and trace-back passes (trace-backs) to a respective sample dataset as described herein before, for example, in equations 34 and 35. In particular, the trainer 320 may train each network based weighted circular Viterbi decoder using a respective sample subset by applying forward pass to each training sample of the respective sample subset followed by a plurality of trace-back passes. However, rather than applying the trace-backs using all termination states of the convolutional code, the trace-back passes may be applied using only the limited number of termination states, specifically the termination state(s) included in the respective termination state subset to which the receptive sample subset is mapped.

The trainer 320 may apply one or more of the training algorithms, methods and/or paradigms known in the art for training the network based weighted circular Viterbi decoders, for example, stochastic gradient descent, batch gradient descent, mini-batch gradient descent and/or the like.

Complementary, an ensemble comprising the plurality of trained network based weighted circular Viterbi decoders may be applied to decode error correction convolutional codes as an example for the ensemble of decoders used in the process 1200 for decoding doubly encoded codewords. The ensemble comprising the plurality of trained network based weighted circular Viterbi decoders may be applied to decode error correction convolutional codes, specifically doubly encoded codewords which are first encoded using one or more error detection codes, for example, CRC and further encoded according to the convolutional error correction code.

The ensemble may therefore execute an exemplary process following the process 1200 to decode doubly encoded codewords encoded according to one or more of the error correction convolutional codes, for example, TBCC.

This should not be construed as limiting since similar and/or other implementations may become apparent to a person skilled in the art for training and using ensembles of decoders to decode other linear and/or non-linear error correction codes which are further encoded for error detection.

Since each of the network based weighted circular Viterbi decoders is specialized for efficiently decoding encoded codewords having a respective subset (region) of the termination state space, employing all the trained network based weighted circular Viterbi decoders, the ensemble may be capable of efficiently decoding any encoded codeword having any of the termination states of the convolutional code. The ensemble therefore builds on the active learning concept by using the plurality of trained network based weighted circular Viterbi decoders.

The ensemble may comprise a mapping function and/or a gating module configured to analyze each received encoded codeword and select one of the trained network based weighted circular Viterbi decoders of the ensemble which is estimated to most efficiently decode the received codeword. In particular, the mapping function(s) may select the network based weighted circular Viterbi decoders most suitable to decode the received encoded codeword based on the termination state determined, estimated and/or computed for the received encoded codeword.

The ensemble comprising a trained neural network based weighted circular Viterbi decoders may receive a doubly encoded error correction code [symbol] transmitted via a transmission channel subject to interference characterized by a certain interference pattern injected to the transmission channel.

The ensemble may apply one or more mapping functions to map the received doubly encoded word [symbol] to one of the plurality of termination states of the convolutional code. In particular, the mapping function(s) configured to estimate the state of the received doubly encoded codeword may apply the forward pass and trace-back passes for the received codeword as described herein before. In particular, the mapping function(s) may estimate the state of the received doubly encoded codeword based on a CRC value computed for the received doubly encoded codeword.

To this end, the mapping function(s) may apply, for example, one or more gating Viterbi decoders, for example, a circular Viterbi decoder to the received encoded word [symbol] as described in equation 34. However, since all states are equally probable, the starting (initial) state which as described herein before equals the termination state may be chosen as λ₁(s)=0, ∀s∈S instead of equation 35.

The gating Viterbi decoder(s) may be relatively simple decoder(s) having limited performance in order to limit the computing resources required for the forward pass. Using the low-end limited performance gating Viterbi decoder(s) may be sufficient since the forward pass coupled with the trace-back passes described herein after are not directed for actually decoding the received encoded word [symbol] but rather map the received encoded word [symbol] to an estimated termination state and select one of the neural network based weighted circular Viterbi decoder to do the actual decoding.

After applying the gating Viterbi decoder to calculate λᵢ(s) for every termination state and stage, the mapping function(s) may apply the gating Viterbi decoder(s) to compute a plurality of trace-back passes Π(⋅), specifically, α trace-backs each starting from α different termination/starting state. The states may be spread uniformly over S, with the decoded codewords given by equation 40 below.

$${\tilde{u}}^{( i )} = \prod ( ℓ , \frac{{2}^{v}}{α} \cdot ( i - \frac{1}{2} ) ) , 1 \leq i \leq α \qquad \underline{Equation 40}$$

It should be noted that the trace-back which is repeated multiple times is a simple operation requiring significantly low computing resources compared to the forward pass which is conducted only once.

The mapping function(s) may further compute a CRC syndrome value gi for each of the decoded codewords R(O computed in the plurality of trace-back passes as expressed in equation 41 below.

gᵢ=∥ũ⁽ⁱ⁾H_{CRC}^{T}∥ Equation 41:

Wherein gᵢ=0 indicates that no error has occurred or more accurately no error was detected. In case gᵢ=0 for only a single one of the α trace-backs, the mapping function(s) may output the corresponding decoded codeword ũ⁽ⁱ⁾. In case gᵢ equals zero for more than one trace-back pass, the decoded codeword ũ⁽ⁱ⁾ may be chosen randomly among the candidate trace-back passes for which gᵢ=0.

However, in case gᵢ≠0 for all decoded codewords ũ⁽ⁱ⁾ computed in all of the trace-back passes, the mapping function(s) may select one of the trained neural network based weighted circular Viterbi decoders of the ensemble according to the CRC (syndrome) values.

Each of the CRC values gᵢ≠0 may be correlated with an ascription of the received encoded codeword [symbol] to a respective termination state

$$\frac{{2}^{ν}}{α} \cdot ( i - \frac{1}{2} ) .$$

The mapping function(s) may therefore select the neural network based weighted circular Viterbi decoder corresponding to the termination state which minimal CRC value in the trace-back passes since the neural network based weighted circular Viterbi decoder trained with the subset of termination states comprising the termination state which produced the minimal CRC value may naturally most efficient decoder the received encoded codeword [symbol] . While the ground-truth termination state may not necessarily have the minimum gᵢ, this minimal gᵢ value may provide a highly reliable estimation of the ground-truth termination state or at least of a close-by termination state.

In case multiple CRC value computed in multiple trace-back passes equal the same minimal value, the mapping function(s) may select multiple neural network based weighted circular Viterbi decoders corresponding to the multiple termination states used in the trace-backs that produced the minimal value CRC. In other words, assuming multiple CRC values gᵢ_{₁}, . . . , gᵢ_{ₖ} are computed in k trace-backs each using a respective termination state each included in a respective termination state subset used to train a respective one of k neural network based weighted circular Viterbi decoders.

The received doubly encoded codeword [symbol] may then be fed to the selected neural network based weighted circular Viterbi decoder which may decode the received encoded codeword [symbol] an output a respective decoded codeword decoded codeword ii(O.

In case multiple, for example, k neural network based weighted circular Viterbi decoders i₁, . . . , iₖ are selected to decode the received encoded codeword [symbol] , the ensemble may output the one of the decoded codeword ũ⁽ⁱ⁾ computed by the k neural network based weighted circular Viterbi decoders, specifically the decoded codeword ũ⁽ⁱ⁾ which produces the minimal CRC value.

Presented herein after are results of experiments conducted to evaluate performance of the ensemble, designated WCVAE (weighted circular Viterbi algorithm ensemble) herein after comprising a plurality of neural network based weighted circular Viterbi decoders each trained and specialized to decode encoded convolutional codewords having a respective subset of termination states.

The WCVAE was simulated with CRC codes and TBCC that are in accordance with the LTE standard. It should be noted that while LTE employs QPSK modulation, for simplicity the experiments were conducted using BPSK. A TBCC code of specific length is denoted with (N_{c}, Nᵤ, Nₘ) referring to the code's length, detection codeword's length and message's length, respectively. A summary of relevant parameters of the convolutional code (CC) appears in table 5.

TABLE 5

| Symbol | Definition | Values |
|---|---|---|
| υ | CC memory size | 6 |
| — | CC polynomials | (133, 171, 165) |
| R_{CC} | CC rate | 1/3 |
| — | CRC length | 16 |

Two variants of the WCVAE were evaluated, specifically the gated WCVAE described in the process 1200 and a (non-gated) WCVAE. In the WCVAE, all the decoders are employed for decoding, and their output is combined into a single chosen codeword. The gated WCVAE and the WCVAE were evaluated compared to the next common baselines:
1) 3-repetitions Circular Viterbi Algorithm (CVA)—a fixed-repetitions CVA.
2) List Circular Viterbi Algorithm (LCVA)—a list Viterbi algorithm (LVA) that runs CVA instead of a VA.
3) List Genie Viterbi Algorithm (LGVA)—an LVA decoder with list of size a, that runs from a known ground-truth state. The optimal decoded codeword is chosen by the CRC criterion. The Frame Error Rate (FER) of the gated and non-gated WCVAE are lower bounded by this genie-empowered decoder.

The experiments include Monte Carlo experiments run on a validation dataset composed of SNR values in the range of −2 dB to 2 dB with a step of 1 dB. Simulations at each point continued until at least 500 errors were accumulated. The number of decoders in the ensemble was set to α=8. Since words are drawn from the channels arbitrarily, the notion of “epoch” which refers to the number of full transitions over the training dataset is not sufficiently defined. The number of training mini-batches is provided instead. All the Viterbi based decoders, i.e. the gating decoder and the specialized decoders, were executed with I=3 repetitions. The overall hyperparameters for the ensemble training are depicted in table 6.

TABLE 6

| Symbol | Definition | Values |
|---|---|---|
| α | Ensemble size | 8 |
| I | Repetitions per decoder | 3 |
| λₘₐₓ | LLR clipping | 20 |
| — | Learning rate | 10⁻³ |
| — | Optimizer | RMSPROP |
| — | Loss | Cross Entropy |
| — | Training SNR range [dB] | (−2) − 0 |
| — | Mini-batch size | 450 |
| — | Number of mini-batches | 50 |

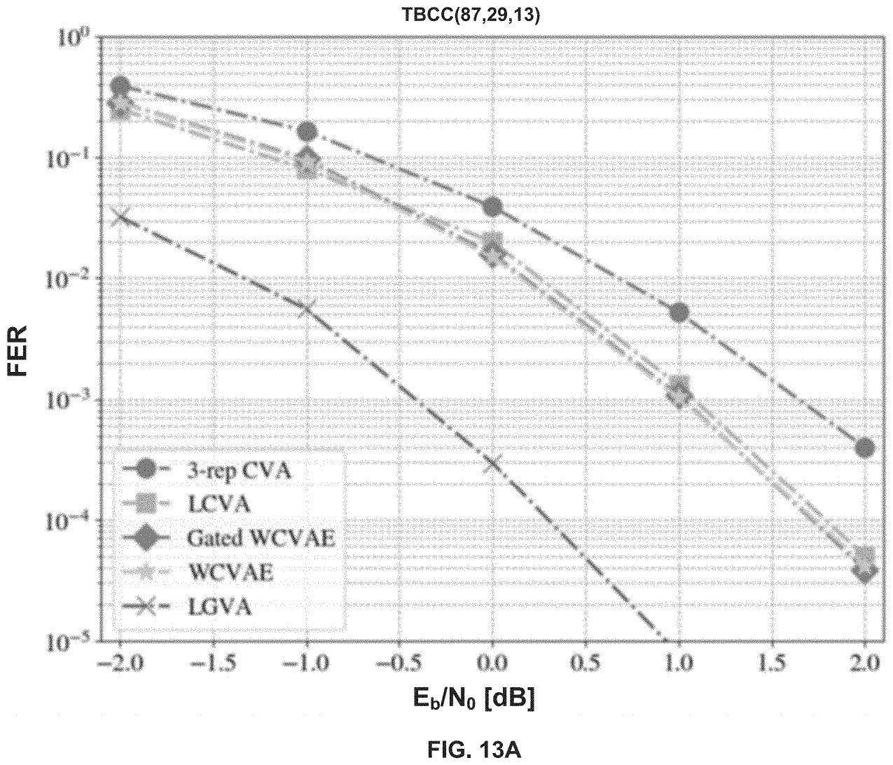

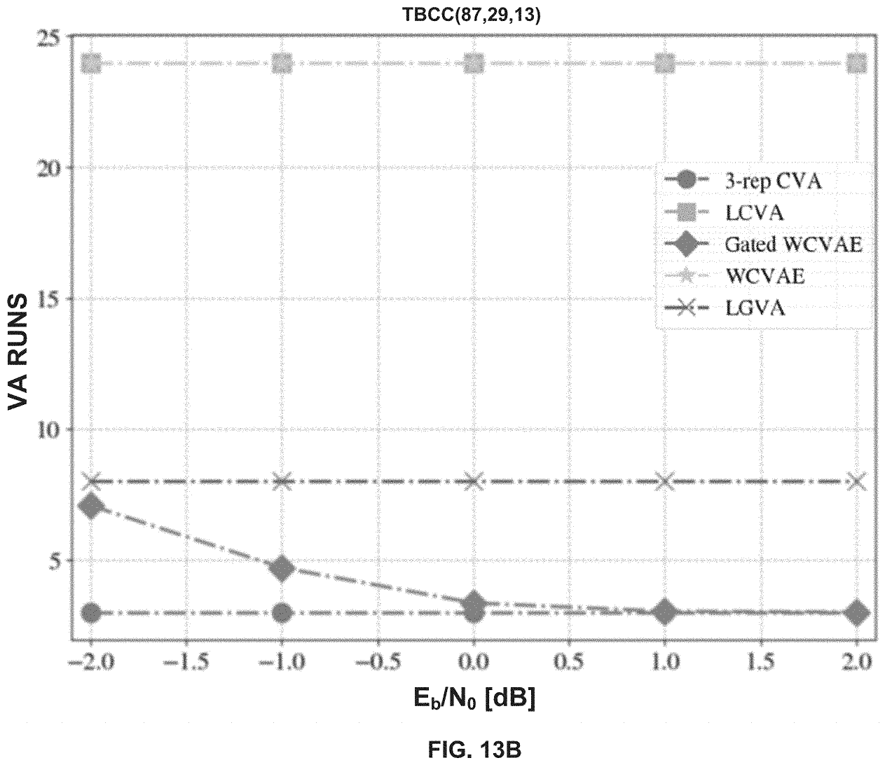

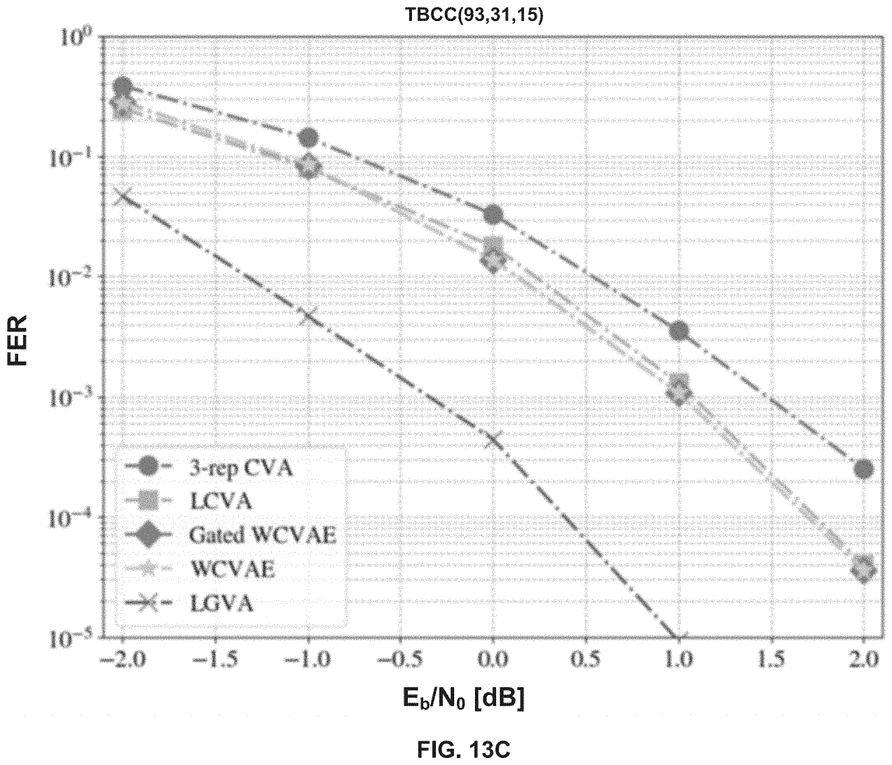

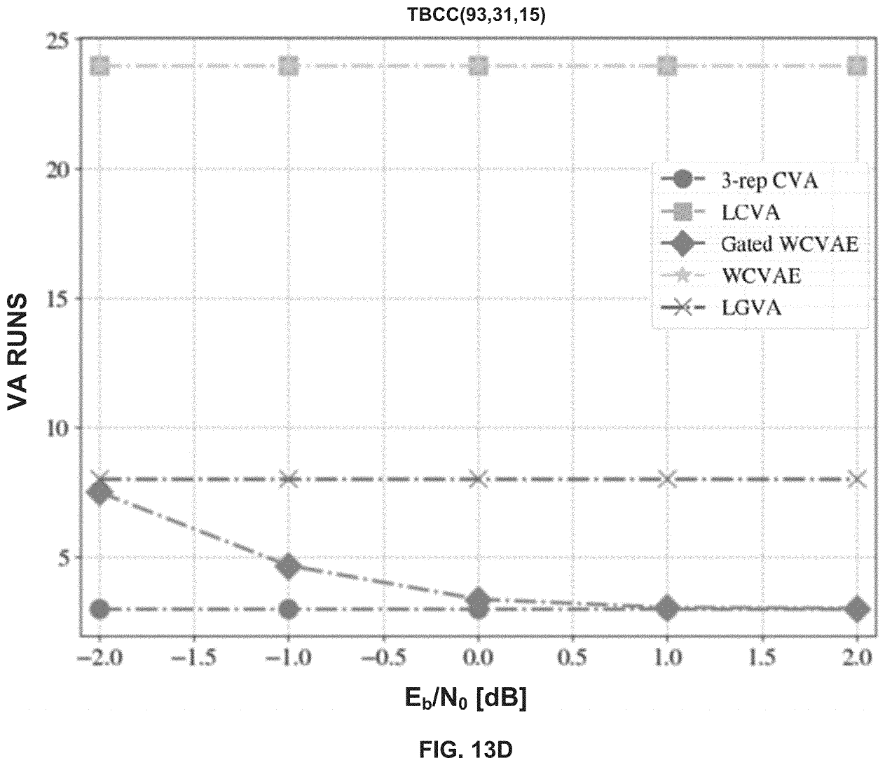

Reference is now made to FIG. 13A, FIG. 13B, FIG. 13C and FIG. 13D, which are graph charts of FER and VA run results of an ensemble of neural network based weighted circular Viterbi decoders applied to decode Tail-Biting (87,29,13) and (93, 31, 15) convolutional codes, according to some embodiments of the present invention.

The graph charts in FIG. 13A and FIG. 13C present FER results for the two TBCC codes, specifically a TBCC(87,29,13) and TBCC(93,31,15) respectively. The graph charts in FIG. 13B and FIG. 13D present computational complexity which is expressed by VA runs for the TBCC(87,29,13) and TBCC(93,31,15) codes respectively.

As can be seen in the graphs in FIGS. 13A and 13C, the gated WCVAE and the non-gated WCVAE achieve higher performance expressed by FER gains of up to 0.75 dB and 0.625 dB gain over the CVA in the waterfall region, for the TBCC code lengths of 13 and 15, respectively. The gated WCVAE and the non-gated WCVAE also surpasses the LCVA by a small margin.

Moreover, considering the complexity, as seen in FIG. 13B and FIG. 13D, the gated WCVAE significantly outperform the LCVA and the non-gated WCVAE. Furthermore, the number of VA runs of the gated WCVAE decreases as an inverse function of the SNR and converges with the 3-repetitions CVA in high SNR values. Since the trace-backs have negligible complexity compared to the forward pass of the VA, the computational complexities of the evaluation of the received encoded may be regarded to be similar.

The WCVAE in its gated and non-gated forms may be easily generalized for decoding longer convolutional codes. This ability was demonstrated in experiments with longer TBCC codes.

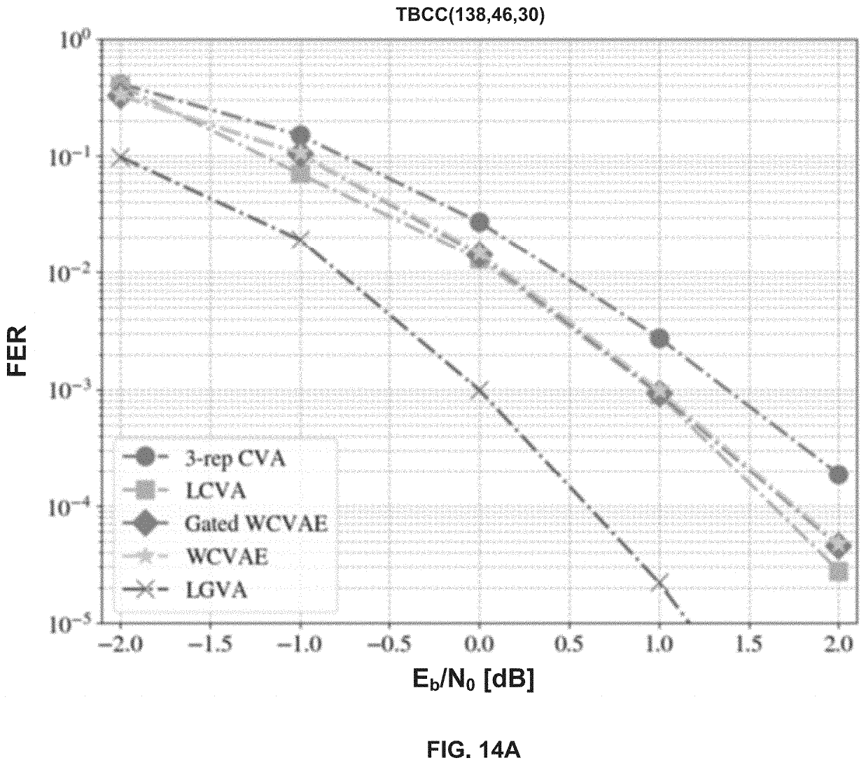

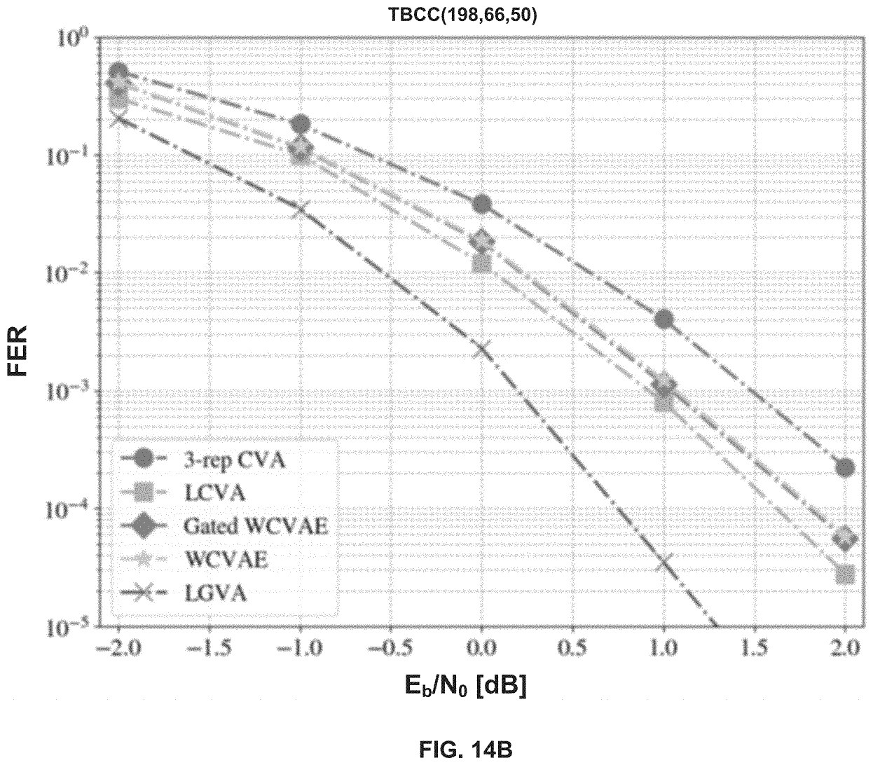

Reference is now made to FIG. 14A and FIG. 14B, which are graph charts of FER results of an ensemble of neural network based weighted circular Viterbi decoders applied to decode Tail-Biting (138,46,30) and (198, 66, 50) convolutional codes, according to some embodiments of the present invention.

The graph charts in FIG. 14A and FIG. 14B present FER results for the two long TBCC codes, specifically a TBCC(138,46,30) and TBCC(198,6,50) respectively. The same WCVAE used for the shorter TBCC codes presented in FIGS. 13A-13D was trained over the two longer length TBCC codes. Except for their length, the code parameters of the longer TBCC codes are exactly as in tables 5 and 6.

As evident from the charts in FIG. 14A and FIG. 14B, an FER gain of around the 0.6 dB is achieved similarly to the longer one of the two shorter codes, i.e., TBCC(93,31,15). This may empirically demonstrate the scalability and generalization of the WCVAE to longer length codes. Moreover, the training process as described in the process 1100 may remain similarly simple even as the length if the convolutional code increases eliminating the need to enforce a curriculum based ramp-up method for convergence as known in the art.

The experiments were also directed to evaluate the performance of the weighted circular Viterbi algorithm as disclosed herein compared to the circular Viterbi algorithm as known in the art. In particular, the experiments are directed to evaluate the performance of the trained neural network based weighted circular Viterbi decoders specialized for a subset of termination states compared to neural network based circular Viterbi decoders as known in the art.

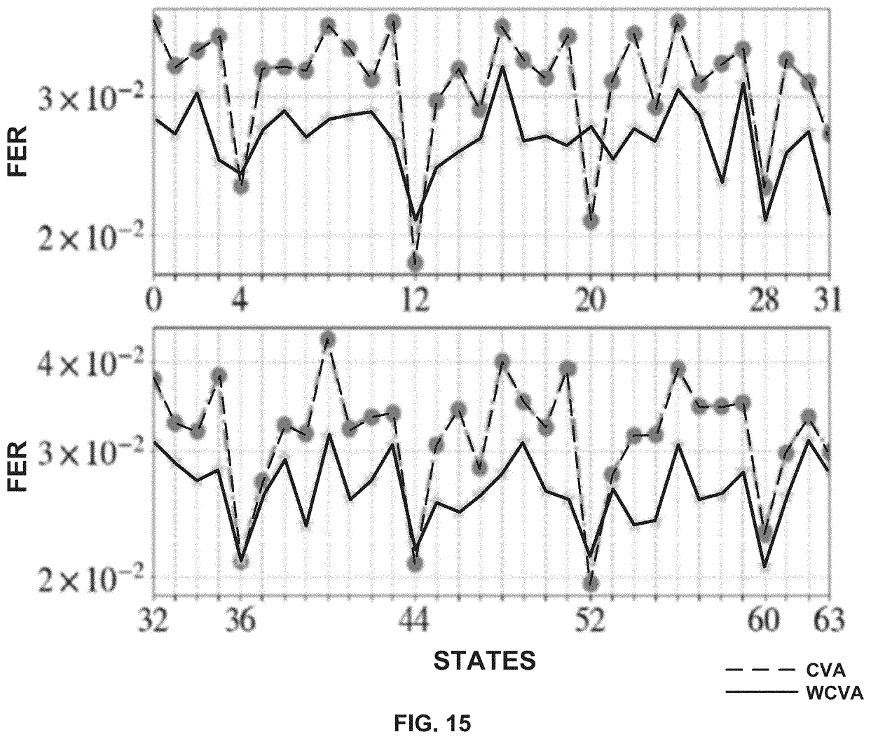

Reference is now made to FIG. 15, which is a graph chart of FER results of a trained neural network based circular Viterbi decoder vs, a trained neural network based weighted circular Viterbi decoder as function of the number of termination states of a convolutional codes, according to some embodiments of the present invention.

The graph chart presents the FER performance of a trained neural network based weighted circular Viterbi decoders (solid line designated WCVA in the charts) compared to a classical neural network based circular Viterbi decoder (dashed line designated CVA in the charts). The experiments were conducted using a TBCC (87; 29; 13) code with the SNR set to 0 dB.

The i^{th} classical CVA had 3 repetitions, and α trace-back was run from state

$$\frac{{2}^{ν}}{α} \cdot ( i - \frac{1}{2} )$$

as described herein before. The trained WCVA is the i^{th} of the ensemble (WCVAE) configured and trained for decoding states

$$\{ \frac{{2}^{ν}}{α} \cdot ( i - \frac{1}{2} ) , … , \frac{{2}^{v}}{α} \cdot i - 1 \} .$$

The trained WCVA run the trace-back from the same state

$$\frac{{2}^{ν}}{α} \cdot ( i - \frac{1}{2} ) .$$

At each point, codewords of the given state, and only this state, were simulated until 250 errors were accumulated. As evident, the CVA has peak performance at the trace-back state, yet at all other states the CVA decoder performs poorly. On the other hand, the WCVA decoders manage a trade-off as they may sacrifice performance over the trace-back state, compensating for this loss by achieving lower error rates at other states. This demonstrates the fact that the specialized WCVA decoders are indeed specialized at decoding codewords with a termination states included in their respective subset of termination states.

Some of the experiments were conducted to evaluate the impact of the size of the ensemble of neural network based weighted circular Viterbi decoders on its performance.

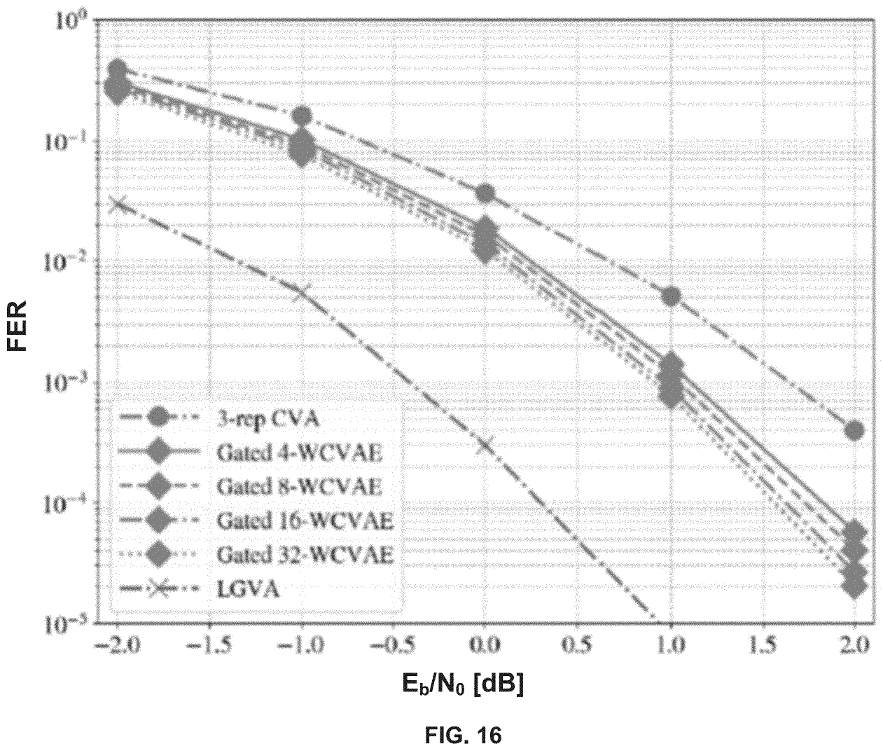

Reference is now made to FIG. 16, which is a graph chart presenting performance of an ensemble of neural network based weighted circular Viterbi decoders as function of their size, according to some embodiments of the present invention.

The graph chart presents the FER performance of a simulation of several ensembles each comprising a different number α∈{4,8,16,32} of neural network based weighted circular Viterbi decoders where each of the decoders is specialized for decoding codewords having termination states mapped to different subsets each associated with one of the decoders of the ensemble. In the experiment, all the ensembles are applied to decode the same TBCC(87; 29; 13) code and are simulated with 500 accumulated errors (per point). All other parameters and hyperparameters are the same as in tables 5 and 6.

As implied by the graph chart, increasing the number of neural network based weighted circular Viterbi decoders by a factor of two provides an FER performance gain of around 0.1 dB. This simulation may empirically validate an intuitive assumption that the ensemble (WCVAE) is more diverse as its size increases, i.e. the ensemble may successfully capture a larger portion of the input codeword space.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

It is expected that during the life of a patent maturing from this application many relevant systems, methods and computer programs will be developed and the scope of the terms error correction codes, neural networks and variants of the Viterbi algorithm are intended to include all such new technologies a priori.

As used herein the term “about” refers to ±10%.

The terms “comprises”, “comprising”, “includes”, “including”, “having” and their conjugates mean “including but not limited to”. This term encompasses the terms “consisting of” and “consisting essentially of”.

The phrase “consisting essentially of” means that the composition or method may include additional ingredients and/or steps, but only if the additional ingredients and/or steps do not materially alter the basic and novel characteristics of the claimed composition or method.

As used herein, the singular form “a”, “an” and “the” include plural references unless the context clearly dictates otherwise. For example, the term “a compound” or “at least one compound” may include a plurality of compounds, including mixtures thereof.

The word “exemplary” is used herein to mean “serving as an example, an instance or an illustration”. Any embodiment described as “exemplary” is not necessarily to be construed as preferred or advantageous over other embodiments and/or to exclude the incorporation of features from other embodiments.

The word “optionally” is used herein to mean “is provided in some embodiments and not provided in other embodiments”. Any particular embodiment of the invention may include a plurality of “optional” features unless such features conflict.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible subranges as well as individual numerical values within that range. For example, description of a range such as from 1 to 6 should be considered to have specifically disclosed subranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals there between.

The word “exemplary” is used herein to mean “serving as an example, an instance or an illustration”. Any embodiment described as “exemplary” is not necessarily to be construed as preferred or advantageous over other embodiments and/or to exclude the incorporation of features from other embodiments.

The word “optionally” is used herein to mean “is provided in some embodiments and not provided in other embodiments”. Any particular embodiment of the invention may include a plurality of “optional” features unless such features conflict.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable sub-combination or as suitable in any other described embodiment of the invention. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

It is the intent of the applicant(s) that all publications, patents and patent applications referred to in this specification are to be incorporated in their entirety by reference into the specification, as if each individual publication, patent or patent application was specifically and individually noted when referenced that it is to be incorporated herein by reference. In addition, citation or identification of any reference in this application shall not be construed as an admission that such reference is available as prior art to the present invention. To the extent that section headings are used, they should not be construed as necessarily limiting. In addition, any priority document(s) of this application is/are hereby incorporated herein by reference in its/their entirety.

What is claimed is:

1. A computer implemented method of training neural network based decoders to decode error correction codes transmitted over transmission channels subject to interference, comprising:
using at least one processor for:
obtaining a plurality of samples each mapping at least one training codeword encoded according to at least one error detection code and further encoded according to at least one error correction code, each sample is subjected to a different interference pattern injected to the transmission channel;
computing an error detection value for each of the plurality of samples according to the at least one error detection code;
mapping each of the plurality of samples, based on its respective error detection value, to one of a plurality of regions of the distribution space of the error correction code;
selecting a plurality of sample subsets each comprising at least one of the plurality of samples which is mapped to a respective one of the plurality of regions; and
training each of a plurality of neural network based decoders using a respective one of the plurality of sample subsets.

2. The computer implemented method of claim 1, wherein the at least one error detection code comprising Cyclic Redundancy Check (CRC) code.

3. The computer implemented method of claim 1, wherein the at least one error detection code and the at least one error correction code are selected according to at least one 5G cellular communication protocol.

4. The computer implemented method of claim 1, wherein the plurality of neural network based decoders are implemented based on Viterbi algorithm.

5. The computer implemented method of claim 1, wherein each of the plurality of neural network based decoder comprises an input layer, an output layer and a plurality of hidden layers comprising a plurality of nodes corresponding to transmitted messages over a plurality of edges of a graph representation of the encoded code and a plurality of edges connecting the plurality of nodes, each of the plurality of edges having a source node and a destination node is assigned with a respective weight adjusted during the training.

6. The computer implemented method of claim 5, wherein the graph is a member of a group consisting of: a bipartite graph, a Tanner graph and a factor graph.

7. The computer implemented method of claim 1, wherein the at least one training encoded codeword encodes the zero codeword.

8. The computer implemented method of claim 1, wherein the training is done using at least one of: stochastic gradient descent, batch gradient descent and mini-batch gradient descent.

9. The computer implemented method of claim 1, wherein at least one of the plurality of neural network based decoders is further trained online when applied to decode at least one new and previously unseen encoded codeword of the code transmitted over a certain transmission channel.

10. A system for training neural network based decoders to decode error correction codes transmitted over transmission channels subject to interference, comprising:
at least one processor adapted to execute code, the code comprising:
code instructions to obtain a plurality of samples each mapping at least one training codeword encoded according to at least one error detection code and further encoded according to at least one error correction code, each sample is subjected to a different interference pattern injected to the transmission channel;
code instructions to compute an error detection value for each of the plurality of samples according to the at least one error detection code;
code instructions to map each of the plurality of samples, based on its respective error detection value, to one of a plurality of regions of the distribution space of the error correction code;
code instructions to select a plurality of sample subsets each comprising at least one of the plurality of samples which is mapped to a respective one of the plurality of regions; and
code instructions to train each of a plurality of neural network based decoders using a respective one of the plurality of sample subsets.

11. A computer implemented method of decoding a code transmitted over a transmission channel subject to interference using an ensemble of neural network based decoders, comprising:
using at least one processor for:
receiving an encoded codeword transmitted over a transmission channel, the received codeword is encoded according to at least one error detection code and further encoded according to at least one error correction code;
applying at least one mapping function to map the received encoded codeword to one of a plurality of regions of a distribution space of the error correction code based on an error detection value computed for the received encoded codeword according to the at least one error detection code;
selecting at least one of a plurality of neural network based decoders based on a region of the plurality of regions into which the received encoded codeword is mapped, each of the plurality of neural network based decoders is trained to decode codes mapped into a respective one of the plurality of regions constituting the distribution space; and
feeding the code to the at least one selected neural network based decoder to decode the code.

12. The computer implemented method of claim 11, wherein the at least one error detection code comprising Cyclic Redundancy Check (CRC) code.

13. The computer implemented method of claim 11, wherein the at least one error detection code and the at least one error correction code are selected according to at least one 5G cellular communication protocol.

14. The computer implemented method of claim 11, wherein the plurality of neural network based decoders are implemented based on Viterbi algorithm.

15. The computer implemented method of claim 11, wherein the at least one mapping function is based on decoding the received encoded codeword using at least one low complexity decoder.

16. The computer implemented method of claim 11, wherein the at least one mapping function employs at least one gating neural network based decoder trained to decode the received encoded codeword.

17. The computer implemented method of claim 16, wherein the at least one gating neural network based decoder is implemented based on Viterbi algorithm.

18. The computer implemented method of claim 11, wherein during training, the plurality of neural network based decoders are trained using a plurality of samples each mapping at least one training encoded codeword of the at least one error correction code, each of the plurality of neural network based decoders is trained with a respective one of a plurality of sample subsets, each of the plurality of sample subsets comprising at least one of the plurality of samples which is mapped to a respective one of the plurality of regions.

19. The computer implemented method of claim 11, wherein at least one of the plurality of neural network based decoders is further trained online when applied to decode at least one new and previously unseen encoded codeword of the at least one error correction code transmitted over a certain transmission channel.

20. A system for decoding a code transmitted over a transmission channel subject to interference using an ensemble of neural network based decoders, comprising:
at least one processor adapted to execute code, the code comprising:
code instructions to receive an encoded codeword transmitted over a transmission channel, the received codeword is encoded according to at least one error detection code and further encoded according to at least one error correction code;
code instructions to apply at least one mapping function to map the received encoded codeword to one of a plurality of regions of a distribution space of the error correction code based on an error detection value computed for the received encoded codeword according to the at least one error detection code;
code instructions to select at least one of a plurality of neural network based decoders based on a region of the plurality of regions into which the received encoded codeword is mapped, each of the plurality of neural network based decoders is trained to decode codes mapped into a respective one of the plurality of regions constituting the distribution space; and
code instructions to feed the code to the at least one selected neural network based decoder to decode the code.
